(19) United States
(12) Patent Application Publication
(10) Pub. No.: US 2022/0308265 A1
(43) Pub. Date: Sep. 29, 2022

(54) LIGHT ABSORPTION FILTER, OPTICAL FILTER, ORGANIC ELECTROLUMINESCENT DISPLAY DEVICE, AND LIQUID CRYSTAL DISPLAY DEVICE

(71) Applicant: FUJIFILM Corporation, Tokyo (JP)

(72) Inventors: Nobutaka FUKAGAWA, Kanagawa (JP); Daisuke SASAKI, Kanagawa (JP)

(73) Assignee: FUJIFILM Corporation, Tokyo (JP)

(21) Appl. No.: 17/833,664

(22) Filed: Jun. 6, 2022

Related U.S. Application Data
(63) Continuation of application No. PCT/JP2020/049006, filed on Dec. 25, 2020.

(30) Foreign Application Priority Data
Dec. 26, 2019 (JP) 2019-236078
Aug. 28, 2020 (JP) 2020-144790
Dec. 25, 2020 (JP) 2020-217111

(51) Int. Cl. G02B 1/04; C09B 57/00; C09B 23/14; G02B 5/22

(52) U.S. Cl. CPC G02B 1/04; C09B 57/007; C09B 23/145; G02B 5/22; G02F 1/133514

(57) ABSTRACT

There is provided a light absorption filter, an optical filter, an OLED display device, or a liquid crystal display device, containing a resin; a dye that has a main absorption wavelength band at a wavelength of 400 to 700 nm; and a compound that generates a radical upon ultraviolet irradiation, in which the dye includes a specific squarine-based coloring agent represented by General Formula (1) or a specific benzylidene-based coloring agent or cinnamylidene-based coloring agent represented by General formula (V).

### CROSS-REFERENCE TO RELATED APPLICATIONS

This application is a Continuation of PCT International Application No. PCT/JP2020/049006 filed on Dec. 25, 2020, which claims priority under 35 U.S.C. § 119 (a) to Japanese Patent Application No. 2019-236078 filed in Japan on Dec. 26, 2019, Japanese Patent Application No. 2020-144790 filed in Japan on Aug. 28, 2020, and Japanese Patent Application No. 2020-217111 filed in Japan on Dec. 25, 2020. Each of the above applications is hereby expressly incorporated by reference, in its entirety, into the present application.

### BACKGROUND OF THE INVENTION

### 1. Field of the Invention

The present invention relates to a light absorption filter, an optical filter, an organic electroluminescent display device, and a liquid crystal display device.

### 2. Description of the Related Art

As image display apparatuses, an organic electroluminescence (OLED) display device, a liquid crystal display device, and the like have been used in recent years.

A liquid crystal display device is widely used year by year as a space-saving image display apparatus with low power consumption. The liquid crystal display device is a non-light emitting element in which the liquid crystal panel itself on which an image is displayed does not emit light, and thus the liquid crystal display device includes a backlight unit which is disposed on a rear surface of the liquid crystal panel and supplies light to the liquid crystal panel.

The OLED display device is a device that displays an image by utilizing the self-luminescence of the OLED element. Therefore, the OLED display device has advantages that a high contrast ratio, a high color reproducibility, a wide viewing angle, a high-speed responsiveness, and reduction in thickness and weight can be achieved, as compared with various display devices such as a liquid crystal display device and a plasma display device. In addition to these advantages, in terms of flexibility, research and development are being actively carried out as a next-generation display device.

In the development of an image display apparatus, it is known a technique of incorporating a light absorption filter as a configuration.

For example, in a liquid crystal display device, in a case where a white light emitting diode (LED) is used as a light source for a backlight unit, an attempt has been made to provide a light absorption filter in order to block light having unnecessary wavelengths emitted from the white LED. Further, in the OLED display device, an attempt has been made to provide a light absorption filter from the viewpoint of suppressing the reflection of external light.

### SUMMARY OF THE INVENTION

As another form of the light absorption filter incorporated in the image display apparatus, it is possible to consider an optical filter having both a light absorptive portion having a light absorption effect and a portion in which the light absorption properties have been eliminated (hereinafter, also simply referred to as a “light absorption property-eliminated portion”), which is obtained by eliminating the light absorption properties of the desired part in a desired portion.

For example, JP1997-286979A (JP-H9-286979A) discloses a photo-decolorizable composition containing a dye and a compound that changes the color development mechanism of the dye upon ultraviolet irradiation, and being faded or decolorized upon ultraviolet irradiation.

However, it was found that a light absorption filter using the photo-decolorizable composition described in JP1997-286979A (JP-H9-286979A) together with a resin has a low quenching rate upon ultraviolet irradiation, and there is room for improvement. Moreover, it was also found that depending on a dye used, the dye is decomposed due to ultraviolet irradiation, and the absorption derived from a new coloration structure associated with this decomposition (hereinafter, also referred to as the “secondary absorption”) may occur, in addition to the fact the quenching rate is not sufficient.

In particular, in a form in which an optical filter is used by being incorporated in an image display apparatus, light absorption characteristics close to being colorless are required at a light absorption property-eliminated portion in the optical filter.

That is, an object of the present invention is to provide a light absorption filter that exhibits an excellent quenching rate in a case of being irradiated with an ultraviolet ray and hardly causes secondary absorption associated with the decomposition of the dye upon ultraviolet irradiation.

Further, another object of the present invention is to provide an optical filter using the above-described light absorption filter, where the optical filter includes an optical filter having a light absorptive portion and a light absorption property-eliminated portion at a desired position, and provide an OLED display device as well as a liquid crystal display device which include this optical filter.

As a result of diligent studies in consideration of the above objects, the inventors of the present invention have found that a configuration of a light absorption filter containing a dye that has a specific chemical structure and a compound that generates a radical upon ultraviolet irradiation makes it possible to obtain an excellent photoquenching property. Further studies have been carried out based on these findings, whereby the present invention has been completed.

That is, the above object has been achieved by the following means.

<1> A light absorption filter comprising a resin; a dye that has a main absorption wavelength band at a wavelength of 400 to 700 nm; and a compound that generates a radical upon ultraviolet irradiation, in which the dye includes a squarine-based coloring agent represented by General Formula (1),

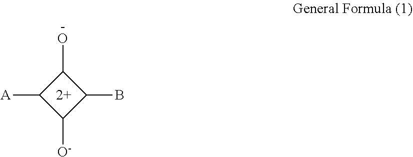

in the formula, A and B each independently represent an aryl group which may have a substituent, a heterocyclic group which may have a substituent, or —CH=G, and G represents a heterocyclic group which may have a substituent.

<2> A light absorption filter comprising: a resin; a dye that has a main absorption wavelength band at a wavelength of 400 to 700 nm; and a compound that generates a radical upon ultraviolet irradiation, in which the dye includes a benzylidene-based or cinnamylidene-based coloring agent represented by General Formula (V),

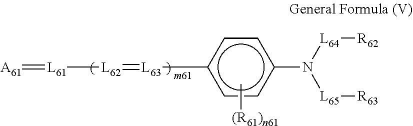

in the formula, A₆₁ represents an acidic nucleus. L₆₁, L₆₂, and L₆₃ each independently represent a methine group which may be substituted, L₆₄ and L₆₅ each independently represent an alkylene group having 1 to 4 carbon atoms. R₆₂ and R₆₃ each independently represent a cyano group, —COOR₆₄, —CONR₆₅R₆₆, —COR₆₄, —SO₂R₆₄, or —SO₂NR₆₅R₆₆, where R₆₄ represents an alkyl group, an alkenyl group, a cycloalkyl group, or an aryl group, R₆₅ and R₆₆ each independently represent a hydrogen atom, an alkyl group, an alkenyl group, a cycloalkyl group, or an aryl group, R₆₁ represents a substituent, m₆₁ is an integer of 0 or 1, and n₆₁ is an integer of 0 to 4.

<3> The light absorption filter according to <1> or <2>, in which the compound that generates a radical upon ultraviolet irradiation is a compound that generates a radical upon intramolecular cleavage.

<4> The light absorption filter according to <1> or <2>, in which the compound that generates a radical upon ultraviolet irradiation is a compound that abstracts a hydrogen atom from a compound present in a vicinity thereof to generate a radical.

<5> The light absorption filter according to <4>, in which the compound that abstracts a hydrogen atom from a compound present in a vicinity thereof to generate a radical is a benzophenone compound substituted with an alkoxy group.

<6> The light absorption filter according to any one of <1> to <5>, in which in the light absorption filter, the dye is chemically changed to be decolorized upon irradiation with light.

<7> An optical filter that is obtained by subjecting the light absorption filter according to any one of <1> to <6> to mask exposure by ultraviolet irradiation.

<8> An organic electroluminescent display device or a liquid crystal display device, comprising the optical filter according to <7>.

<9> The organic electroluminescent display device or the liquid crystal display device according to <8>, in which the organic electroluminescent display device or the liquid crystal display device has a layer, on a viewer side of the optical filter, which inhibits light absorption of the compound that generates a radical upon ultraviolet irradiation.

<10> A method of manufacturing an optical filter, comprising irradiating the light absorption filter according to any one of <1> to <6> with an ultraviolet ray to carry out mask exposure.

<11> The method of manufacturing an optical filter according to <10>, in which the irradiation with an ultraviolet ray is carried out under a condition of heating.

<12> The method of manufacturing an optical filter according to <11>, in which a temperature of the heating is a temperature that exceeds a glass transition temperature of the light absorption filter.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same as or different from each other unless otherwise specified. The same applies to the definition of the number of substituents or the like. In addition, in a case where a plurality of substituents and the like are close to each other (particularly in a case where the substituents and the like are adjacent to each other), the substituents and the like may also be linked to each other to form a ring unless otherwise specified. In addition, unless otherwise specified, rings, for example, alicyclic rings, aromatic rings, and heterocyclic rings may be further fused to form a fused ring.

In the present invention, unless otherwise specified, the light absorption filter may contain one kind of each of components constituting the light absorption filter (a dye, a resin, and a compound that generates a radical upon ultraviolet irradiation, as well as another component that may be appropriately contained) or may contain two or more kinds thereof. The same applies to an optical filter produced by using the light absorption filter of the present invention.

Unless otherwise specified, the optical filter of the present invention can preferably apply the description of the light absorption filter of the present invention, except that it has a light absorption property-eliminated portion formed by ultraviolet irradiation.

In the present invention, in a case where an E type double bond and a Z type double bond are present in a molecule, the double bond may be any one thereof or may be a mixture thereof, unless otherwise specified.

In the present invention, the representation of a compound (including a complex) is used to mean not only the compound itself but also a salt thereof, and an ion thereof. In addition, it is meant to include those in which a part of the structure is changed, as long as the effect of the present invention is not impaired. Furthermore, it is meant that a compound, which is not specified to be substituted or unsubstituted, may have any substituent, as long as the effect of the present invention is not impaired. The same applies to the definition of a substituent or a linking group.

In addition, in the present invention, the numerical range indicated by using “to” means a range including the numerical values before and after “to” as the lower limit value and the upper limit value, respectively.

In the present invention, the “composition” includes a mixture in which the component concentration varies within a range in which a desired function is not impaired, in addition to a mixture in which the component concentration is constant (each component is uniformly dispersed).

In the present invention, the description of “having a main absorption wavelength band at a wavelength XX to YY nm” means that a wavelength at which the maximum absorption is exhibited (that is, the maximal absorption wavelength) is present in the wavelength range of XX to YY nm. Therefore, in a case where the maximal absorption wavelength is present in the above-described wavelength range, the entire absorption band including this wavelength may be in the above-described wavelength range or may also extend up to the outside of the above-described wavelength range. In addition, in a case where there are a plurality of maximal absorption wavelengths, it suffices that a maximal absorption wavelength at which the highest absorbance is exhibited is present in the above-described wavelength range. That is, the maximal absorption wavelength other than the maximal absorption wavelength at which the highest absorbance is exhibited may be present in any wavelength regardless of the inside or the outside of the above-described wavelength range of XX to YY nm.

The light absorption filter of the present invention exhibits an excellent quenching rate in a case of being irradiated with an ultraviolet ray and hardly causes secondary absorption associated with the decomposition of the dye upon ultraviolet irradiation.

Further, the optical filter of the present invention, as well as the OLED display device and the liquid crystal display device of the present invention which include this optical filter, can have a light absorptive portion and a light absorption property-eliminated portion at a desired position.

### BRIEF DESCRIPTION OF THE DRAWINGS

FIG. 1 is a schematic view illustrating an outline of an embodiment of a liquid crystal display device including polarizing plates, which has a filter of the present invention in a backlight.

### DESCRIPTION OF THE PREFERRED EMBODIMENTS

[Light Absorption Filter]

A light absorption filter according to the embodiment of the present invention contains a resin; a dye that has a main absorption wavelength band at a wavelength of 400 to 700 nm (hereinafter, also simply referred to as “dye”); and a compound that generates a radical upon ultraviolet irradiation, in which the dye includes a squarine-based coloring agent represented by General Formula (1) or a benzylidene-based or cinnamylidene-based coloring agent represented by General formula (V).

In the present invention, the main absorption wavelength band of a dye is the main absorption wavelength band of the dye, which is measured in the state of being a light absorption filter. Specifically, in Examples described later, it is measured in a state of being a base material-attached light absorption filter under the conditions described in the section of the absorbance of the light absorption filter.

In the light absorption filter according to the embodiment of the present invention, the “dye” is dispersed (preferably dissolved) in the resin to make the light absorption filter a layer exhibiting a specific absorption spectrum derived from the dye. The dispersion may be random, regular, or the like.

Further, in a case where the above-described “compound that generates a radical upon ultraviolet irradiation” is dispersed (preferably dissolved) in a resin, it generates a radical in a case of being irradiated with an ultraviolet ray, and then the dye can be faded and decolorized by a mechanism in which the generated radical reacts with the dye. As will be described later, in a case where the compound that generates a radical upon ultraviolet irradiation is a compound (hereinafter, also referred to as a “hydrogen abstraction type photoradical generator”) that abstracts a hydrogen atom from a compound present in the vicinity thereof to generate a radical, the hydrogen abstraction type photoradical generator excited upon ultraviolet irradiation abstracts a hydrogen atom (a hydrogen radical) of a dye present in the vicinity thereof to generate a dye having a radical, and as a result, the dye can faded and decolorized.

The light absorption filter according to the embodiment of the present invention has a configuration in which a dye that has a specific chemical structure having a main absorption wavelength band at a wavelength of 400 to 700 nm and a compound that generates a radical upon ultraviolet irradiation are contained in a resin. In a case where the light absorption filter according to the embodiment of the present invention having such a configuration is irradiated with an ultraviolet ray, it exhibits an excellent quenching rate, and moreover, secondary absorption associated with the decomposition of the dye hardly occurs, and it can exhibit decolorization characteristics close to being colorless. The presumable reason for this is thought to be as follows.

In the light absorption filter according to the embodiment of the present invention, the compound that generates a radical upon ultraviolet irradiation generates radical species upon ultraviolet irradiation, and the radical species directly or indirectly reacts with a dye to decompose the dye, whereby the dye is faded or decolorized. Further, a hydrogen abstraction type photoradical generator excited upon ultraviolet irradiation generates a dye that has a radical through a hydrogen abstraction reaction, and the active dye undergoes a reaction, decomposition, or the like, whereby the dye can be faded or decolorized. In particular, the squarine-based coloring agent represented by General Formula (1) described later or the benzylidene-based or cinnamylidene-based coloring agent represented by General Formula (V) described later, which is contained in the light absorption filter according to the embodiment of the present invention has specific chemical structure, and thus the coloring agent can be decolorized with little secondary absorption associated with the decomposition of the dye.

Moreover, in the light absorption filter according to the embodiment of the present invention, the squarine-based coloring agent represented by General Formula (1) described later, as well as the benzylidene-based and cinnamylidene-based coloring agents represented by General Formula (V) described later can exhibit sharp absorption. As a result, in a case where the light absorption filter according to the embodiment of the present invention is used, the dye can be preferably used in the formation the optical filter according to the embodiment of the present invention which has a light absorptive portion having a light absorption effect and a light absorption property-eliminated portion, in a desired pattern.

As described above, in the light absorption filter according to the embodiment of the present invention, the dye is chemically changed to be decolorized upon irradiation with light (an ultraviolet ray). That is, the light absorption filter according to the embodiment of the present invention has a characteristic that the dye is chemically changed to be decolorized upon irradiation with light (an ultraviolet ray).

Therefore, the light absorption filter according to the embodiment of the present invention preferably does not contain a compound having an ethylenically unsaturated bond.

<Dye Having Main Absorption Wavelength Band at wavelength of 400 to 700 nm>

Specific examples of the dye that is used in the present invention having a main absorption wavelength band at a wavelength of 400 to 700 nm (hereinafter, also simply referred to as the “dye”) include tetraazaporphyrin (TAP)-based, squarine (SQ)-based, cyanine (CY)-based, benzylidene-based, and cinnamylidene-based coloring agents (dyes).

The dye that can be contained in the light absorption filter according to the embodiment of the present invention may be one kind or two or more kinds.

The light absorption filter according to the embodiment of the present invention may also contain a dye other than the above dye.

Among these, the light absorption filter according to the embodiment of the present invention contains, as the above-described dye, a squarine-based coloring agent represented by General Formula (1) described later or a benzylidene-based or cinnamylidene-based coloring agent represented by General Formula (V) described later from the viewpoint that a secondary coloration structure associated with the decomposition of the dye is hardly generated. In a case where a coloring agent that hardly generates the secondary coloration structure associated with the decomposition of the dye as described above is used as the dye, the portion irradiated with ultraviolet light can be efficiently made colorless.

Further, the above-described dye is preferably the squarine-based coloring agent represented by General Formula (1) described later or the benzylidene-based or cinnamylidene-based coloring agent represented by General Formula (V) described later from the viewpoint that the absorption waveform in the main absorption wavelength band is sharp. In a case where a coloring agent that has a sharp absorption waveform as described above is used as the dye, it is possible to minimize a decrease in the transmittance of the display light and prevent the reflection of external light.

That is, in a case where the squarine-based coloring agent represented by General Formula (1) described later or the benzylidene-based or cinnamylidene-based coloring agent represented by General Formula (V) described later is used as the above-described dye, it is possible to suitably produce the optical filter according to the embodiment of the present invention by subjecting the light absorption filter according to the embodiment of the present invention to mask exposure by ultraviolet irradiation.

In the present invention, in the coloring agent represented by each General Formula, a cation is present in a delocalized manner, and thus a plurality of tautomer structures are present. Therefore, in the present invention, in a case where at least one tautomer structure of a certain coloring agent matches with each general formula, the certain coloring agent shall be a coloring agent represented by the general formula. Therefore, a coloring agent represented by a specific general formula can also be said to be a coloring agent having at least one tautomer structure that can be represented by the specific general formula. In the present invention, a coloring agent represented by a general formula may have any tautomer structure as long as at least one tautomer structure of the coloring agent matches with the general formula.

(1) Squarine-Based Coloring Agent Represented by General Formula (1)

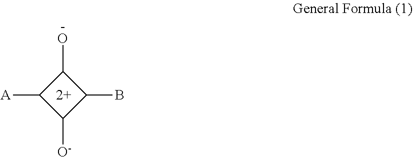

In General Formula (1), A and B each independently represent an aryl group which may have a substituent, a heterocyclic group which may have a substituent, or —CH=G. G represents a heterocyclic group which may have a substituent.

The aryl group that can be employed as A or B is not particularly limited and may be a group consisting of a single ring or a group consisting of a fused ring. The aryl group preferably has 6 to 30 carbon atoms, more preferably 6 to 20 carbon atoms, and still more preferably 6 to 12 carbon atoms. Examples of the aryl group include groups respectively consisting of a benzene ring and a naphthalene ring, and a group consisting of a benzene ring is more preferable.

The heterocyclic group that can be employed as A or B is not particularly limited, and examples thereof include a group consisting of an aliphatic heterocyclic ring or an aromatic heterocyclic ring. A group consisting of an aromatic heterocyclic ring is preferable. Examples of the heteroaryl group that is an aromatic heterocyclic group include a heteroaryl group that can be employed as a substituent X described below. The aromatic heterocyclic group that can be employed as A or B is preferably a group of a 5-membered ring or a 6-membered ring and more preferably a group of a nitrogen-containing 5-membered ring. Specific examples thereof suitably include a group consisting of any one of a pyrrole ring, a furan ring, a thiophene ring, an imidazole ring, a pyrazole ring, a thiazole ring, an oxazole ring, a triazole ring, an indole ring, an indolenine ring, an indoline ring, a pyridine ring, a pyrimidine ring, a quinoline ring, a benzothiazole ring, a benzoxazole ring, or a pyrazolotriazole ring. Among these, a group consisting of any one of a pyrrole ring, a pyrazole ring, a thiazole ring, a pyridine ring, a pyrimidine ring, or a pyrazolotriazole ring is preferable. The pyrazolotriazole ring consists of a fused ring of a pyrazole ring and a triazole ring and may be a fused ring obtained by fusing at least one pyrazole ring and at least one triazole ring. Examples thereof include fused rings in General Formulae (4) and (5) described below.

A and B may be bonded to a squaric acid moiety (the 4-membered ring represented by General Formula (1)) at any moiety (ring-constituting atom) without particular limitation and is preferable to be bonded to a carbon atom.

G in —CH=G that can be employed as A or B represents a heterocyclic group which may have a substituent, and examples thereof suitably include examples shown in the heterocyclic group that can be employed as A or B. Among these, a group consisting of any one of a benzoxazole ring, a benzothiazole ring, an indoline ring, or the like is preferable.

At least one of A or B may have a hydrogen bonding group that forms an intramolecular hydrogen bond.

Each of A, B, and G may have the substituent X, and, in a case where A, B, or G has the substituent X, adjacent substituents may be bonded to each other to further form a ring structure. In addition, a plurality of substituents X may be present.

Examples of the substituent X include substituents that can be employed as R¹ in General Formula (2) described below. Specific examples thereof include a halogen atom, a cyano group, a nitro group, an alkyl group (including a cycloalkyl group), an alkenyl group, an alkynyl group, an aryl group, a heteroaryl group, an aralkyl group, and a ferrocenyl group, —OR¹⁰, —C(═O)R¹¹, —C(═O)OR¹², —OC(═O)R¹³, —NR¹⁴R¹⁵, —NHCOR¹⁶, —CONR¹⁷R¹⁸, —NHCONR¹⁹R²⁰, —NHCOOR²¹, —SR²², —SO₂R²³, —SO₃R²⁴, —NHSO₂R²⁵, and SO₂NR²⁶R²⁷. Further, it is also preferable that the substituent X has a quencher moiety described later, in addition to the ferrocenyl group.

In General Formula (1), R¹⁰ to R²⁷ each independently represent a hydrogen atom, an aliphatic group, an aromatic group, or a heterocyclic group. The aliphatic group and the aromatic group, which can be employed as R¹⁰ to R²⁷, are not particularly limited, and they can be appropriately selected from an alkyl group, a cycloalkyl group, an alkenyl group, and an alkynyl group, which are classified as the aliphatic group, and an aryl group which is classified as the aromatic group, in the substituent that can be employed as R¹ in General Formula (2) described later. The heterocyclic group that can be employed as R¹⁰ to R²⁷ may be aliphatic or aromatic, and it can be appropriately selected from heteroaryl groups or heterocyclic groups that can be employed as R¹ in General Formula (2) described below.

It is noted that in a case where R¹² of —COOR¹² is a hydrogen atom (that is, a carboxy group), the hydrogen atom may be dissociated (that is, a carbonate group) or may be in a salt state. In addition, in a case where R²⁴ of —SO₃R²⁴ is a hydrogen atom (that is, a sulfo group), the hydrogen atom may be dissociated (that is, a sulfonate group) or may be in a salt state.

Examples of the halogen atom that can be employed as the substituent X include a fluorine atom, a chlorine atom, a bromine atom, and an iodine atom.

The alkyl group that can be employed as the substituent X preferably has 1 to 20 carbon atoms, more preferably 1 to 15 carbon atoms, and still more preferably 1 to 8 carbon atoms. The alkenyl group preferably has 2 to 20 carbon atoms, more preferably 2 to 12 carbon atoms, and still more preferably 2 to 8 carbon atoms. The alkynyl group preferably has 2 to 40 carbon atoms, more preferably 2 to 30 carbon atoms, and particularly preferably 2 to 25 carbon atoms. The alkyl group, the alkenyl group, and the alkynyl group each may be linear, branched, or cyclic, and they are preferably linear or branched.

The aryl group that can be employed as the substituent X includes a monocyclic group or a fused ring group. The aryl group preferably has 6 to 30 carbon atoms, more preferably 6 to 20 carbon atoms, and still more preferably 6 to 12 carbon atoms.

An alkyl portion in the aralkyl group that can be employed as the substituent X is the same as that in the alkyl group. An aryl portion in the aralkyl group is the same as that in the aryl group. The aralkyl group preferably has 7 to 40 carbon atoms, more preferably 7 to 30 carbon atoms, and still more preferably 7 to 25 carbon atoms.

The heteroaryl group that can be employed as the substituent X include a group consisting of a single ring or a fused ring, a group consisting of a single ring or a fused ring having 2 to 8 rings is preferable, and a group consisting of a single ring or a fused ring having 2 to 4 rings is more preferable. The number of heteroatoms constituting the ring of the heteroaryl group is preferably 1 to 3. Examples of the heteroatom constituting the ring of the heteroaryl group include a nitrogen atom, an oxygen atom, and a sulfur atom. The heteroaryl group is preferably a group having a 5-membered ring or a 6-membered ring. The number of carbon atoms constituting the ring in the heteroaryl group is preferably 3 to 30, more preferably 3 to 18, and still more preferably 3 to 12. Examples of the heteroaryl group include each group consisting of any one of a pyridine ring, a piperidine ring, a furan ring, a furfuran ring, a thiophene ring, a pyrrole ring, a quinoline ring, a morpholine ring, an indole ring, an imidazole ring, a pyrazole ring, a carbazole ring, a phenothiazine ring, a phenoxazine ring, an indoline ring, a thiazole ring, a pyrazine ring, a thiadiazine ring, a benzoquinoline ring, or a thiadiazole ring.

The ferrocenyl group that can be employed as the substituent X is preferably represented by General Formula (2M).

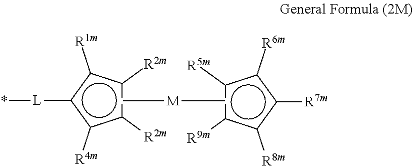

In General Formula (2M), L represents a single bond or a divalent linking group that does not conjugate with A, B, or G in General Formula (1). R^{1m} to R^{9m} each independently represent a hydrogen atom or a substituent. M represents an atom that can constitute a metallocene compound and represents Fe, Co, Ni, Ti, Cu, Zn, Zr, Cr, Mo, Os, Mn, Ru, Sn, Pd, Rh, V, or Pt. * represents a bonding site to A, B, or G.

In the present invention, in a case where L in General Formula (2M) is a single bond, a cyclopentadienyl ring directly bonded to A, B, or G (a ring having R^{1m} in General Formula (2M)) is not included in the conjugated structure which conjugates with A, B, or G.

The divalent linking group that can be employed as L is not particularly limited as long as it is a linking group that does not conjugate with A, B, or G, and it may have a conjugated structure in the inside thereof or at a cyclopentadiene ring side end part in General Formula (2M). Examples of the divalent linking group include an alkylene group having 1 to 20 carbon atoms, an arylene group having 6 to 20 carbon atoms, a divalent heterocyclic group obtained by removing two hydrogens from the heterocyclic ring, —CH═CH—, —CO—, —CS—, —NR— (R represents a hydrogen atom or a monovalent substituent), —O—, —S—, —SO₂—, or —N═CH—, or a divalent linking group formed by combining a plurality (preferably, 2 to 6) of these groups. The divalent linking group is preferably a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a divalent linking group in which two or more (preferably 2 to 6) selected from the above group are combined, and it is particularly preferably a group selected from the group consisting of an alkylene group having 1 to 4 carbon atoms, a phenylene group, —CO—, —NH—, —O—, and —SO₂—, or a linking group in which two or more (preferably 2 to 6) selected from the above group are combined. The divalent linking group combined is not particularly limited, and is preferably a group containing —CO—, —NH—, —O—, or —SO₂—, and examples thereof include a linking group formed by combining two or more of —CO—, —NH—, —O—, or —SO₂—, or a linking group obtained by combining at least one of —CO—, —NH—, —O—, or —SO₂— and an alkylene group or an arylene group. Examples of the linking group formed by combining two or more of —CO—, —NH—, —O—, or —SO₂— include —COO—, —OCO—. —CONH—, —NHCOO—, —NHCONH—, and —SO₂NH—. Examples of the linking group formed by combining at least one of —CO—, —NH—, —O—, or —SO₂— and an alkylene group or an arylene group include a group in which —CO—, —COO—, or —CONH— and an alkylene group or an arylene group are combined.

The substituent that can be employed as R is not particularly limited, and it has the same meaning as the substituent X which may be contained in A in General Formula (2).

L is preferably a single bond or a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined.

L may have one or a plurality of substituents. The substituent which may be contained in L is not particularly limited, and for example, it has the same meaning as the substituent X. In a case where L has a plurality of substituents, the substituents bonded to adjacent atoms may be bonded to each other to further form a ring structure.

The alkylene group that can be employed as L may be linear, branched, or cyclic as long as the group has 1 to 20 carbon atoms, and examples thereof include methylene, ethylene, propylene, methylethylene, methylmethylene, dimethylmethylene, 1,1-dimethylethylene, butylene, 1-methylpropylene, 2-methylpropylene, 1,2-dimethylpropylene, 1,3-dimethylpropylene, 1-methylbutylene, 2-methylbutylene, 3-methylbutylene, 4-methylbutylene, 2,4-dimethylbutylene, 1,3-dimethylbutylene, pentylene, hexylene, heptylene, octylene, ethane-1,1-diyl, propane-2,2-diyl, cyclopropane-1,1-diyl, cyclopropane-1,2-diyl, cyclobutane-1,1-diyl, cyclobutane-1,2-diyl, cyclopentane-1,1-diyl, cyclopentane-1,2-diyl, cyclopentane-1,3-diyl, cyclohexane-1,1-diyl, cyclohexane-1,2-diyl, cyclohexane-1,3-diyl, cyclohexane-1,4-diyl, and methylcyclohexane-1,4-diyl. In a case where a linking group containing at least one of —CO—, —CS—, —NR— (R is as described above), —O—, —S—, —SO₂—, or —N═CH— in the alkylene group is employed as L, the group such as —CO— may be incorporated at any site in the alkylene group, and the number of the groups incorporated is not particularly limited.

The arylene group that can be employed as L is not particularly limited as long as the group has 6 to 20 carbon atoms, and examples thereof include a group obtained by further removing one hydrogen atom from each group exemplified as the aryl group having 6 to 20 carbon atoms that can be employed as A in General Formula (1).

The heterocyclic group that can be employed as L is not particularly limited, and examples thereof include a group obtained by further removing one hydrogen atom from each group exemplified as the heterocyclic group that can be employed as A.

In General Formula (2M), the remaining partial structure excluding the linking group L corresponds to a structure (metallocene structure portion) in which one hydrogen atom is removed from the metallocene compound. In the present invention, for the metallocene compound serving as the metallocene structure portion, a known metallocene compound can be used without particular limitation, as long as it is a compound conforming to the partial structure defined by General Formula (2M) (a compound in which a hydrogen atom is bonded instead of L). Hereinafter, the metallocene structure portion defined by General Formula (2M) will be specifically described.

In General Formula (2M), R^{1m} to R^{9m} each independently represent a hydrogen atom or a substituent. The substituents that can be employed as R^{1m} to R^{9m} are not particularly limited, and can be selected from, for example, the substituents that can be employed as R¹ in General Formula (3). R^{1m} to R^{9m} each are preferably a hydrogen atom, a halogen atom, an alkyl group, an acyl group, an alkoxy group, an amino group, or an amide group, more preferably a hydrogen atom, a halogen atom, an alkyl group, an acyl group, or an alkoxy group, still more preferably a hydrogen atom, a halogen atom, an alkyl group, or an acyl group, particularly preferably a hydrogen atom, a halogen atom, or an alkyl group, and most preferably a hydrogen atom.

As the alkyl group that can be employed as R^{1m} to R^{9m}, among the alkyl groups that can be employed as R¹, an alkyl group having 1 to 8 carbon atoms is preferable, and examples thereof include methyl, ethyl, propyl, isopropyl, butyl, sec-butyl, tert-butyl, isobutyl, pentyl, tert-pentyl, hexyl, octyl, and 2-ethylhexyl.

This alkyl group may have a halogen atom as a substituent. Examples of the alkyl group substituted with a halogen atom include, for example, chloromethyl, dichloromethyl, trichloromethyl, bromomethyl, dibromomethyl, tribromomethyl, fluoromethyl, difluoromethyl, trifluoromethyl, 2,2,2-trifluoroethyl, perfluoroethyl, perfluoropropyl, perfluorobutyl. In addition, in the alkyl group that can be employed as Rim or the like, at least one methylene group that forms a carbon chain may be substituted with —O— or —CO—. Examples of the alkyl group in which the methylene group is substituted with —O— include, for example, an alkyl group in which the end part methylene group of methoxy, ethoxy, propoxy, isopropoxy, isobutoxy, sec-butoxy, tert-butoxy, 2-methoxyethoxy, chloromethyloxy, dichloromethyloxy, trichloromethyloxy, bromomethyloxy, dibromomethyloxy, tribromomethyloxy, fluoromethyloxy, difluoromethyloxy, trifluoromethyloxy, 2,2,2-trifluoroethyloxy, perfluoroethyloxy, perfluoropropyloxy, or perfluorobutyloxy is substituted, and an alkyl group in which an internal methylene group of the carbon chain such as 2-methoxyethyl or the like is substituted. Examples of the alkyl group in which a methylene group is substituted with —CO— include, for example, acetyl, propionyl, monochloroacetyl, dichloroacetyl, trichloroacetyl, trifluoroacetyl, propane-2-one-1-yl, butane-2-one-1-yl.

In General Formula (2M), M represents an atom that can constitute a metallocene compound, and represents Fe, Co, Ni, Ti, Cu, Zn, Zr, Cr, Mo, Os, Mn, Ru, Sn, Pd, Rh, V, or Pt. Among these, M is preferably Fe, Ti, Co, Ni, Zr, Ru, or Os, more preferably Fe, Ti, Ni, Ru, or Os, still more preferably Fe or Ti, and most preferably Fe.

The group represented by General Formula (2M) is preferably a group formed by combining preferred ones of L, R^{1m} to R^{9m}, and M. Examples thereof include a group formed by combining, as L, a single bond, or a group selected from the group consisting of an alkylene group having 2 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined; as R^{1m} to R^{9m}, a hydrogen atom, a halogen atom, an alkyl group, an acyl group, or an alkoxy group; and as M, Fe.

The alkyl group, the alkenyl group, the alkynyl group, the aralkyl group, the aryl group, and the heteroaryl group which can be employed as the substituent X and the aliphatic group, the aromatic group, and the heterocyclic group which can be employed as R¹⁰ to R²⁷ each may further have a substituent or may be unsubstituted. The substituent which may be further contained therein is not particularly limited, and it is preferably a substituent selected from an alkyl group, an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfonylamino group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group, and it is more preferably a substituent selected from an alkyl group, an aryl group, an alkoxy group, an aryloxy group, an aromatic heterocyclic oxy group, an acyl group, an alkoxycarbonyl group, an aryloxycarbonyl group, an acyloxy group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group. This group can be appropriately selected from the substituents that can be employed as R¹ in General Formula (2) described below.

One preferred embodiment of the coloring agent represented by General Formula (1) includes a coloring agent represented by General Formula (2).

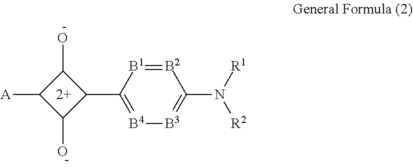

In General Formula (2), A¹ is the same as A in General Formula (1). Among these, a heterocyclic group which is a nitrogen-containing 5-membered ring is preferable.

In General Formula (2), R¹ and R² each independently represent a hydrogen atom or a substituent. R¹ and R² may be the same as or different from each other, and they may be bonded together to form a ring.

The substituents that can be employed as R¹ and R² are not particularly limited, and examples thereof include an alkyl group (a methyl group, an ethyl group, a propyl group, an isopropyl group, a butyl group, a t-butyl group, an isobutyl group, a pentyl group, a hexyl group, an octyl group, a dodecyl group, a trifluoromethyl group, or the like), a cycloalkyl group (a cyclopentyl group, a cyclohexyl group, or the like), an alkenyl group (a vinyl group, an allyl group, or the like), an alkynyl group (an ethynyl group, a propargyl group, or the like), an aryl group (a phenyl group, a naphthyl group, or the like), a heteroaryl group (a furyl group, a thienyl group, a pyridyl group, a pyridazyl group, a pyrimidyl group, a pyrazyl group, a triazyl group, an imidazolyl group, a pyrazolyl group, a thiazolyl group, a benzoimidazolyl group, a benzoxazolyl group, a quinazolyl group, a phthalazyl group, or the like), a heterocyclic group (also referred to as heterocyclic groups, for example, a pyrrolidyl group, an imidazolidyl group, a morpholyl group, an oxazolidyl group, or the like), an alkoxy group (a methoxy group, an ethoxy group, a propyloxy group, or the like), a cycloalkoxy group (a cyclopentyloxy group, a cyclohexyloxy group, or the like), an aryloxy group (a phenoxy group, a naphthyloxy group, or the like), a heteroaryloxy group (an aromatic heterocyclic oxy group), alkylthio group (a methylthio group, an ethylthio group, a propylthio group, or the like), a cycloalkylthio group (a cyclopentylthio group, a cyclohexylthio group, or the like), an arylthio group (a phenythio group, a naphthylthio group, or the like), a heteroarylthio group (an aromatic heterocyclic thio group), alkoxycarbonyl group (a methyloxycarbonyl group, an ethyloxycarbonyl group, a butyloxycarbonyl group, an octyloxycarbonyl group, or the like), an aryloxycarbonyl group (a phenyloxycarbonyl group, a naphthyloxycarbonyl group, or the like), a phosphoryl group (dimethoxyphosphonyl or diphenylphosphoryl, a sulfamoyl group (an aminosulfonyl group, a methylaminosulfonyl group, a dimethylaminosulfonyl group, a butylaminosulfonyl group, a cyclohexylaminosulfonyl group, an octylaminosulfonyl group, a phenylaminosulfonyl group, a 2-pyridylaminosulfonyl group, or the like), an acyl group (an acetyl group, an ethylcarbonyl group, a propylcarbonyl group, a cyclohexylcarbonyl group, an octylcarbonyl group, a 2-ethylhexylcarbonyl group, a phenylcarbonyl group, a naphthylcarbonyl group, a pyridylcarbonyl group, or the like), an acyloxy group (an acetyloxy group, an ethylcarbonyloxy group, a butylcarbonyloxy group, an octylcarbonyloxy group, a phenylcarbonyloxy group, or the like), an amide group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, or the like), a sulfonylamide group (a methylsulfonylamino group, an octylsulfonylamino group, a 2-ethylhexylsulfonylamino group, a trifluoromethylsulfonylamino group, or the like), a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, or the like), a ureido group (a methylureido group, an ethylureido group, a pentylureido group, a cyclohexylureido group, an octylureido group, a dodecylureido group, a phenylureido group, a naphthylureido group, a 2-pyridylaminoureido group, or the like), an alkylsulfonyl group (a methylsulfonyl group, an ethylsulfonyl group, a butylsulfonyl group, a cyclohexylsulfonyl group, a 2-ethylhexylsulfonyl group, or the like), an arylsulfonyl group (a phenylsulfonyl group, a naphthylsulfonyl group, a 2-pyridylsulfonyl group, or the like), an amino group (an amino group, an ethylamino group, a dimethylamino group, a butylamino group, a dibutylamino group, a cyclopentylamino group, a 2-ethylhexylamino group, a dodecylamino group, an anilino group, a naphthylamino group, a 2-pyridylamino group, or the like), an alkylsulfonyloxy group (methanesulfonyloxy), a cyano group, a nitro group, halogen atoms (a fluorine atom, a chlorine atom, a bromine atom, or the like), and a hydroxy group.

Among these, an alkyl group, an alkenyl group, an aryl group, or a heteroaryl group is preferable, an alkyl group, an aryl group, or a heteroaryl group is more preferable, and an alkyl group is still more preferable.

The substituent that can be employed as R¹ and R² may further have a substituent. Examples of the substituent which may be further contained therein include the substituent that can be employed as R¹ and R², and the substituent X which may be contained in A, B, and G in General Formula described above. In addition, R¹ and R² may be bonded to each other to form a ring, and R¹ or R² and the substituent of B² or B³ may be bonded to each other to form a ring.

The ring that is formed in this case is preferably a heterocyclic ring or a heteroaryl ring, and it is preferably a 5-membered ring or a 6-membered ring although the size of the ring to be formed is not particularly limited. Further, the number of rings to be formed is not particularly limited, and it may be one or two or more. Examples of the form in which two or more rings are formed include a form in which the substituents of R¹ and B² and the substituents of R² and B³ are respectively bonded to each other to form two rings.

In General Formula (2), B¹, B², B³, and B⁴ each independently represent a carbon atom or a nitrogen atom. The ring including B¹, B², B³, and B⁴ is an aromatic ring. It is preferable that at least two or more of B¹ to B⁴ are a carbon atom, and it is more preferable that all of B¹ to B⁴ are a carbon atom.

The carbon atom that can be employed as B¹ to B⁴ has a hydrogen atom or a substituent. Among carbon atoms that can be employed as B¹ to B⁴, the number of carbon atoms having a substituent is not particularly limited; however, it is preferably zero, one, or two, and more preferably one. Particularly, it is preferable that B¹ and B⁴ are a carbon atom and at least one of them has a substituent.

The substituent possessed by the carbon atom that can be employed as B¹ to B⁴ is not particularly limited, and examples thereof include the above-described substituents that can be employed as R¹ and R². Among these, it is preferably an alkyl group, an alkoxy group, an alkoxycarbonyl group, an aryl group, an acyl group, an amide group, a sulfonylamide group, a carbamoyl group, an alkylsulfonyl group, an arylsulfonyl group, an amino group, a cyano group, a nitro group, a halogen atom, or a hydroxy group, and it is more preferably an alkyl group, an alkoxy group, an alkoxycarbonyl group, an aryl group, an acyl group, an amide group, a sulfonylamide group, a carbamoyl group, an amino group, a cyano group, a nitro group, a halogen atom, or a hydroxy group.

The substituent possessed by the carbon atom that can be employed as B¹ to B⁴ may further have a substituent. The substituents that may be further possessed by the carbon atom include the substituent which may be further contained in R¹ and R² in General Formula (2) described above and the substituent X which may be contained in A, B, and G in General Formula (1) described above, where a ferrocenyl group is preferable.

Examples of the substituent that can be possessed by the carbon atom that can be employed as B¹ and B⁴ still more preferably include an alkyl group, an alkoxy group, a hydroxy group, an amide group, a sulfonylamide group, or a carbamoyl group, and particularly preferably an alkyl group, an alkoxy group, a hydroxy group, an amide group, or a sulfonylamide group, and a hydroxy group, an amide group, or a sulfonylamide group is most preferable. The substituent possessed by the carbon atom that can be employed as B¹ and B⁴ may further have a ferrocenyl group.

It is still more preferable that the substituent that can be possessed by the carbon atom that can be employed as B² and B³ is an alkyl group, an alkoxy group, an alkoxycarbonyl group, an acyl group, an amino group, a cyano group, a nitro group, or a halogen atom, and it is particularly preferable that the substituent as any one of B² or B³ is an electron withdrawing group (for example, an alkoxycarbonyl group, an acyl group, a cyano group, a nitro group, or a halogen atom).

The coloring agent represented by General Formula (2) is preferably a coloring agent represented by any one of General Formulae (3), (4), or (5).

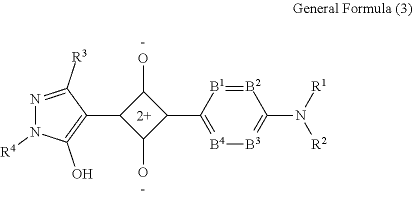

In General Formula (3), R¹ and R² each independently represent a hydrogen atom or a substituent, and they respectively have the same meanings as R¹ and R² in General Formula (2), where the same applies to the preferred ranges thereof.

In General Formula (3), B¹ to B⁴ each independently represent a carbon atom or a nitrogen atom, and they have respectively the same meanings as B¹ to B⁴ in General Formula (2), where the same applies to the preferred ranges thereof.

In General Formula (3), R³ and R each independently represent a hydrogen atom or a substituent. The substituent that can be employed as R³ and R⁴ is not particularly limited, and examples thereof include the same ones as the substituents that can be employed as R¹ and R².

However, the substituent that can be employed as R³ is preferably an alkyl group, an alkoxy group, an amino group, an amide group, a sulfonylamide group, a cyano group, a nitro group, an aryl group, a heteroaryl group, a heterocyclic group, an alkoxycarbonyl group, a carbamoyl group, or a halogen atom, more preferably an alkyl group, an aryl group, or an amino group, and still more preferably an alkyl group. This substituent that can be employed as R³ may further have a ferrocenyl group.

The substituent that can be employed as R⁴ is preferably an alkyl group, an aryl group, a heteroaryl group, a heterocyclic group, an alkoxy group, an alkoxycarbonyl group, an acyl group, an acyloxy group, an amide group, a carbamoyl group, an amino group, or a cyano group, more preferably an alkyl group, an alkoxycarbonyl group, an acyl group, a carbamoyl group, or an aryl group, and still more preferably an alkyl group.

The alkyl group that can be employed as R³ and R⁴ may be linear, branched, or cyclic, and it is preferably linear or branched. The alkyl group preferably has 1 to 12 carbon atoms and more preferably 1 to 8 carbon atoms. An example of the alkyl group is preferably a methyl group, an ethyl group, an n-propyl group, an isopropyl group, a t-butyl group, a 2-ethylhexyl group, or a cyclohexyl group, and more preferably a methyl group or a t-butyl group.

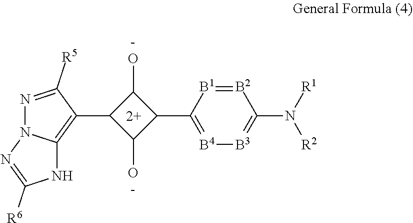

In General Formula (4), R¹ and R² each independently represent a hydrogen atom or a substituent, and they respectively have the same meanings as R¹ and R² in General Formula (2), where the same applies to the preferred ranges thereof.

In General Formula (4), B¹ to B⁴ each independently represent a carbon atom or a nitrogen atom, and they have respectively the same meanings as B¹ to B⁴ in General Formula (2), where the same applies to the preferred ranges thereof.

In General Formula (4), R⁴ and R⁶ each independently represent a hydrogen atom or a substituent. The substituent that can be employed as R³ and R⁶ is not particularly limited, and examples thereof include the same ones as the substituents that can be employed as R¹ and R².

However, the substituent that can be employed as R⁵ is preferably an alkyl group, an alkoxy group, an aryloxy group, an amino group, a cyano group, an aryl group, a heteroaryl group, a heterocyclic group, an acyl group, an acyloxy group, an amide group, a sulfonylamide group, an ureido group, or a carbamoyl group, more preferably an alkyl group, an alkoxy group, an acyl group, an amide group, or an amino group, and still more preferably an alkyl group.

The alkyl group that can be employed as R⁵ has the same meaning as the alkyl group that can be employed as R³ in General Formula (3), and the same applies to the preferred range thereof.

In General Formula (4), the substituent that can be employed as R⁶ is preferably an alkyl group, an alkenyl group, an aryl group, a heteroaryl group, a heterocyclic group, an alkoxy group, a cycloalkoxy group, an aryloxy group, an alkoxycarbonyl group, an acyl group, an acyloxy group, an amide group, a sulfonylamide group, an alkylsulfonyl group, an arylsulfonyl group, a carbamoyl group, an amino group, a cyano group, a nitro group, or a halogen atom, more preferably an alkyl group, an aryl group, a heteroaryl group, or a heterocyclic group, and still more preferably an alkyl group or an aryl group.

The alkyl group that can be employed as R⁶ has the same meaning as the alkyl group that can be employed as R⁴ in General Formula (3), and the same applies to the preferred range thereof.

The aryl group that can be employed as R⁶ is preferably an aryl group having 6 to 12 carbon atoms, and more preferably a phenyl group. This aryl group may have a substituent, examples of the substituent include a group included in the following substituent group A, and an alkyl group, a sulfonyl group, an amino group, an acylamino group, a sulfonylamino group, or the like, which have 1 to 10 carbon atoms, is particularly preferable. This substituent may further have a substituent. Specifically, the substituent is preferably an alkylsulfonylamino group.

—Substituent Group A—

A halogen atom, an alkyl group, an alkenyl group, an alkynyl group, an aryl group, a heterocyclic group, a cyano group, a hydroxy group, a nitro group, a carboxy group, an alkoxy group, an aminooxy group, an aryloxy group, a silyloxy group, a heterocyclic oxy group, an acyloxy group, a carbamoyloxy group, an amino group, an acylamino group, an aminocarbonylamino group, an alkoxycarbonylamino group, an aryloxycarbonylamino group, a sulfamoylamino group, a sulfonylamino group (including an alkyl or arylsulfonylamino group), a mercapto group, an alkylthio group, an arylthio group, a heterocyclic thio group, a sulfamoyl group, a sulfo group, an alkyl or arylsulfonyl group, a sulfonyl group (including an alkyl or arylsulfinyl group), an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a silyl group, and the like.

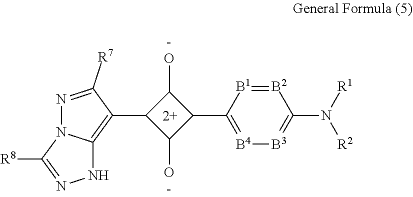

In General Formula (5), R¹ and R² each independently represent a hydrogen atom or a substituent, and they respectively have the same meanings as R¹ and R² in General Formula (2), where the same applies to the preferred ranges thereof.

In General Formula (5), B¹ to B⁴ each independently represent a carbon atom or a nitrogen atom, and they have respectively the same meanings as B¹ to B⁴ in General Formula (2), where the same applies to the preferred ranges thereof.

In General Formula (5), R⁷ and R each independently represent a hydrogen atom or a substituent. The substituent that can be employed as R¹ and R is not particularly limited, and examples thereof include the same ones as the substituents that can be employed as R¹ and R².

However, the preferred range, the more preferred range, and the still more preferred range of the substituent that can be employed as R⁷ are the same as those of the substituent that can be employed as R⁵ in General Formula (4). The alkyl group that can be employed as R⁵ has the same meaning as the alkyl group that can be employed as R³, and the same applies to the preferred range thereof.

In General Formula (5), the preferred range, the more preferred range, and the still more preferred range of the substituent that can be employed as R are the same as those of the substituent that can be employed as R⁶ in General Formula (4). The preferred ranges of the alkyl group and the aryl group that can be employed as Re have the same meaning as the alkyl group and the aryl group that can be employed as R⁶ in General Formula (4), where the same applies to the preferred ranges thereof.

As the squarine-based coloring agent that is used for the above dye, any squarine-based coloring agent represented by any one of General Formulae (1) to (5) can be used without particular limitation. Examples thereof include compounds described in, for example, JP2006-160618A, WO2004/005981A, WO2004/007447A, Dyes and Pigment, 2001, 49, p. 161 to 179, WO2008/090757A, WO2005/121098A, and JP2008-275726A.

Hereinafter, specific examples of the coloring agent represented by any one of General Formula (1) to General Formula (5) will be shown. However, the present invention is not limited thereto.

In the following specific examples, Me represents methyl, Et represents ethyl. Bu represents butyl, and Ph represents phenyl, respectively.

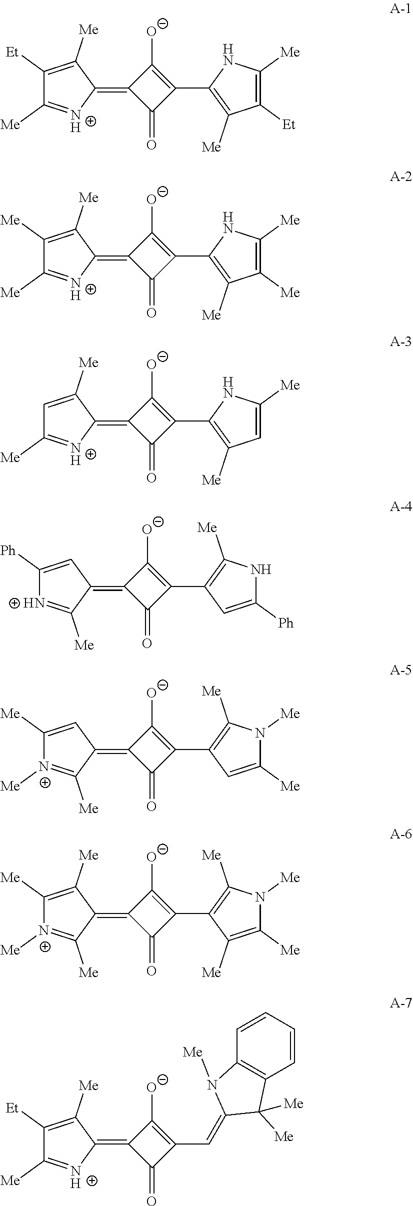

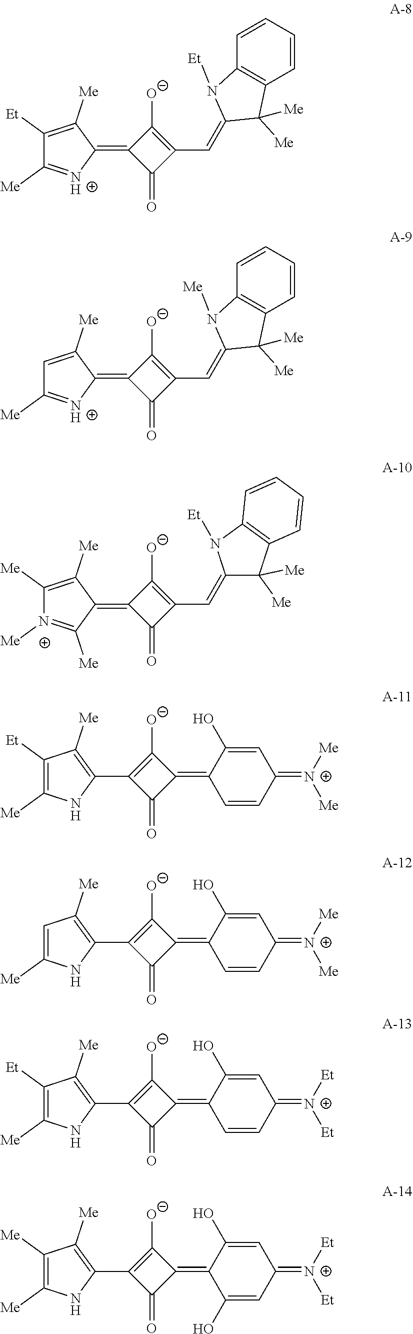

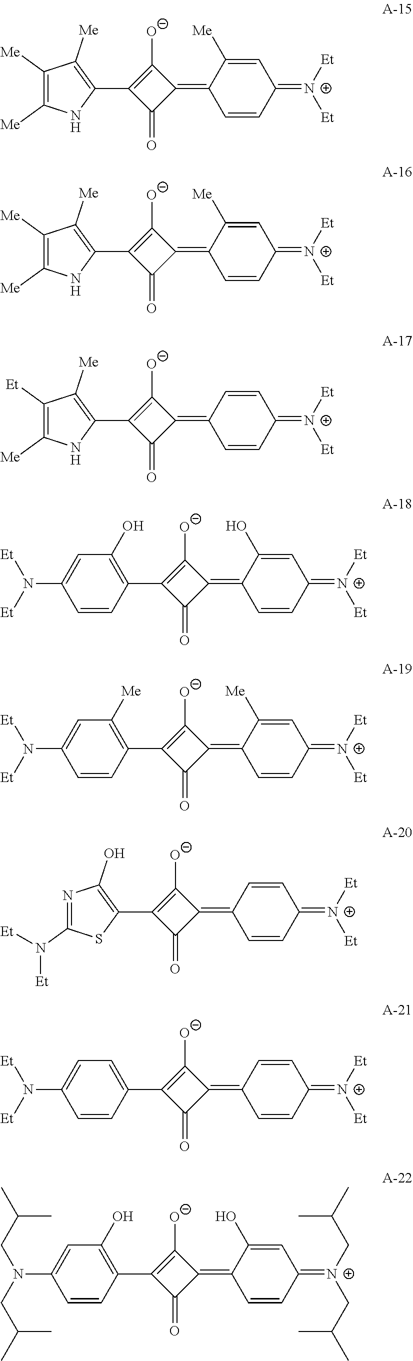

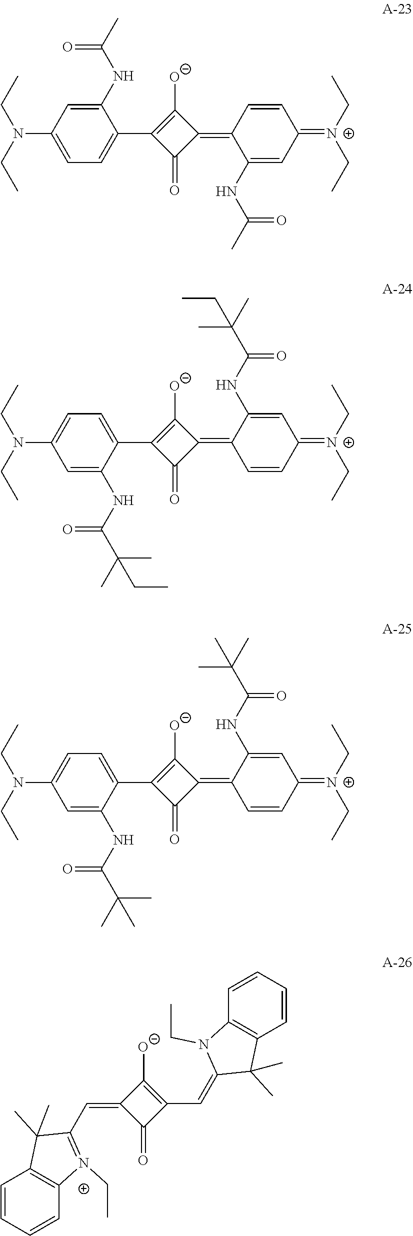

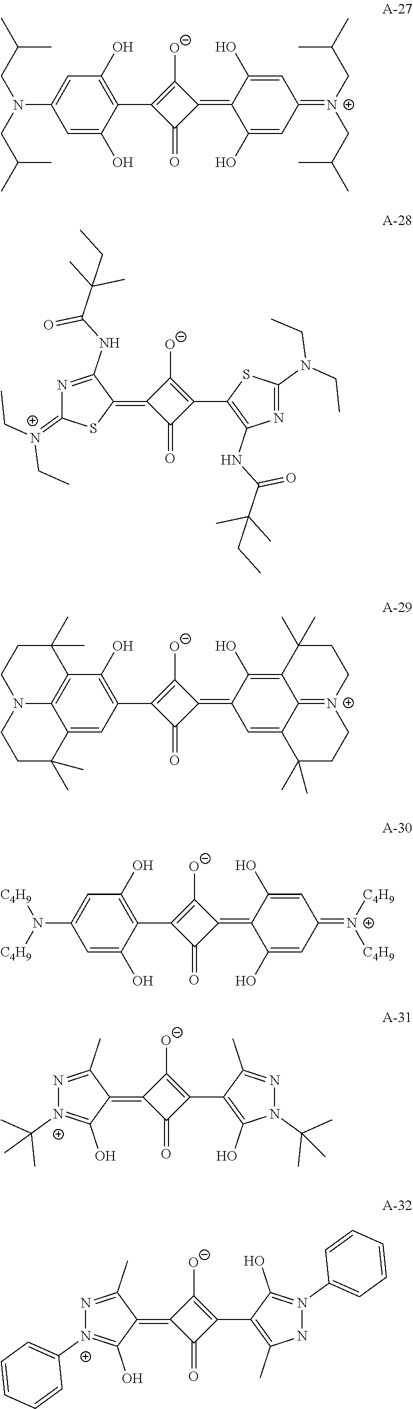

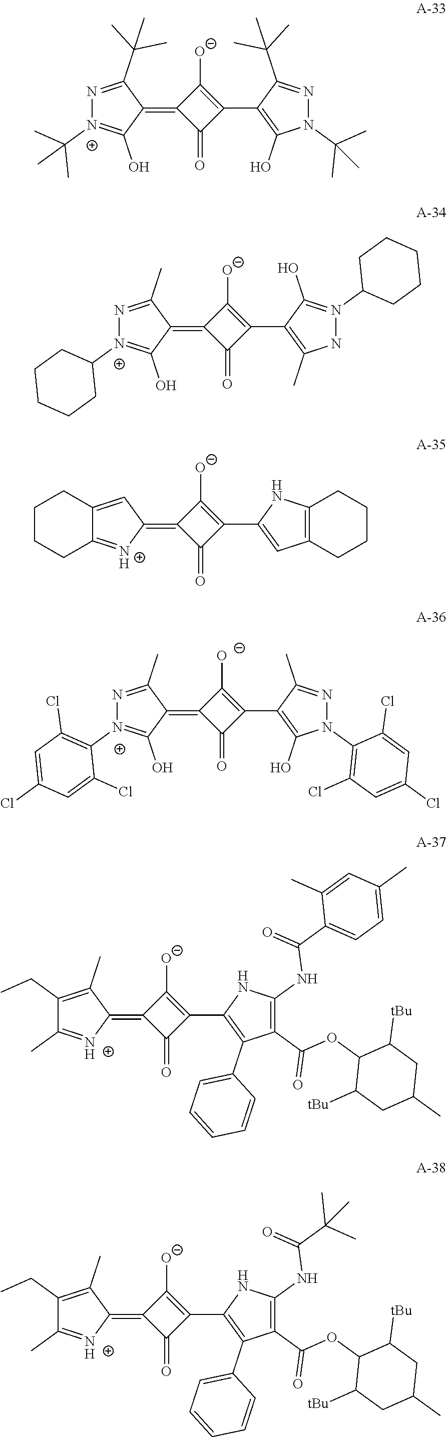

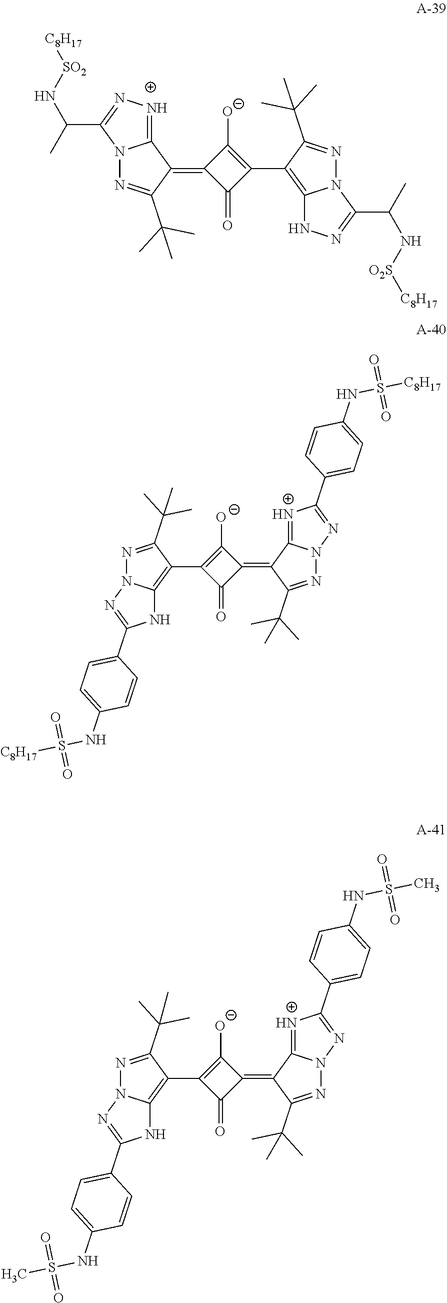

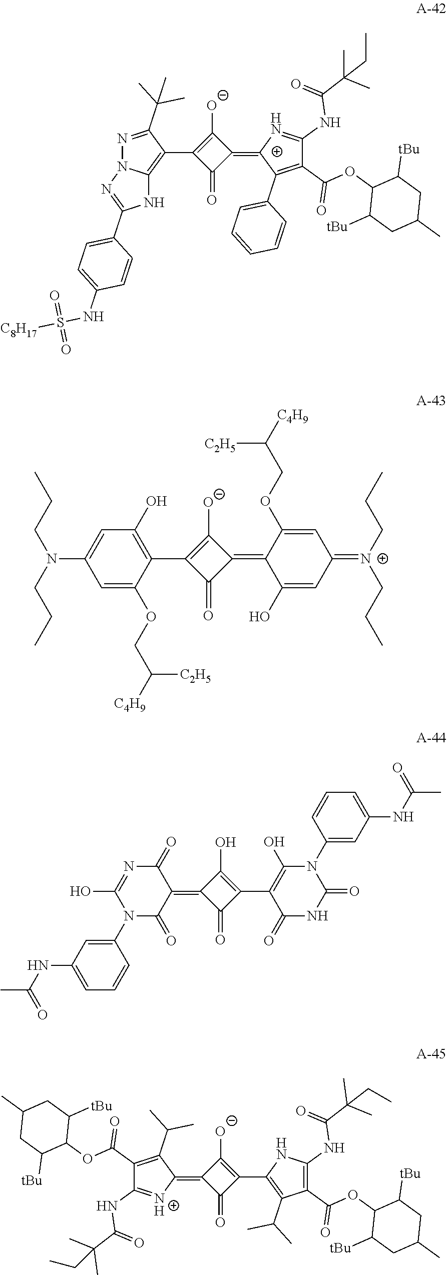

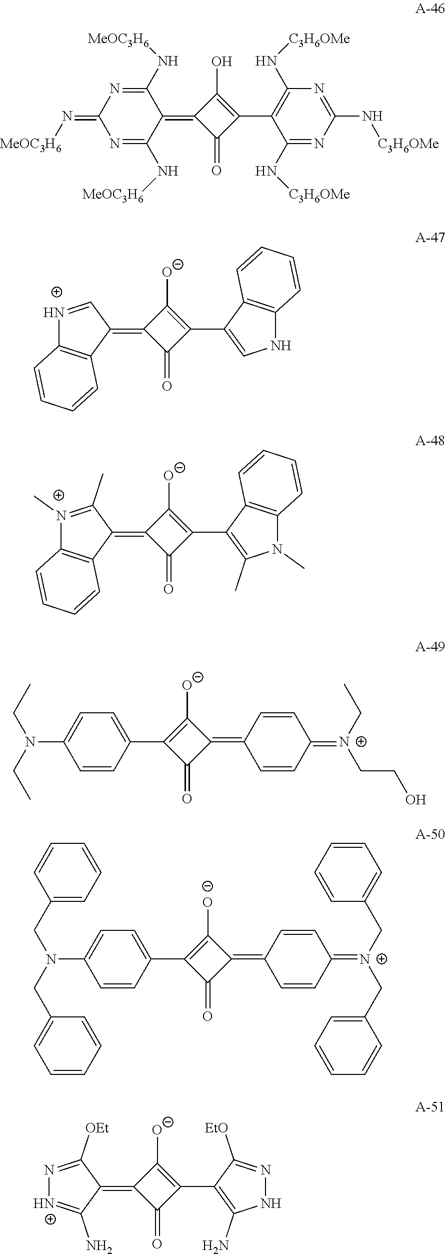

In addition to the above-described specific examples, specific examples of the coloring agents represented by any one of General Formulae (3) to (5) will be shown. The substituent B in the following tables represents the following structures. In the following structures and the following tables, Me represents methyl, Et represents ethyl, i-Pr represents i-propyl, Bu represents n-butyl, t-Bu represents t-butyl, and Ph represents phenyl, respectively. In the following structures, * indicates a bonding site to a 4-membered carbon ring in each General Formula.

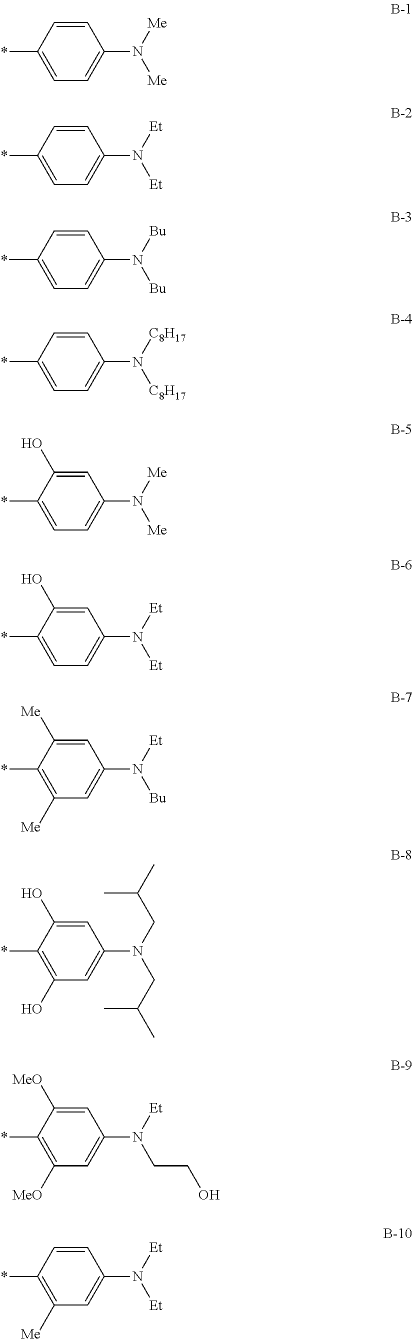

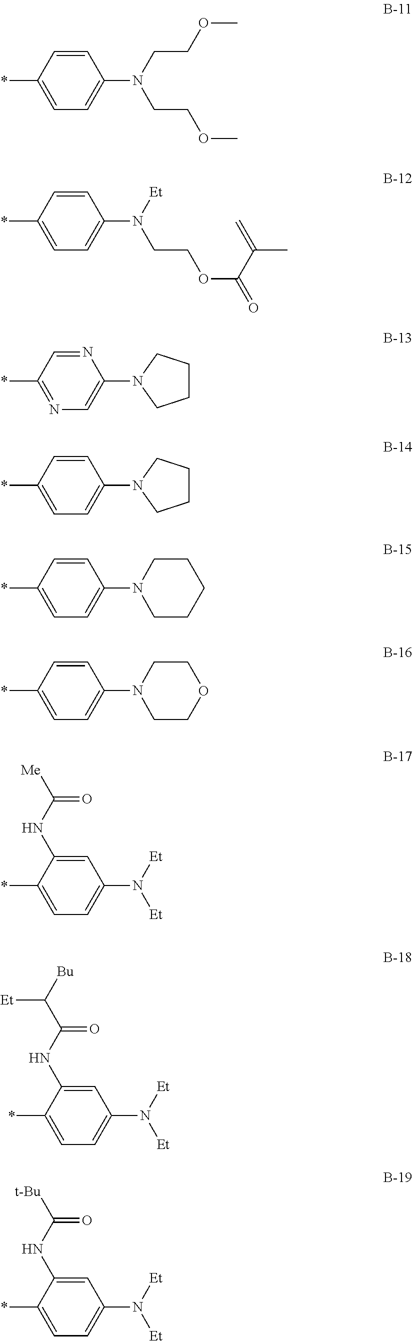

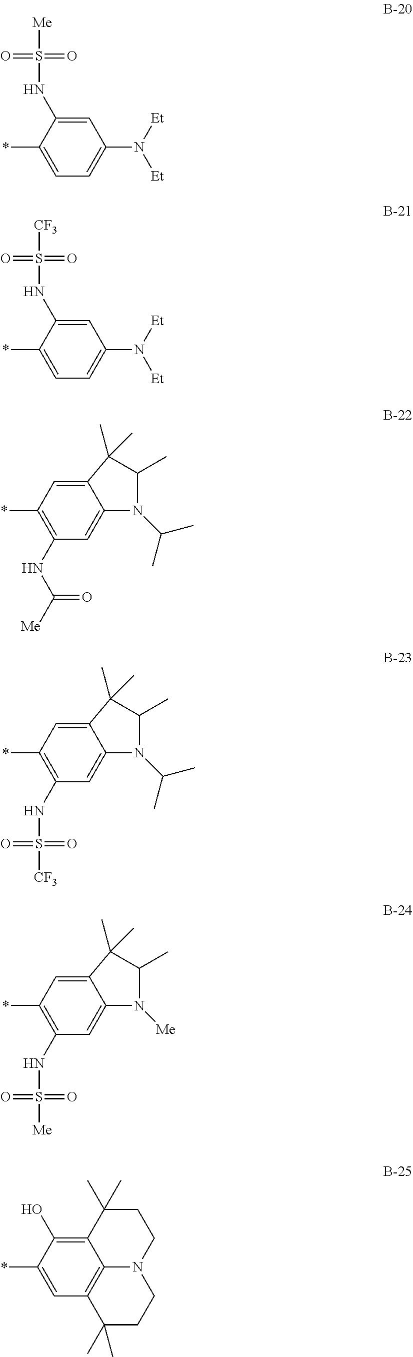

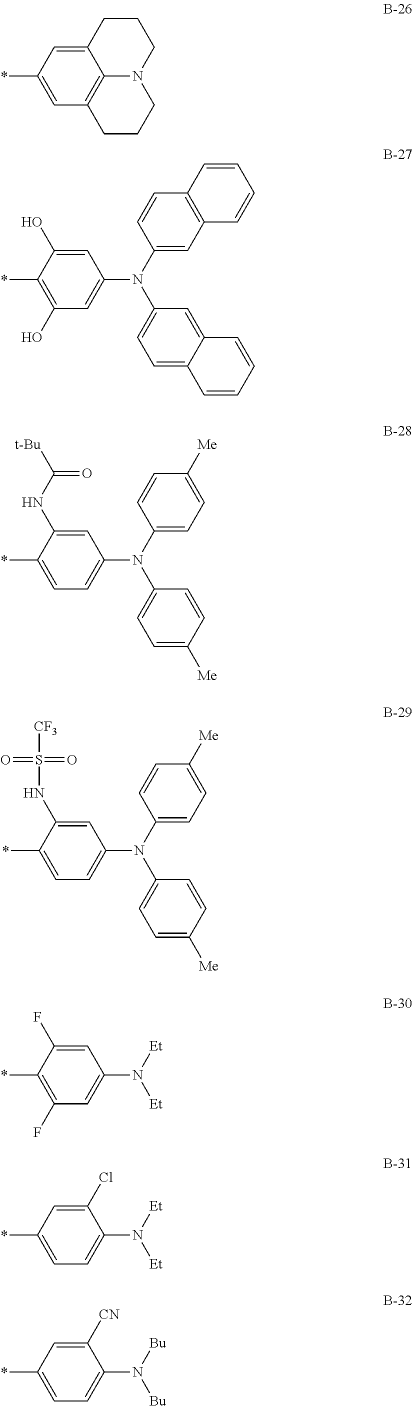

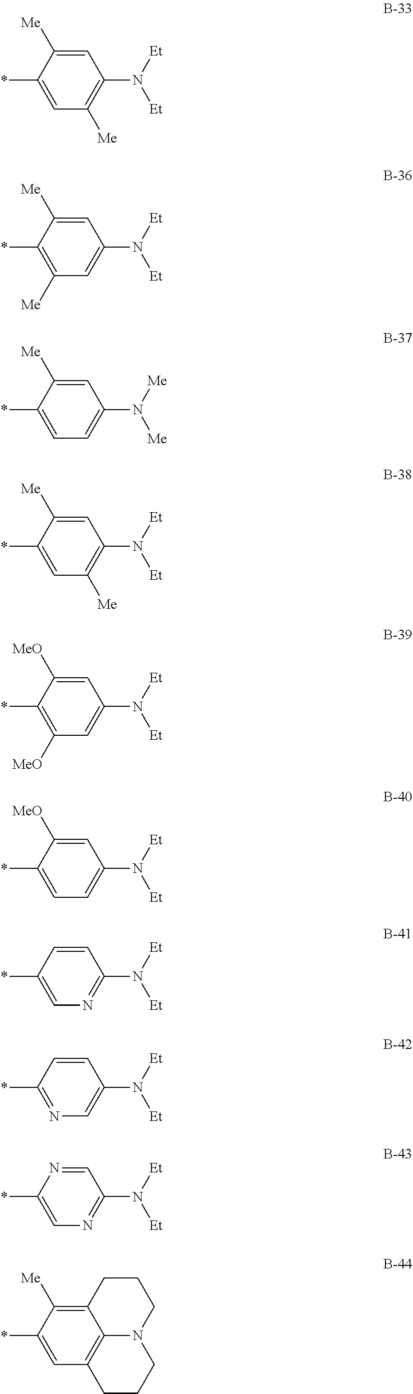

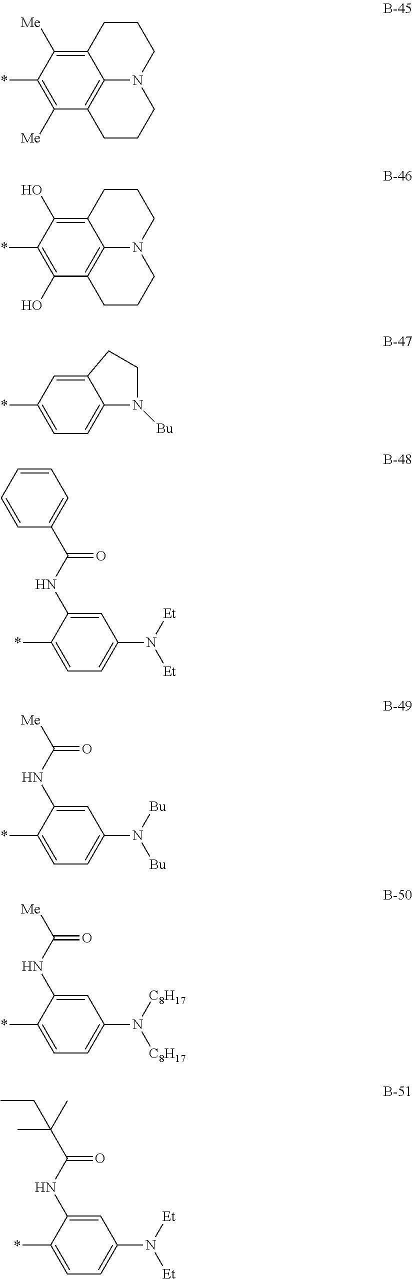

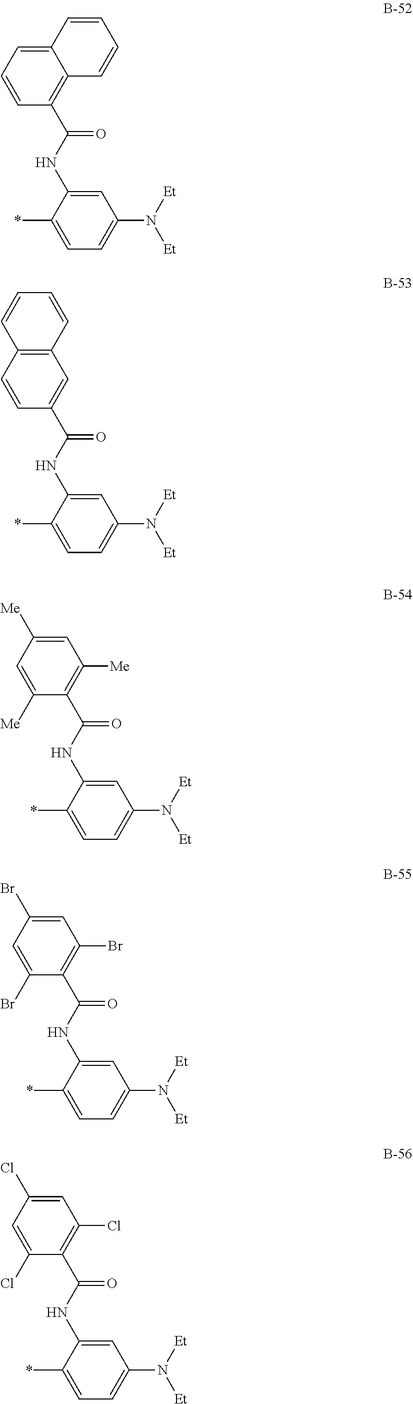

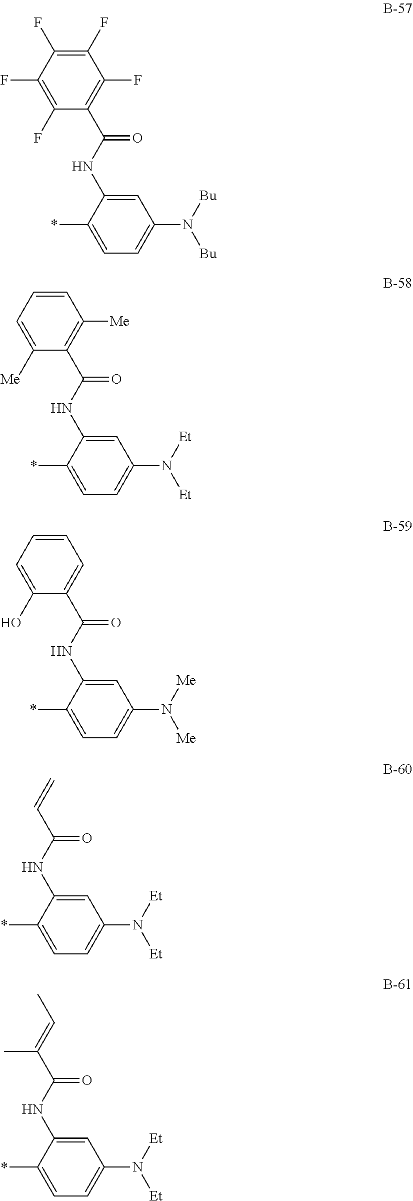

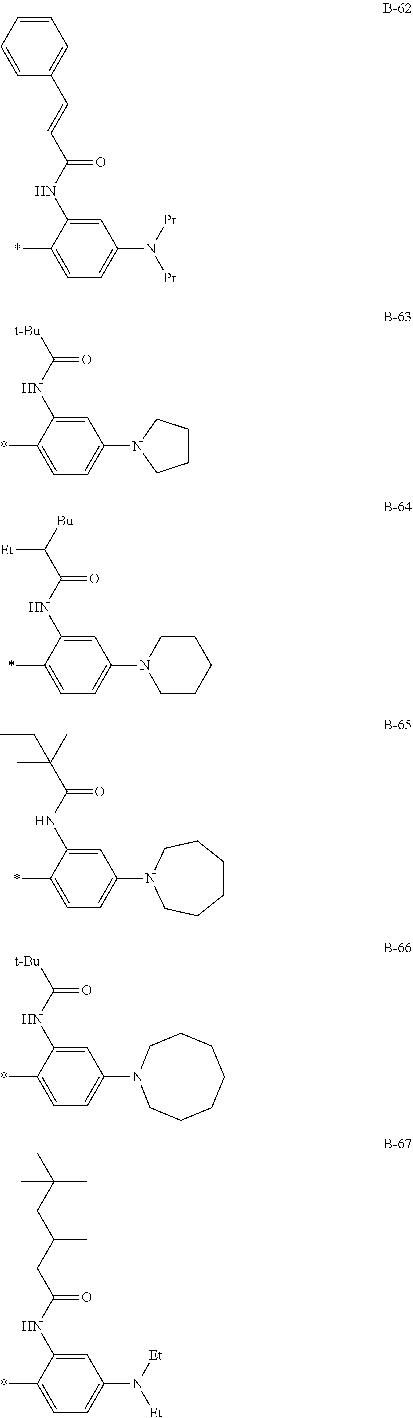

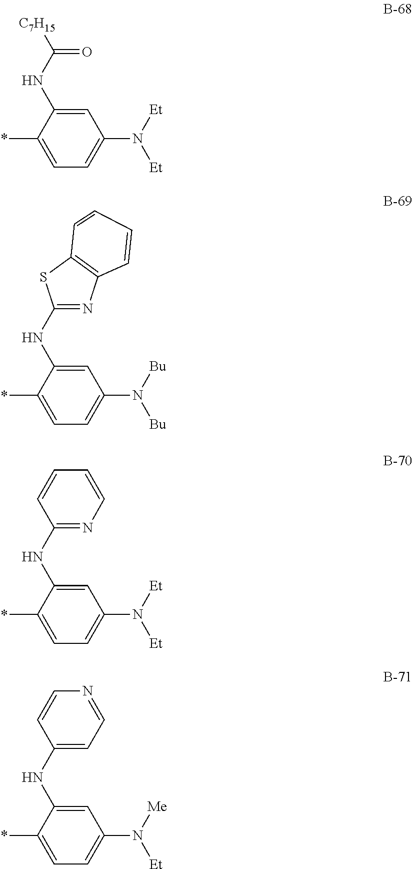

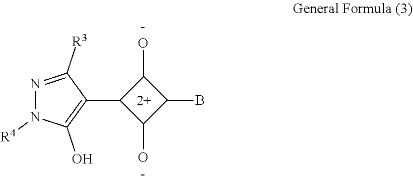

| Chemical | | | | Chemical | | | |
|---|---|---|---|---|---|---|---|
| compound No. | R³ | R⁴ | B | compound No. | R³ | R⁴ | B |
| 3-1 | Me | Me | B-3 | 3-21 | H | H | B-23 |
| 3-2 | Me | Me | B-4 | 3-22 | Et | t-Bu | B-21 |
| 3-3 | Me | Me | B-5 | 3-23 | t-Bu | Me | B-18 |
| 3-4 | Me i | Me | B-10 | 3-24 | CF₃ | i-Pr | B-12 |
| 3-5 | Me | Me | B-14 | 3-25 | COOEt | Et | B-6 |
| 3-6 | Me | Me | B-16 | 3-26 | CN | Ph | B-11 |
| 3-7 | Me | Me | B-17 | 3-27 | NMe₂ | Me | B-2 |
| 3-8 | Me, | Me | B-18 | 3-28 | i-Pr | Me | B-17 |
| 3-9 | Me | Me | B-19 | 3-29 | OEt | Bu | B-27 |
| 3-10 | Me | Me | B-20 | 3-30 | NH₂ | i-Pr | B-9 |
| 3-11 | Me | Me | B-21 | 3-31 | t-Bu | Me | B-17 |
| 3-12 | Me | Me | B-22 | 3-32 | t-Bu | Bu | B-21 |
| 3-13 | Me | Me | B-23 | 3-33 | CF₃ | Me | B-18 |
| 3-14 | Me | Me | B-26 | 3-34 | OEt | Et | B-33 |
| 3-15 | Me | Me | B-32 | 3-35 | NMe₂ | i-Pr | B-2 |
| 3-16 | Me | Me | B-33 | 3-36 | Et | Me | B-17 |
| 3-17 | Me | Me | B-38 | 3-37 | Bu | Me | B-18 |
| 3-18 | Me | Me | B-49 | 3-38 | NH₂ | Ph | B-19 |
| 3-19 | Et | 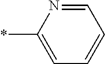 [SMILES: *c1ccccn1] | B-28 | 3-39 | OEt | 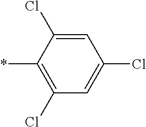 [SMILES: *c1c(Cl)cc(Cl)cc1Cl] | B-26 |
| 3-20 | Me | 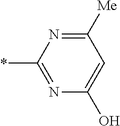 [SMILES: *c1nc(C)cc(O)n1] | B-29 | 3-40 | Me | 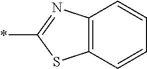 [SMILES: *c1nc2ccccc2s1] | B-2 |
| 3-41 | Me | Ph | B-17 | 3-55 | t-Bu | Me | B-17 |
| 3-42 | Me | Ph | B-21 | 3-56 | t-Bu | Me | B-10 |
| 3-43 | Me | Ph | B-36 | 3-57 | t-Bu | Me | B-44 |
| 3-44 | Me | t-Bu | B-17 | 3-58 | t-Bu | t-Bu | B-17 |
| 3-45 | Me | t-Bu | B-18 | 3-59 | t-Bu | t-Bu | B-10 |
| 3-46 | Me | t-Bu | B-10 | 3-60 | t-Bu | t-Bu | B-6 |
| 3-47 | OEt | Me | B-17 | 3-61 | NBu₂ | Me | B-17 |
| 3-48 | OEt | Me | B-10 | 3-62 | NBu₂ | Me | B-10 |
| 3-49 | Me | 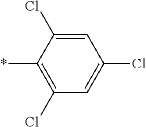 [SMILES: *c1c(Cl)cc(Cl)cc1Cl] | B-17 | 3-63 | t-Bu | 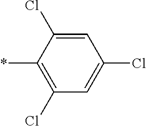 [SMILES: *c1c(Cl)cc(Cl)cc1Cl] | B-17 |
| 3-50 | Me | 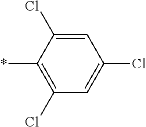 [SMILES: *c1c(Cl)cc(Cl)cc1Cl] | B-19 | 3-64 | t-Bu | 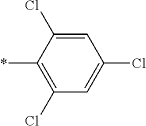 [SMILES: *c1c(Cl)cc(Cl)cc1Cl] | B-19 |
| 3-51 | Me | 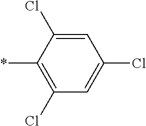 [SMILES: *c1c(Cl)cc(Cl)cc1Cl] | B-21 | 3-65 | t-Bu | 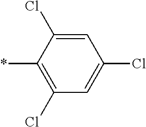 [SMILES: *c1c(Cl)cc(Cl)cc1Cl] | 8-21 |
| 3-52 | Me | 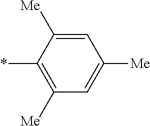 [SMILES: *c1c(C)cc(C)cc1C] | B-17 | 3-66 | t-Bu | 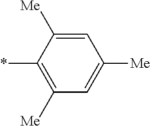 [SMILES: *c1c(C)cc(C)cc1C] | B-17 |
| 3-53 | Me | 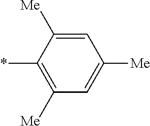 [SMILES: *c1c(C)cc(C)cc1C] | B-20 | 3-67 | t-Bu | 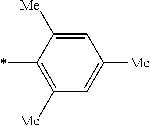 [SMILES: *c1c(C)cc(C)cc1C] | B-20 |
| 3-54 | Me | 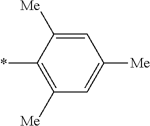 [SMILES: *c1c(C)cc(C)cc1C] | B-21 | 3-68 | t-Bu | 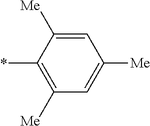 [SMILES: *c1c(C)cc(C)cc1C] | B-21 |
| 3-69 | Me | t-Bu | B-51 | 3-83 | Et | Bu | B-56 |
| 3-70 | Me | t-Bu | B-52 | 3-84 | Me | iPr | B-66 |
| 3-71 | Me | t-Bu | B-54 | 3-85 | Me | 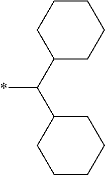 [SMILES: *C(C1CCCCC1)C1CCCCC1] | B-54 |
| 3-72 | Me | t-Bu | B-55 | 3-86 | Me | 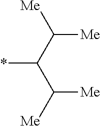 [SMILES: *C(C(C)C)C(C)C] | B-57 |
| 3-73 | Me | t-Bu | B-58 | 3-87 | Et | 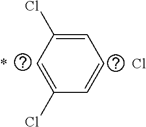 | B-60 |
| 3-74 | Me | t-Bu | B-60 | 3-88 | Me | iPr | B-65 |
| 3-75 | Me | t-Bu | B-65 | 3-89 | Me | t-Bu | B-69 |
| 3-76 | Me | t-Bu | B-67 | 3-90 | Me | 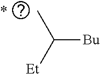 | B-50 |
| 3-77 | Me | t-Bu | B-68 | 3-91 | Me | 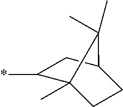 [SMILES: *C1CC2CCC1(C)C2(C)C] | B-61 |
| 3-78 | H | t-Bu | B-51 | 3-92 | Me | 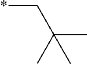 [SMILES: *CC(C)(C)C] | B-51 |
| 3-79 | Et | t-Bu | B-53 | 3-93 | Me | 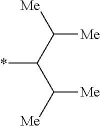 [SMILES: *C(C(C)C)C(C)C] | B-51 |
| 3-80 | Pr | 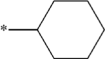 [SMILES: *C1CCCCC1] | B-64 | 3-94 | Me | 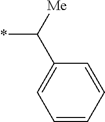 [SMILES: *C(C)c1ccccc1] | B-67 |
| 3-81 | iPr | iPr | B-66 | 3-95 | Me | 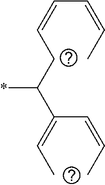 [SMILES: *C(C/C=C\C=C/C)C(/C=C\C)=C/C] | B-51 |
| 3-82 | Me | 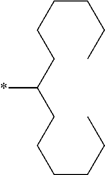 [SMILES: *C(CCCCCC)CCCCCC] | B-51 | 3-96 | Me | 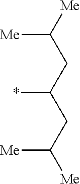 [SMILES: *C(CC(C)C)CC(C)C] | B-51 |

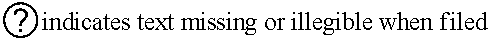

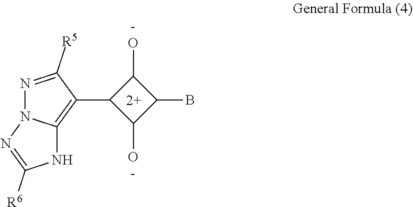

| Chemical | | | | Chemical | | | |
|---|---|---|---|---|---|---|---|
| compound No. | R⁵ | R⁶ | B | compound No. | R⁵ | R⁶ | B |
| 4-1 | t-Bu | 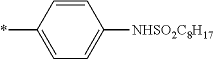 | B-2 | 4-16 | Me | Me. | B-17 |
| 4-2 | t-Bu | 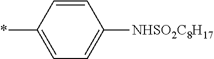 | B-6 | 4-17 | Me | Et | B-18 |
| 4-3 | t-Bu | 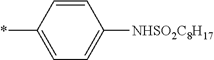 | B-10 | 4-18 | Ph | Ph | B-8 |
| 4-4 | Me | 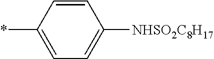 | B-4 | 4-19 | Et | t-Bu | B-17 |
| 4-5 | t-Bu | 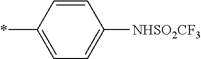 | B-8 | 4-20 | OEt | t-Bu | B-3 |
| 4-6 | t-Bu | 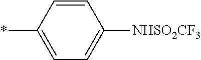 | B-14 | 4-21 | OEt | Bu | B-26 |
| 4-7 | NHCOCH₃ | 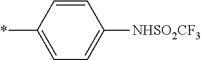 | B-1 | 4-22 | OEt | | B-2 |
| 4-8 | t-Bu | 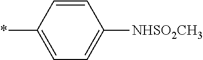 | B-6 | 4-23 | CF3 | t-Bu | B-19 |
| 4-9 | t-Bu | 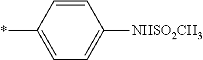 | B-18 | 4-24 | NHCOCH₃ | t-Bu | B-2 |
| 4-10 | OEt | 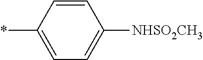 | B-11 | 4-25 | NHCOCH₃ | Me | B-1 |
| 4-11 | t-Bu | 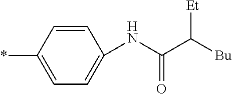 | B-6 | 4-26 | NMe₂ | t-Bu | B-6 |
| 4-12 | t-Bu | 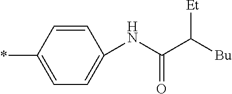 | B-12 | 4-27 | NMe₂ | Et | B-17 |
| 4-13 | OEt | 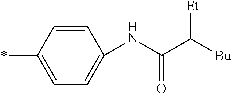 | B-31 | 4-28 | H | Me | B-2 |
| 4-14 | H | H | B-22 | 4-29 | t-Bu | t-Bu | B-18 |
| 4-15 | Me | Me | B-23 | 4-30 | t-Bu | Me | B-17 |
| 4-31 | t- Bu | 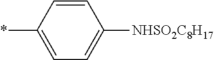 | B-51 | 4-36 | Me | Me | B-65 |
| 4-32 | t-Bu | 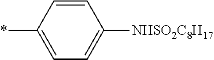 | B-52 | 4-37 | Me | Et | B-67 |
| 4-33 | t- Bu | 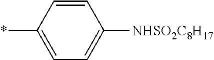 | B-54 | 4-38 | Ph | Ph | B-48 |
| 4-34 | Me | 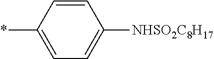 | B-55 | 4-39 | Et | t-Bu | B-54 |
| 4-35 | t-Bu | 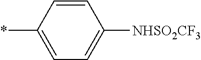 | B-60 | 4-40 | Me | Me | B-51 |

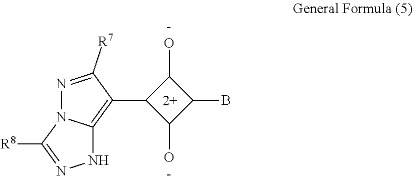

| [symbol] | R¹ | R⁸ | B | [symbol] | R¹ | R⁸ | B |
|---|---|---|---|---|---|---|---|
| 5-1 | t-Bu | 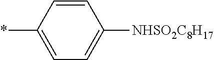 | B--2 | 5-11 | Me | Me | B-17 |
| 5-2 | Me | 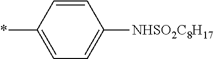 | B-6 | 5-12 | Me | t--Bu | B-18 |
| 5-3 | t-Bu | 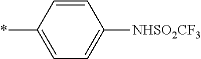 | B-4 | 5-13 | Ph | Ph | B-8 |
| 5-4 | Me | 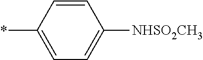 | B-10 | 5-14 | Ph | 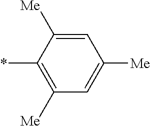 [SMILES: *c1c(C)cc(C)cc1C] | B-17 |
| 5-5 | t-Bu | 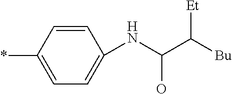 | B-6 | 5-15 | Et | Ph | B-17 |
| 5-6 | t-Bu | 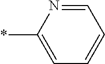 [SMILES: *c1ccccn1] | B-14 | 5-16 | OEt | t-Bu | B-3 |
| 5-7 | Me | 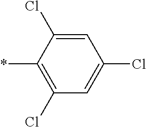 [SMILES: *c1c(Cl)cc(Cl)cc1Cl] | B-1 | 5-17 | OEt | Bu | B-26 |
| 5-8 | Me | 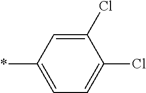 [SMILES: *c1ccc(Cl)c(Cl)c1] | B-6 | 5-18 | CF3 | t-Bu | B-19 |
| 5-9 | Me | 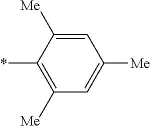 [SMILES: *c1c(C)cc(C)cc1C] | B-16 | 5-19 | NHCOCH3 | t-Bu | B-2 |
| 5-10 | t-Bu | 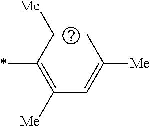 [SMILES: */C(CC)=C(\C)C=C(C)C] | B-11 | 5-20 | NHCOCH3 | 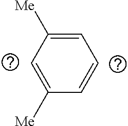 | B-1 |
| 5-21 | t-Bu | 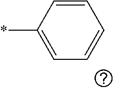 [SMILES: *c1ccccc1] | B-2 | 5-26 | Me | Me | B-65 |
| 5-22 | Me | 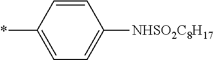 | B-51 | 5-27 | Me | t-Bu | B-67 |
| 5-23 | t-Bu | 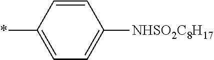 | B-52 | 5-28 | Ph | Ph | B-50 |
| 5-24 | Me | 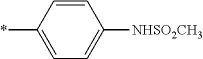 | B-55 | 5-29 | Ph | 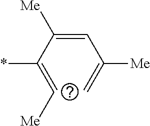 [SMILES: *C(=C\C)/C(C)=C\C(=C)C] | B-23 |
| 5-25 | t-Bu | 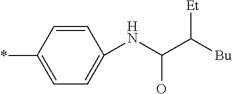 | B-50 | 5-30 | Et | Ph | B-59 |

[symbol]

indicates data missing or illegible when filed

One preferred embodiment of the coloring agent represented by General Formula (1) includes a coloring agent represented by General Formula (6).

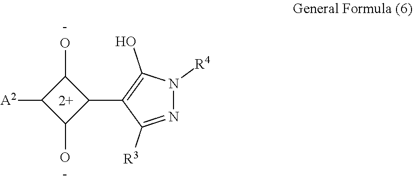

In General Formula (6), R³ and R⁴ each independently represent a hydrogen atom or a substituent and they respectively have the same meanings as R³ and R⁴ in General Formula (3), where the preferred ones thereof are also the same.

In General Formula (6), A² has the same meaning as A in General Formula (1). Among these, a heterocyclic group which is a nitrogen-containing 5-membered ring is preferable.

The coloring agent represented by General Formula (6) is preferably a coloring agent represented by any one of General Formula (7), (8), or (9).

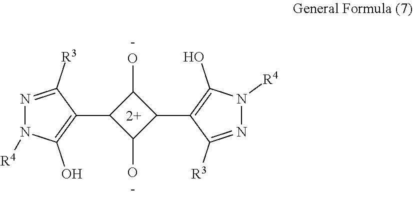

In General Formula (7). R³ and R⁴ each independently represent a hydrogen atom or a substituent, and they respectively have the same meanings as R³ and R⁴ in General Formula (3), where the same applies to the preferred ranges thereof. Two R³'s and two R⁴'s may be the same as or different from each other.

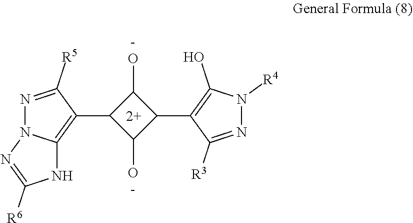

In General Formula (8), R³ and R⁴ each independently represent a hydrogen atom or a substituent, and they respectively have the same meanings as R³ in General Formula (3), where the same applies to the preferred ranges thereof.

In General Formula (8), R⁵ and R⁶ each independently represent a hydrogen atom or a substituent, and they respectively have the same meanings as R⁵ and R⁶ in General Formula (4), where the same applies to the preferred ranges thereof.

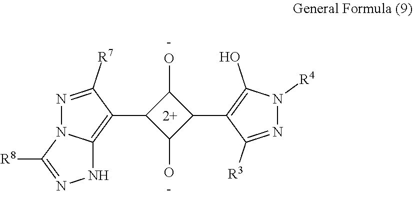

In General Formula (9). R³ and R⁴ each independently represent a hydrogen atom or a substituent, and they respectively have the same meanings as R³ in General Formula (3), where the same applies to the preferred ranges thereof.

In General Formula (9), R⁷ and R⁸ each independently represent a hydrogen atom or a substituent, and they respectively have the same meanings as R⁷ and R⁸ in General Formula (5), where the same applies to the preferred ranges thereof.

Hereinafter, specific examples of the coloring agent represented by any one of General Formulae (6) to (9) will be shown. However, the present invention is not limited thereto.

In the following specific examples, Me represents methyl. Et represents ethyl, i-Pr represents i-propyl, t-Bu represents t-butyl, and Ph represents phenyl, respectively. In the following structures, * indicates a bonding site to a 4-membered carbon ring in each General Formula.

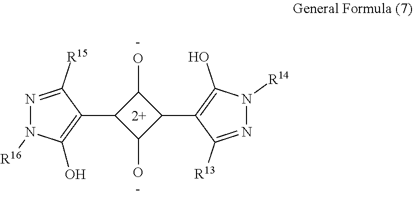

| Chemical compound No. | R¹³ | R¹⁴ | R¹⁵ | R¹⁶ |
|---|---|---|---|---|
| 7-1 | Me | Me | Me | Me |
| 7-2 | Et | Me | Et | Me |
| 7-3 | Me | 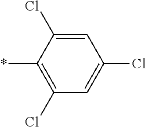 [SMILES: *c1c(Cl)cc(Cl)cc1Cl] | Me | 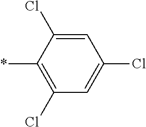 [SMILES: *c1c(Cl)cc(Cl)cc1Cl] |
| 7-4 | t-Bu | 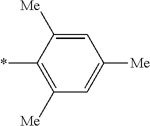 [SMILES: *c1c(C)cc(C)cc1C] | t-Bu | 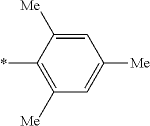 [SMILES: *c1c(C)cc(C)cc1C] |
| 7-5 | NMe₂ | Me | NMe₂ | Me |
| 7-6 | CN | Me | CN | Me |
| 7-7 | OEt | Me | OEt | Me |
| 7-8 | Me | 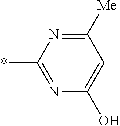 [SMILES: *c1nc(C)cc(O)n1] | Me | 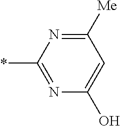 [SMILES: *c1nc(C)cc(O)n1] |
| 7-9 | Et | 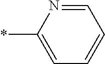 [SMILES: *c1ccccn1] | Et | 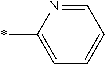 [SMILES: *c1ccccn1] |
| 7-10 | i-Pr | 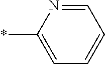 [SMILES: *c1ccccn1] | i-Pr | 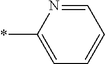 [SMILES: *c1ccccn1] |
| 7-11 | t-Bu | t-Bu | t-Bu | t-Bu |
| 7-12 | CF₃ | Ph | CF₃ | Ph |
| 7-13 | COOEt | Me | COOEt | Me |
| 7-14 | NH₂ | Me | NH₂ | Me |
| 7-15 | Me | Me | Me | 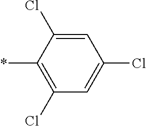 [SMILES: *c1c(Cl)cc(Cl)cc1Cl] |
| 7-16 | Me | Me | t-Bu | t-Bu |
| 7-17 | Me | Me | NMe₂ | Me |
| 7-18 | Me | Me | Me | Ph |
| 7-19 | Et | Me | Et | 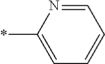 [SMILES: *c1ccccn1] |
| 7-20 | COOEt | Me | Me | 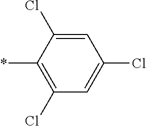 [SMILES: *c1c(Cl)cc(Cl)cc1Cl] |

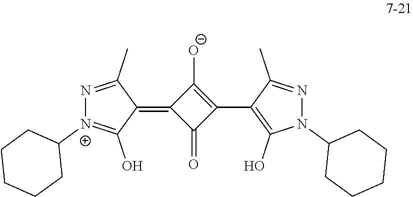 [SMILES: CC1=N[N+](C2CCCCC2)=C(O)/C1=C1\C(=O)C(c2c(C)nn(C3CCCCC3)c2O)=C1[O-]]

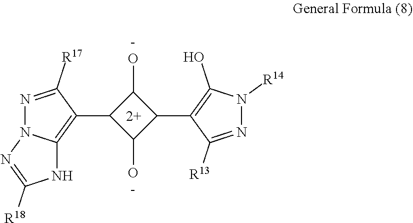

| Chemical compound No. | R¹³ | R¹⁴ | R¹⁷ | R¹⁸ |
|---|---|---|---|---|
| 8-1 | Me | Me | Me | Me |
| 8-2 | Me | Me | t-Bu | 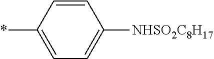 |
| 8-3 | Me | Me | t-Bu | 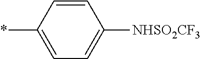 |
| 8-4 | Me | Me | t-Bu | 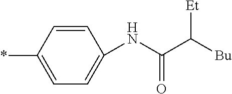 |
| 8-5 | Me | 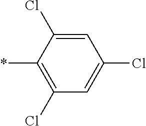 [SMILES: *c1c(Cl)cc(Cl)cc1Cl] | Me | Me |
| 8-6 | Me | 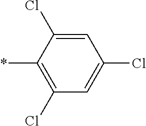 [SMILES: *c1c(Cl)cc(Cl)cc1Cl] | t-Bu | 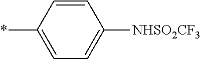 |
| 8-7 | Me | Ph | t-Bu | 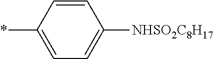 |
| 8-8 | Me | 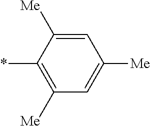 [SMILES: *c1c(C)cc(C)cc1C] | Me | Me |
| 8-9 | Et | Me | Me | Me |
| 8-10 | i-Pr | Me | Me | Me |
| 8-11 | t-Bu | Me | Me | Me |
| 8-12 | Me | Me | OEt | Bu |
| 8-13 | COOEt | Me | Me | Me |
| 8-14 | NH₂ | Me | Me | Me |
| 8-15 | Me | Me | CF₃ | t-Bu |

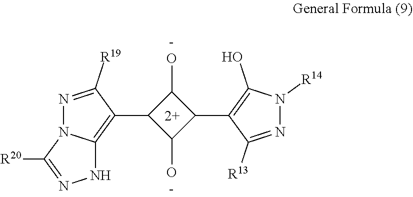

| Chemical compound No. | R¹³ | R¹⁴ | R¹⁹ | R²⁰ |
|---|---|---|---|---|
| 9-1 | Me | Me | Me | Me |
| 9-2 | Me | Me | t-Bu | 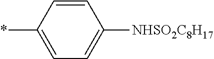 |
| 9-3 | Me | Me | Me | 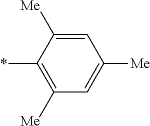 [SMILES: *c1c(C)cc(C)cc1C] |
| 9-4 | Me | Me | Me | 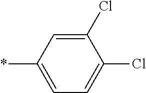 [SMILES: *c1ccc(Cl)c(Cl)c1] |
| 9-5 | Me | 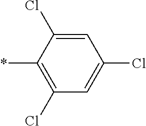 [SMILES: *c1c(Cl)cc(Cl)cc1Cl] | Me | Me |
| 9-6 | Me | 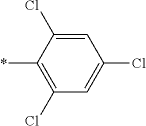 [SMILES: *c1c(Cl)cc(Cl)cc1Cl] | Me | 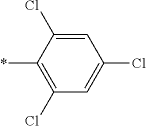 [SMILES: *c1c(Cl)cc(Cl)cc1Cl] |
| 9-7 | t-Bu | Me | t-Bu | 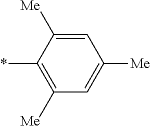 [SMILES: *c1c(C)cc(C)cc1C] |
| 9-8 | t-Bu | Me | Me | Me |
| 9-9 | Et | Me | t-Bu | Me |
| 9-10 | i-Pr | Me | Me | 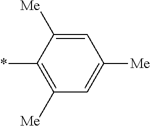 [SMILES: *c1c(C)cc(C)cc1C] |

(Quencher-Embedded Coloring Agent)

The squarine-based coloring agent represented by General Formula (1) may be a quencher-embedded coloring agent in which a quencher moiety is linked to a coloring agent by a covalent bond through a linking group. The quencher-embedded coloring agent can also be preferably used as the above dye. That is, the quencher-embedded coloring agent is counted as the above dye according to the wavelength having the main absorption wavelength band.

Examples of the quencher moiety include the ferrocenyl group in the above-described substituent X. Further, examples thereof include the quencher moiety in a quencher compound described in paragraphs [0199] to [0212] and paragraphs [0234] to [0310] of WO2019/066043A.

Among the squarine-based coloring agents represented by General Formula (1), specific examples of the coloring agent corresponding to the quencher-embedded coloring agent are shown below. However, the present invention is not limited thereto.

In the following specific examples, Me represents methyl, Et represents ethyl, and Bu represents butyl, respectively.

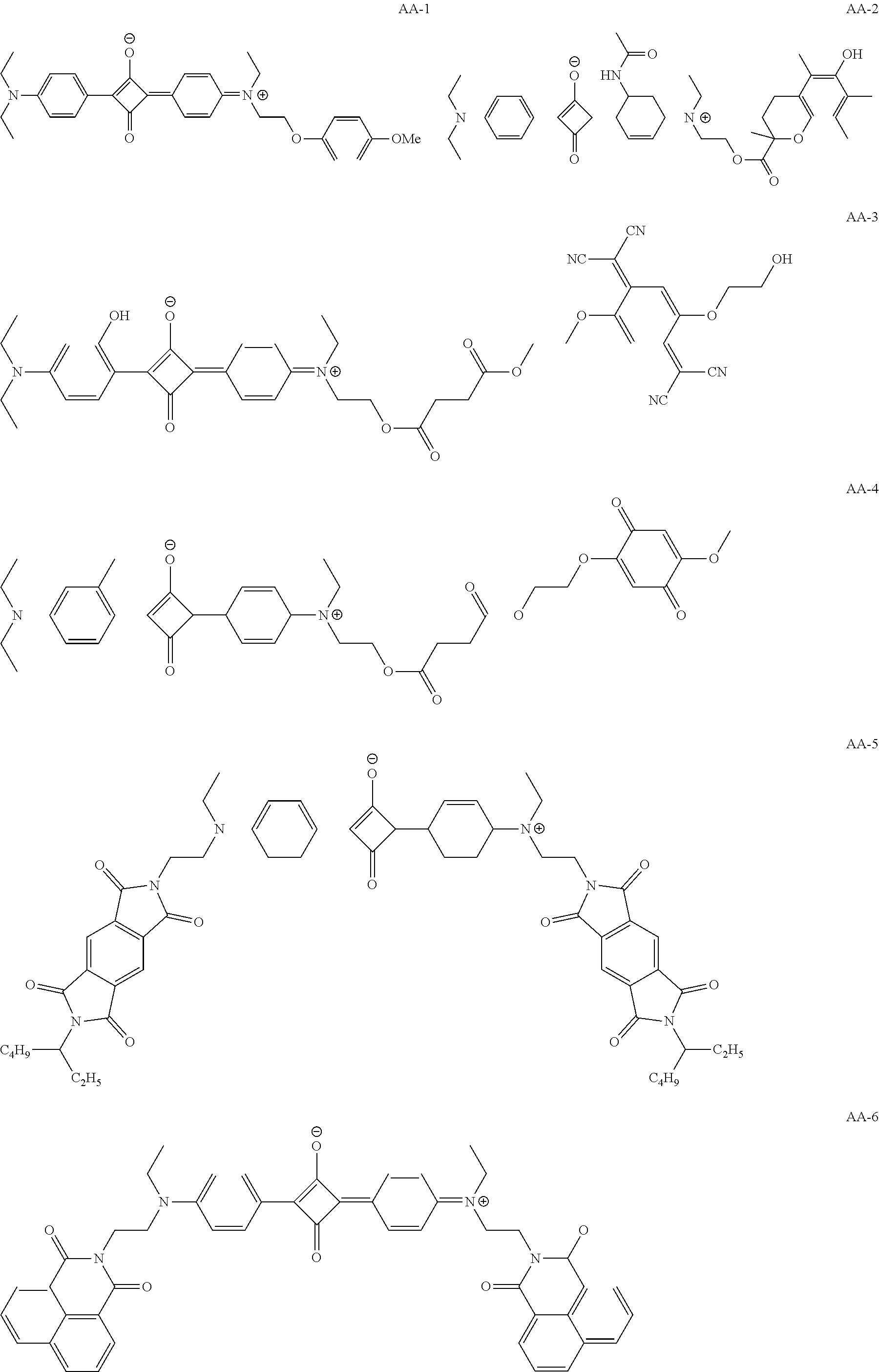

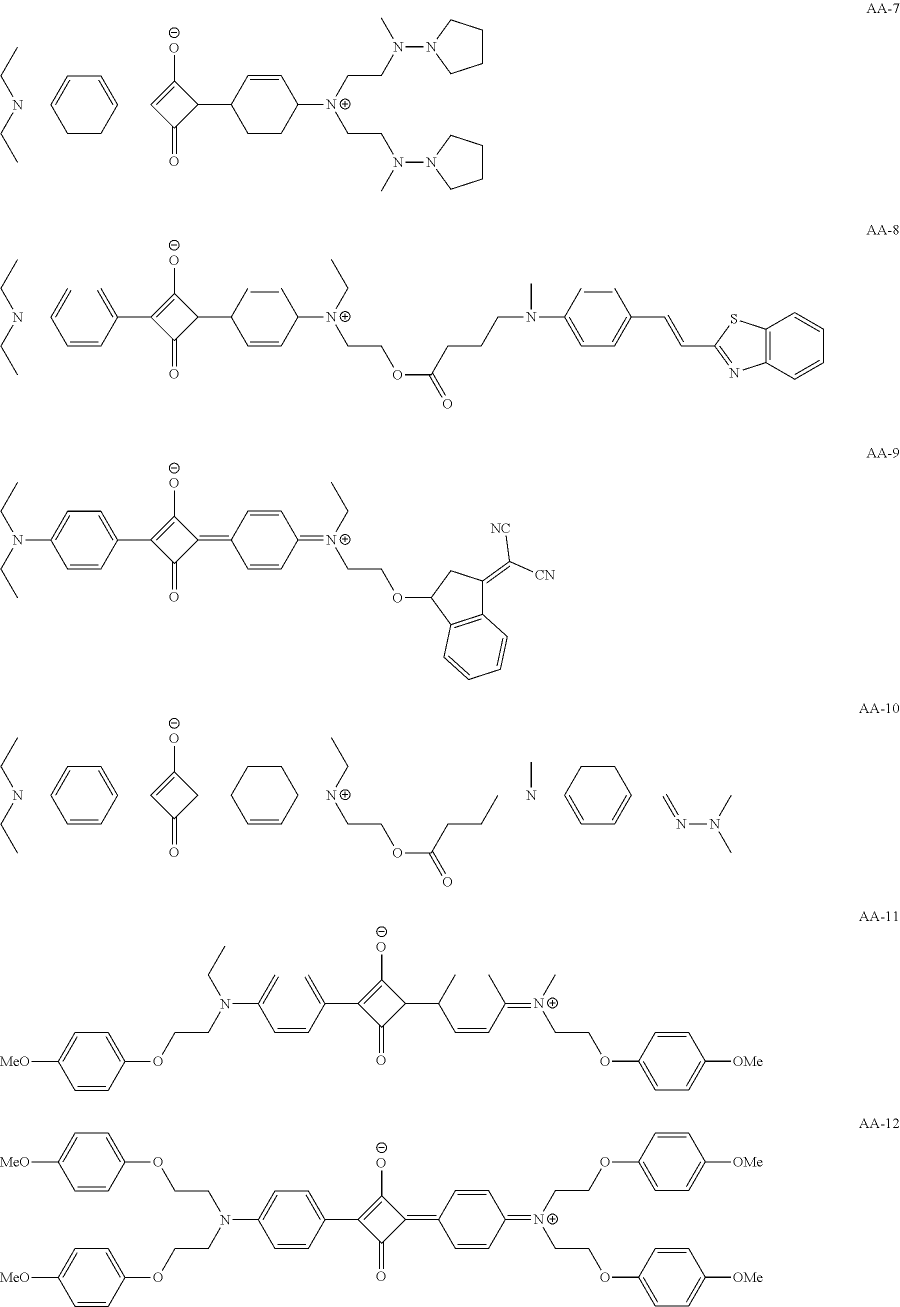

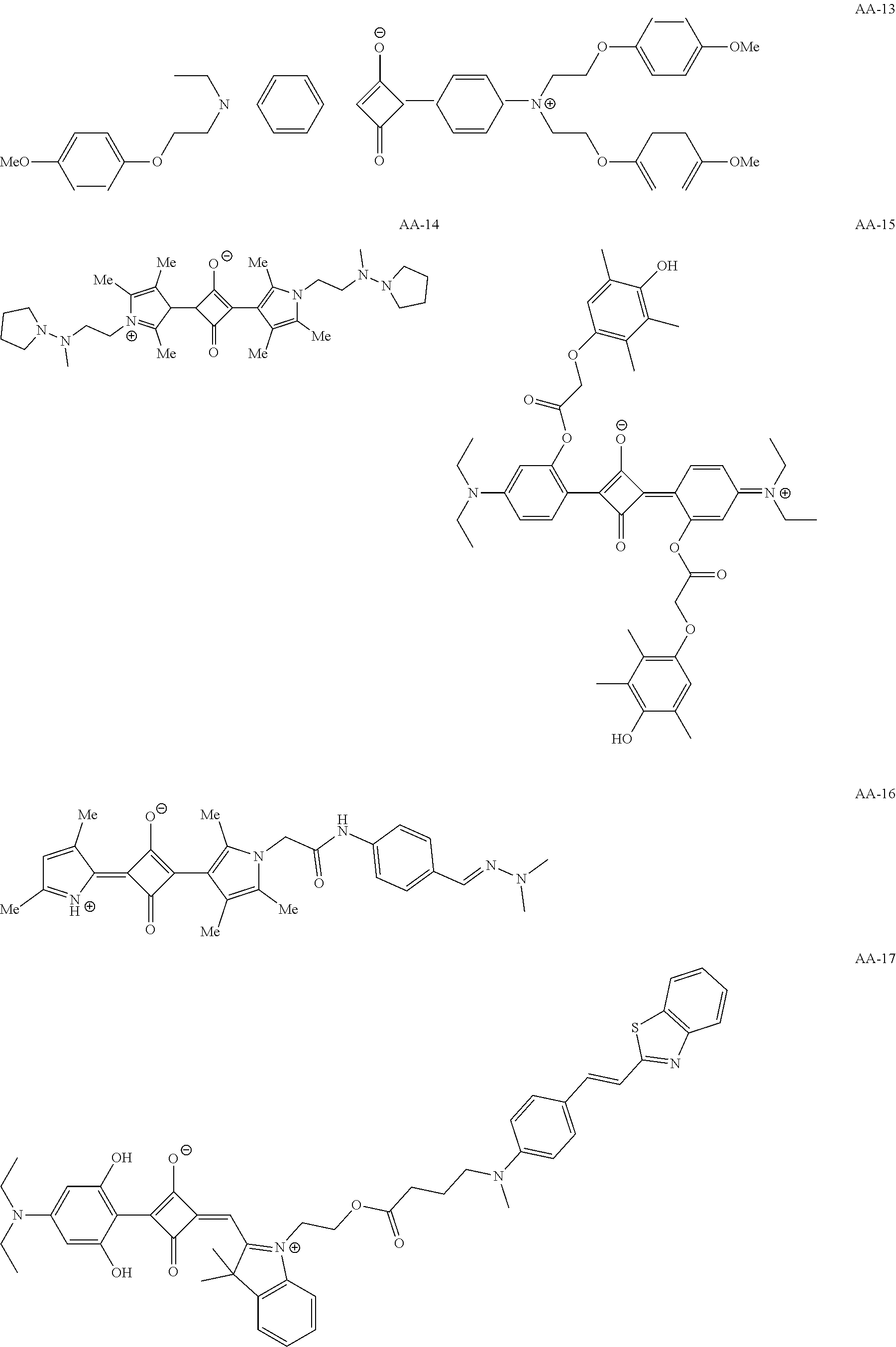

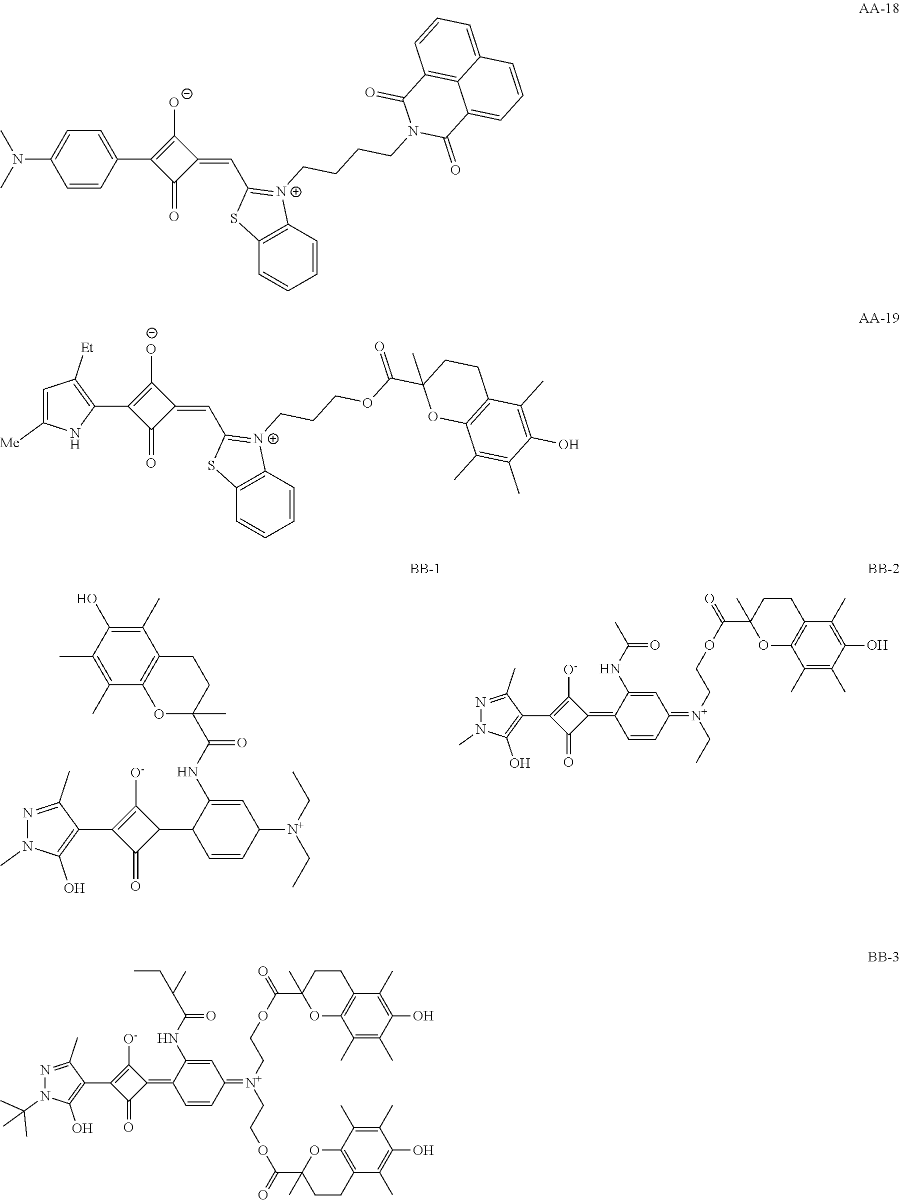

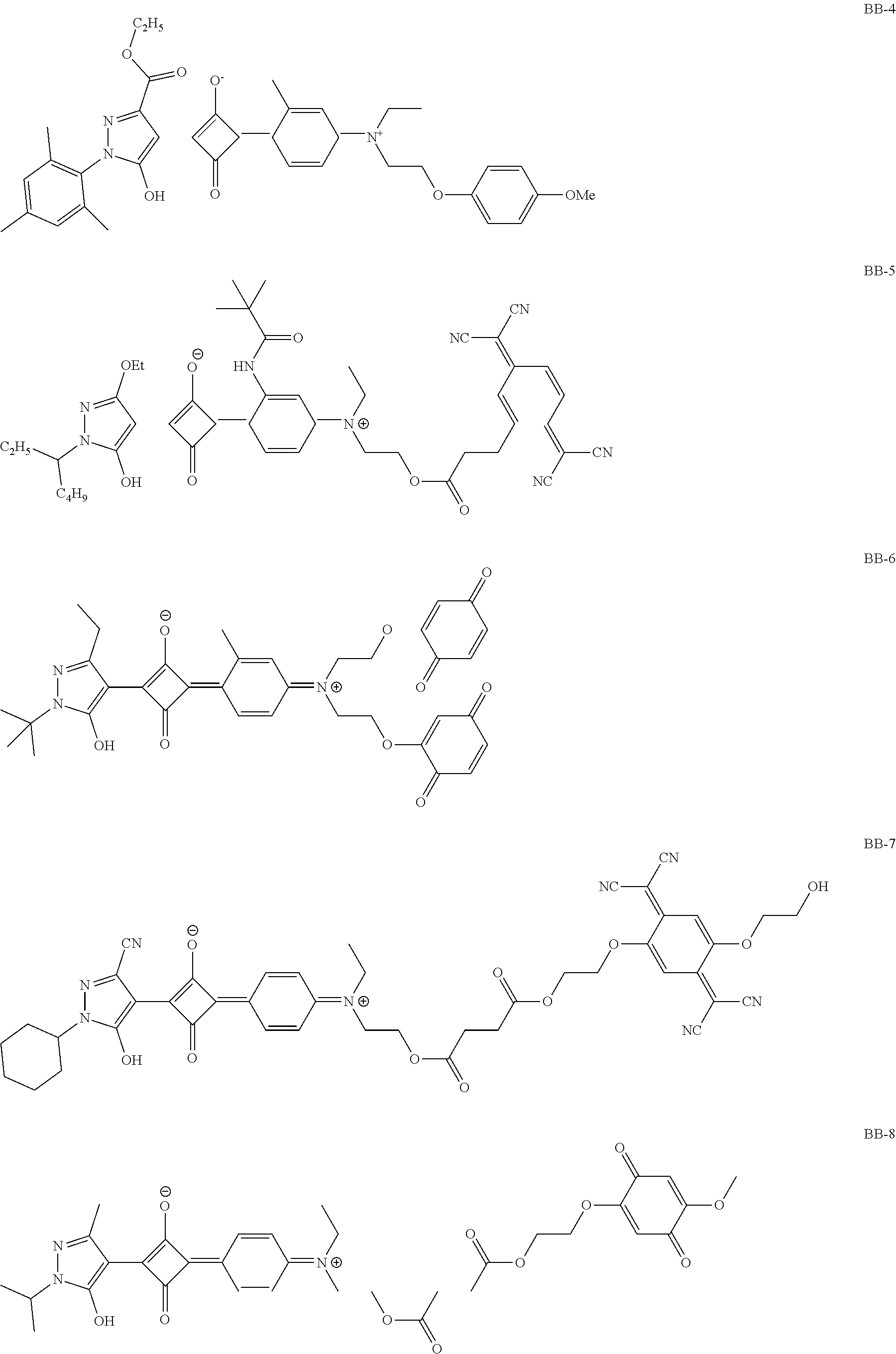

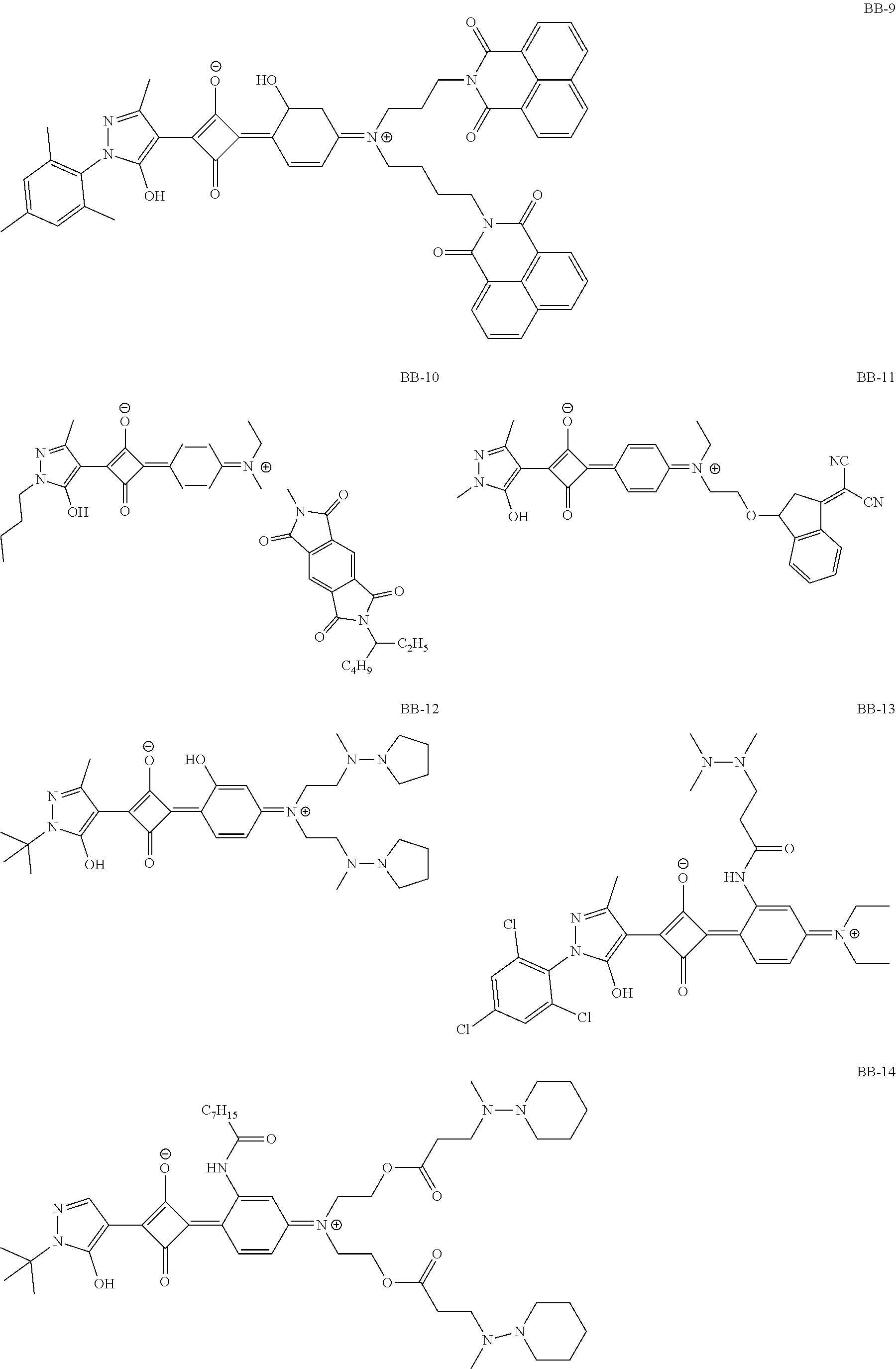

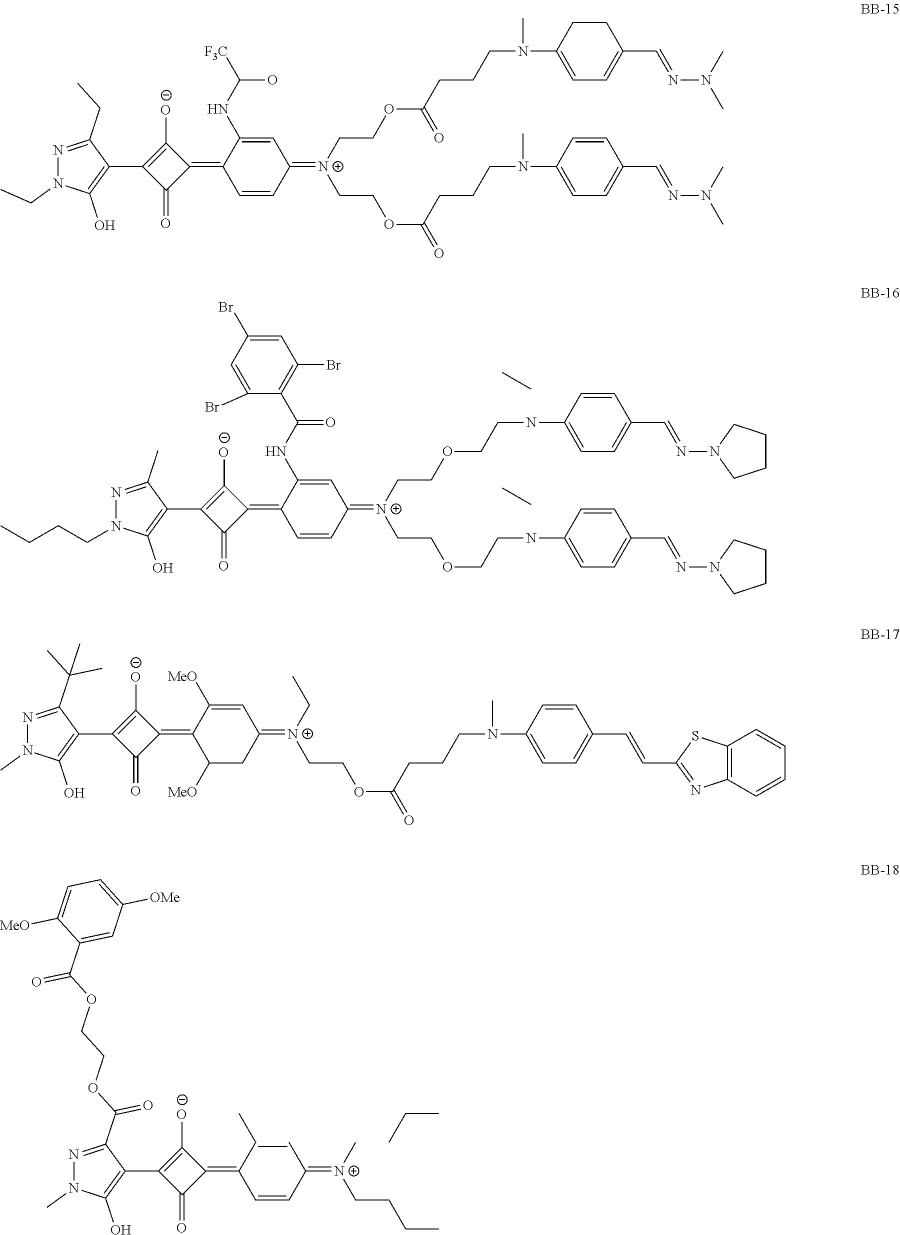

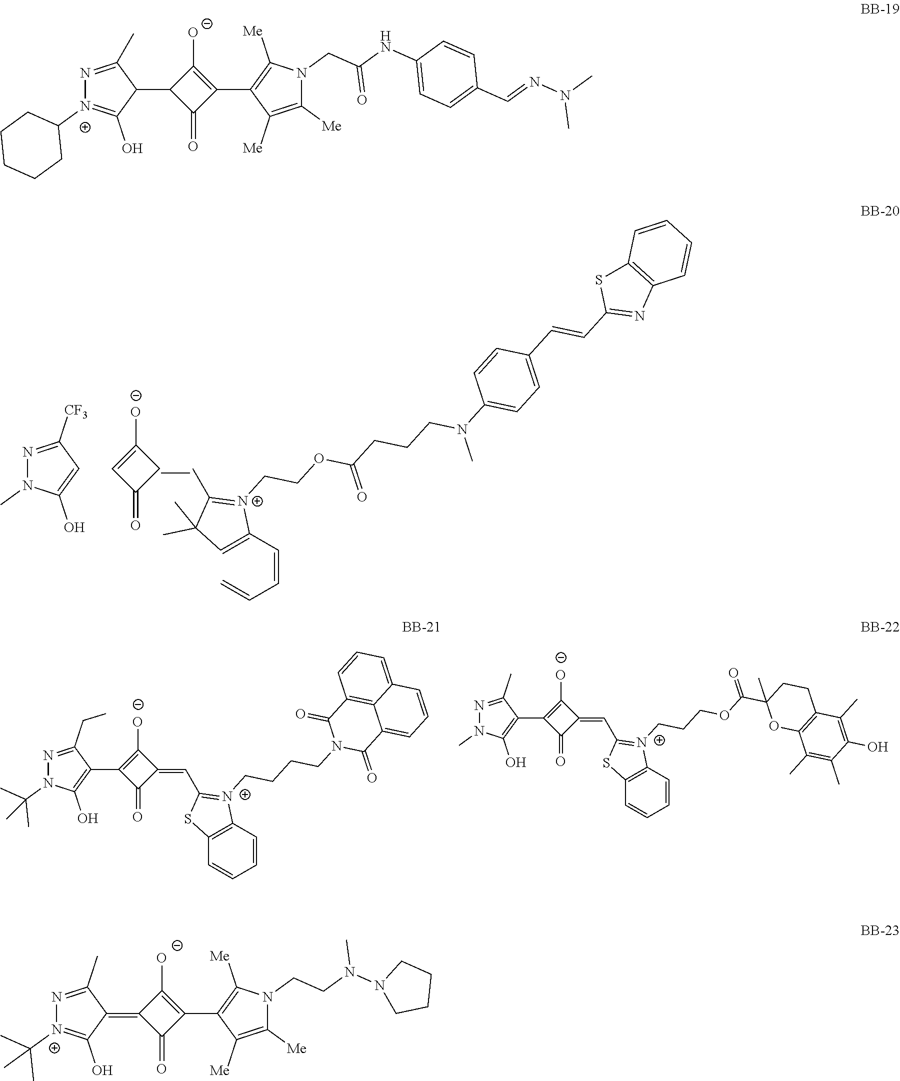

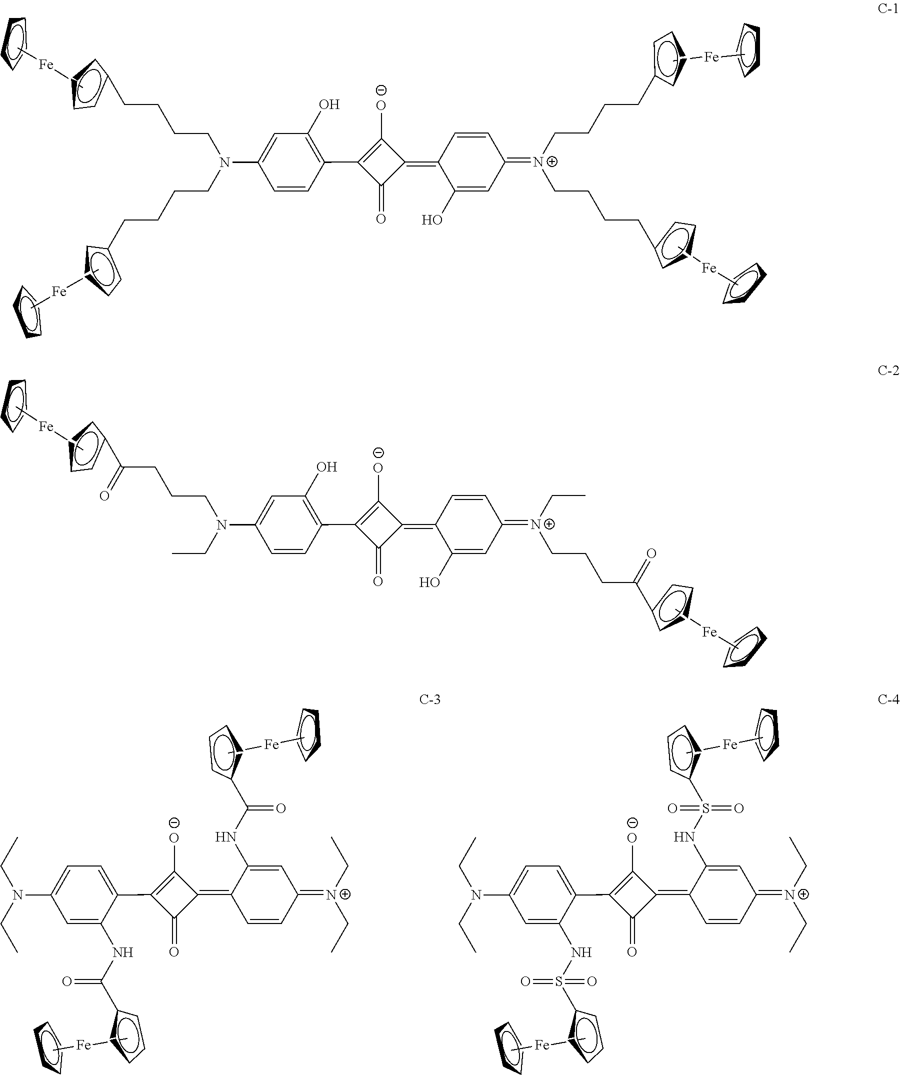

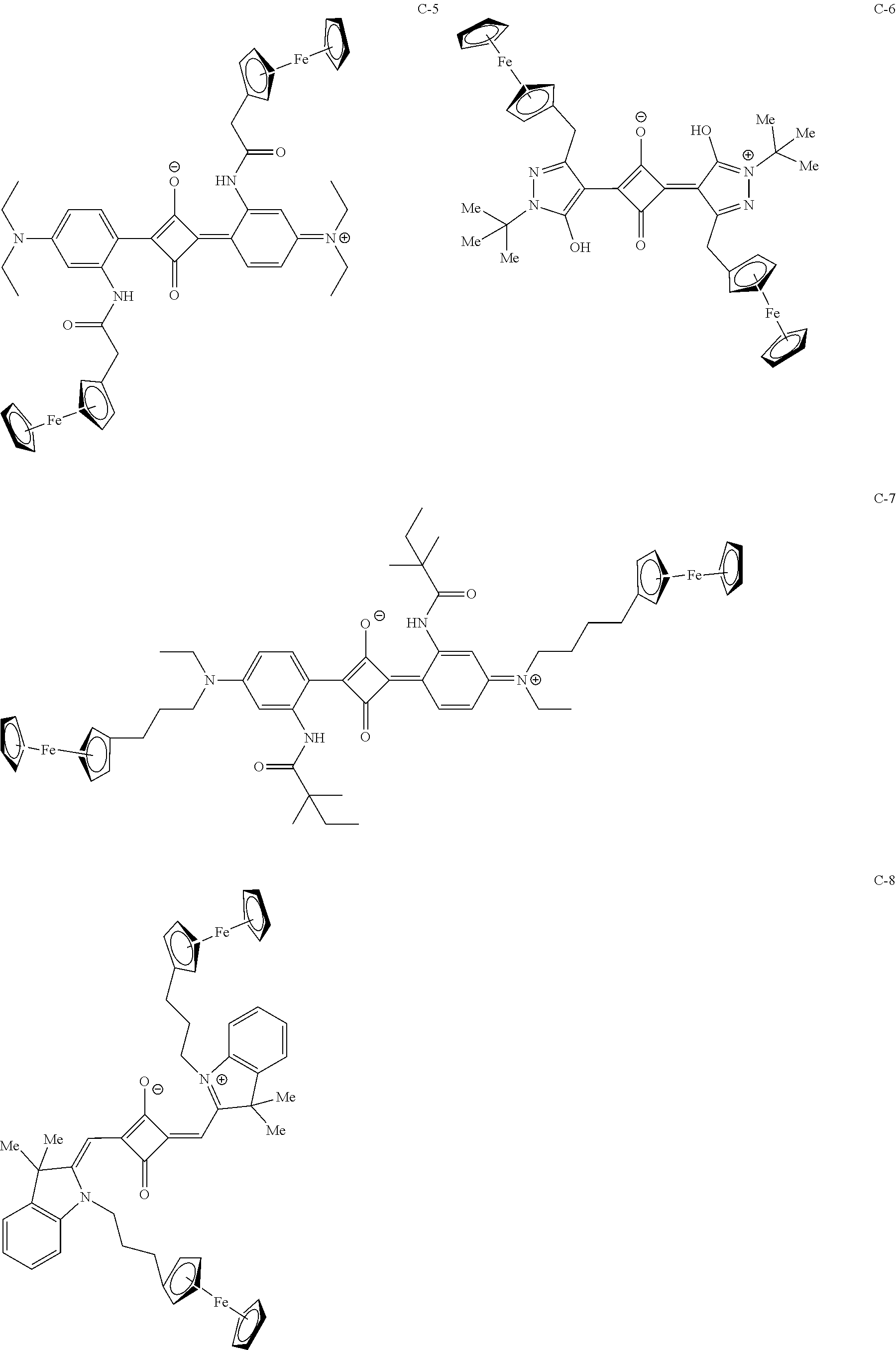

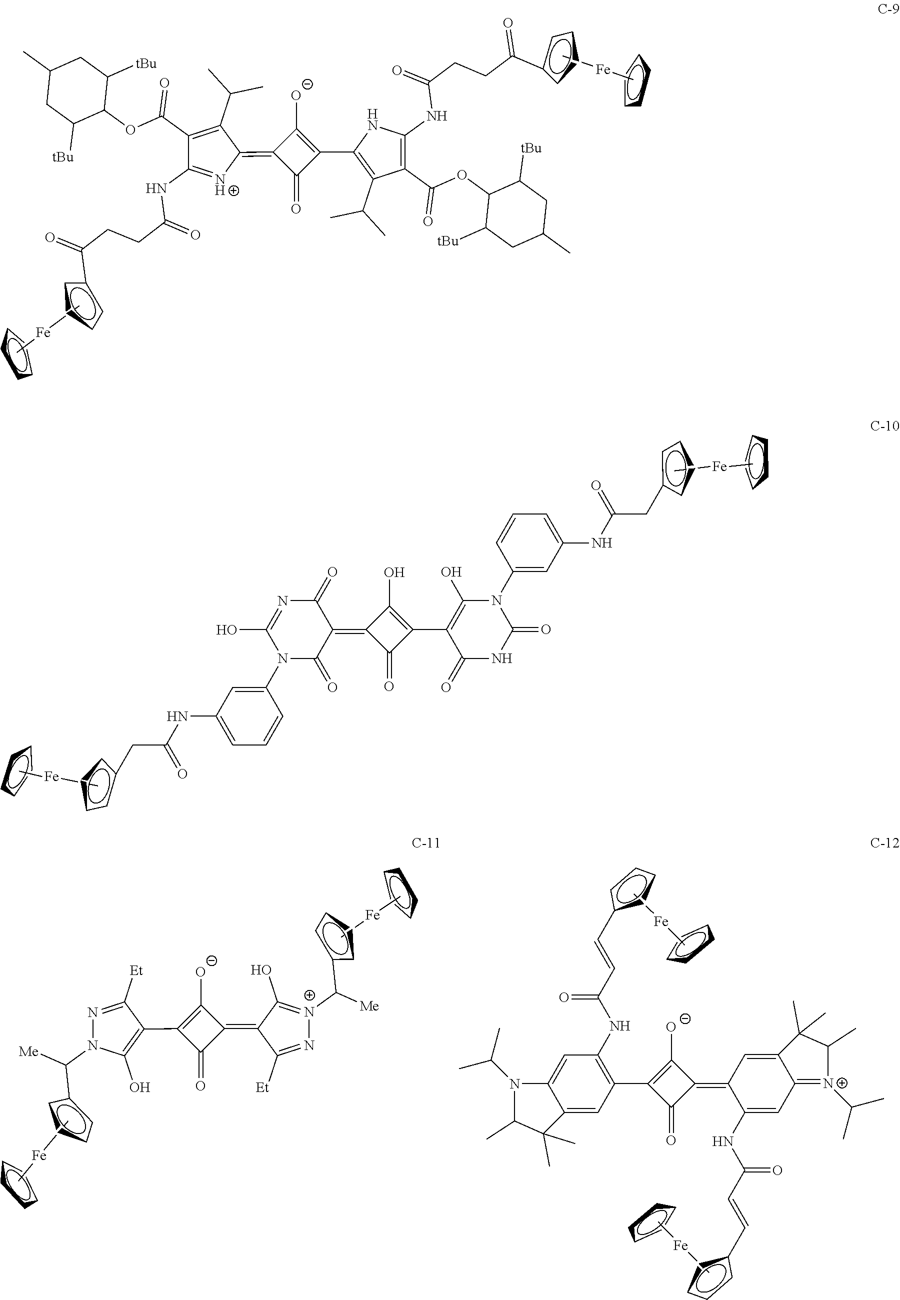

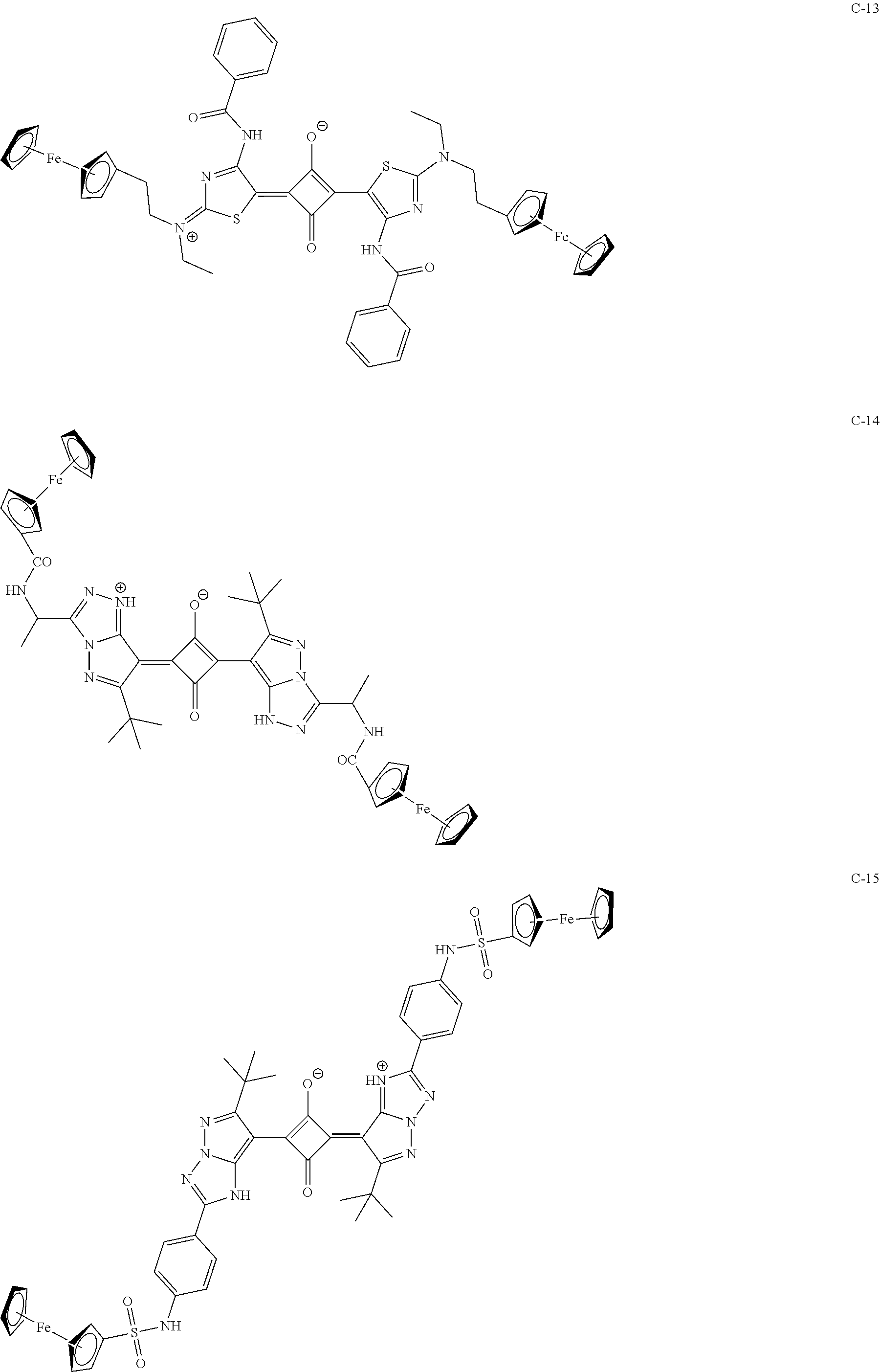

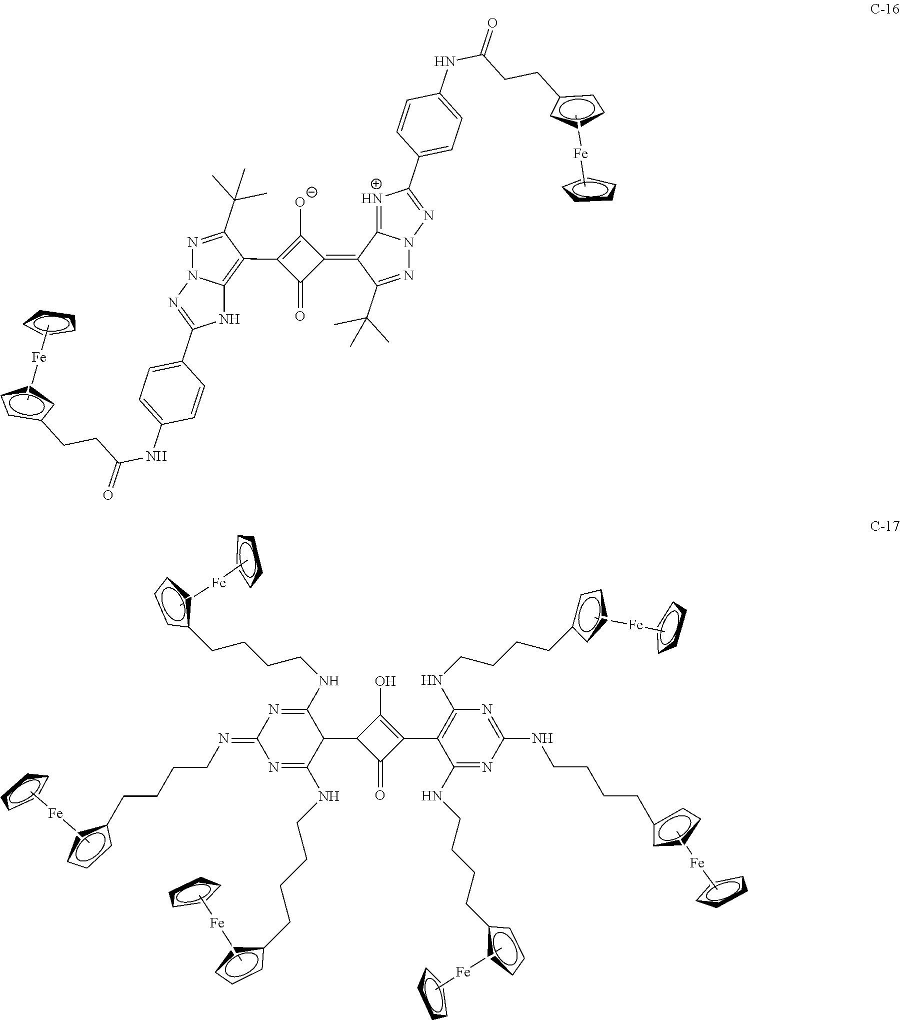

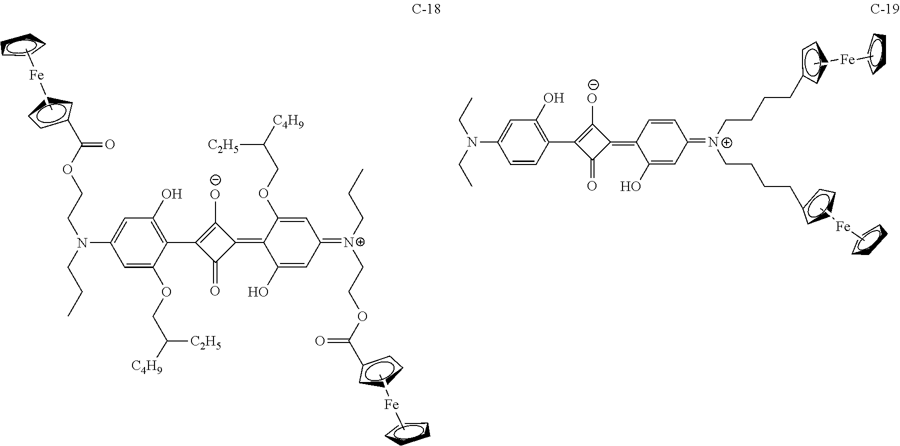

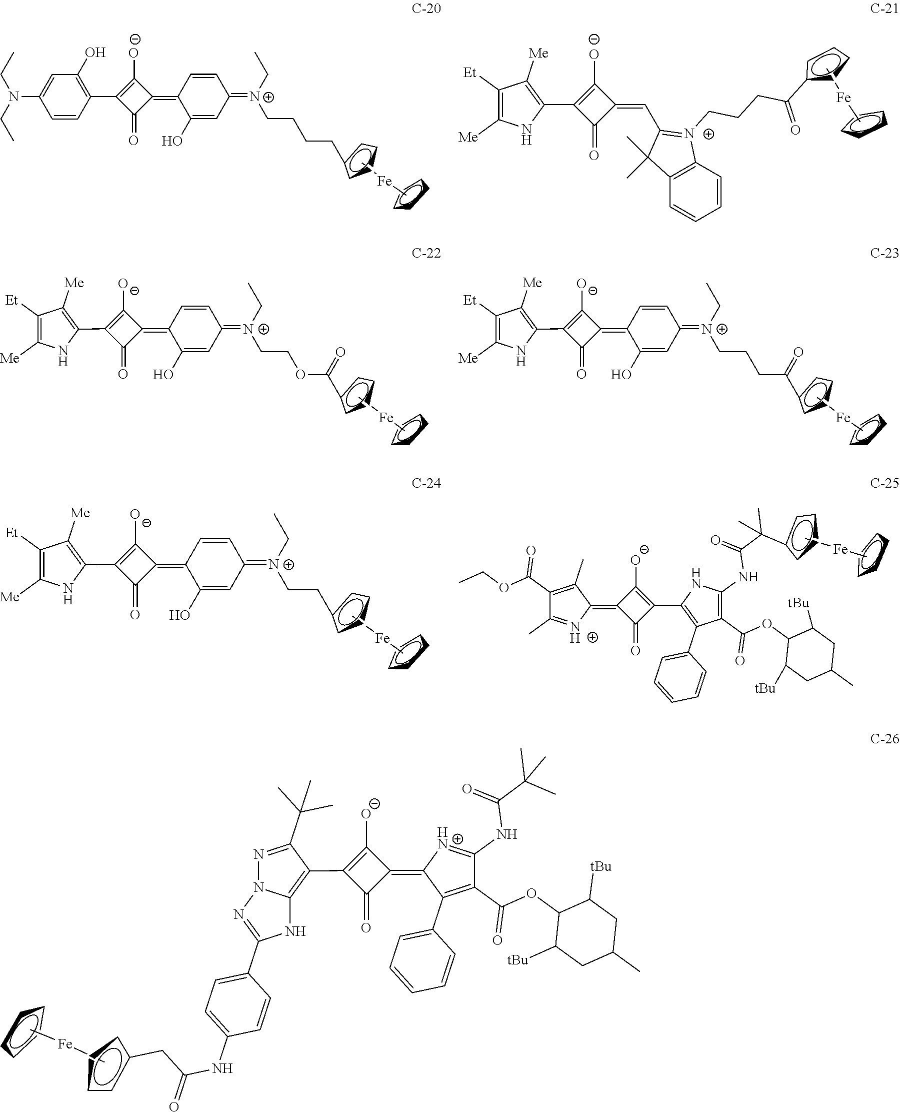

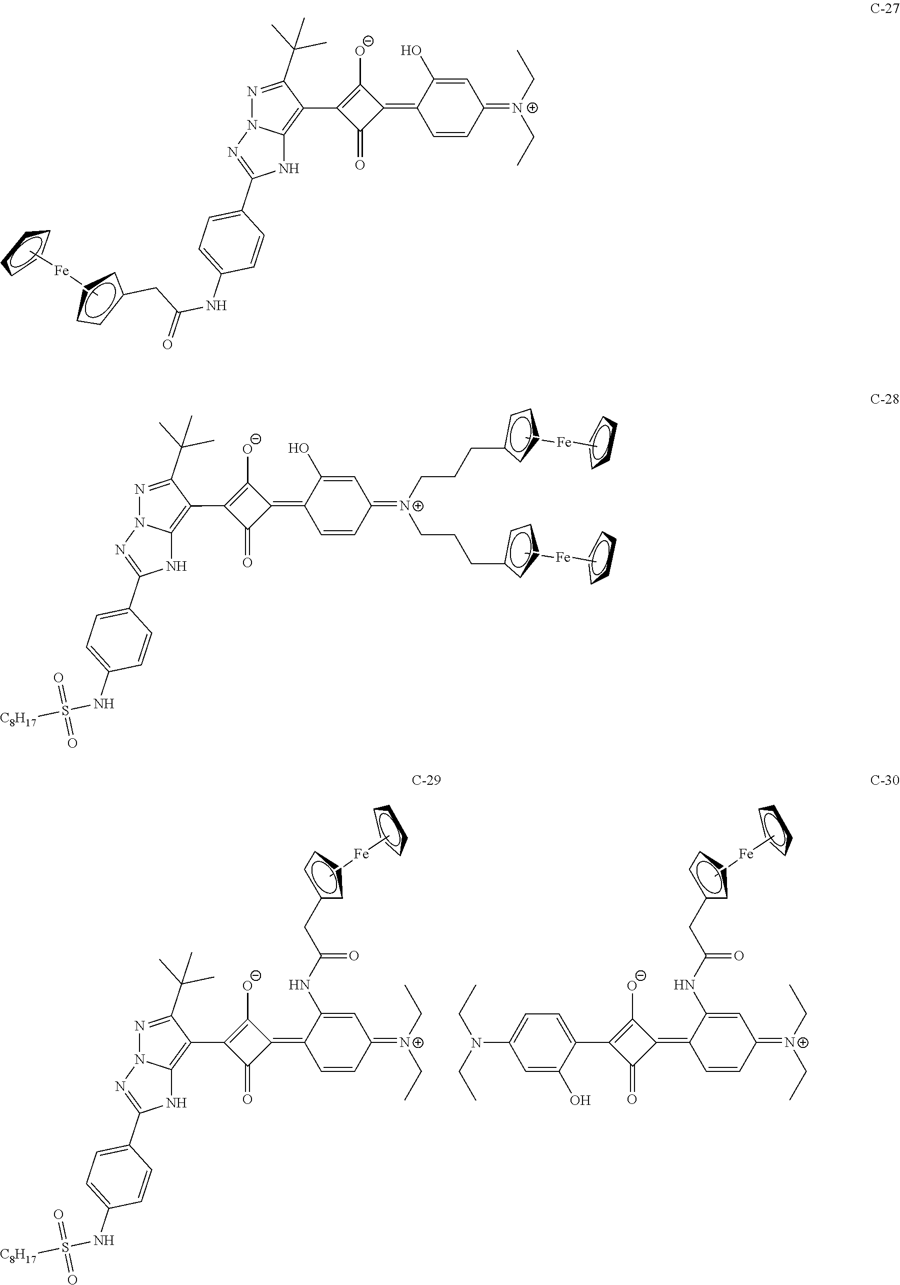

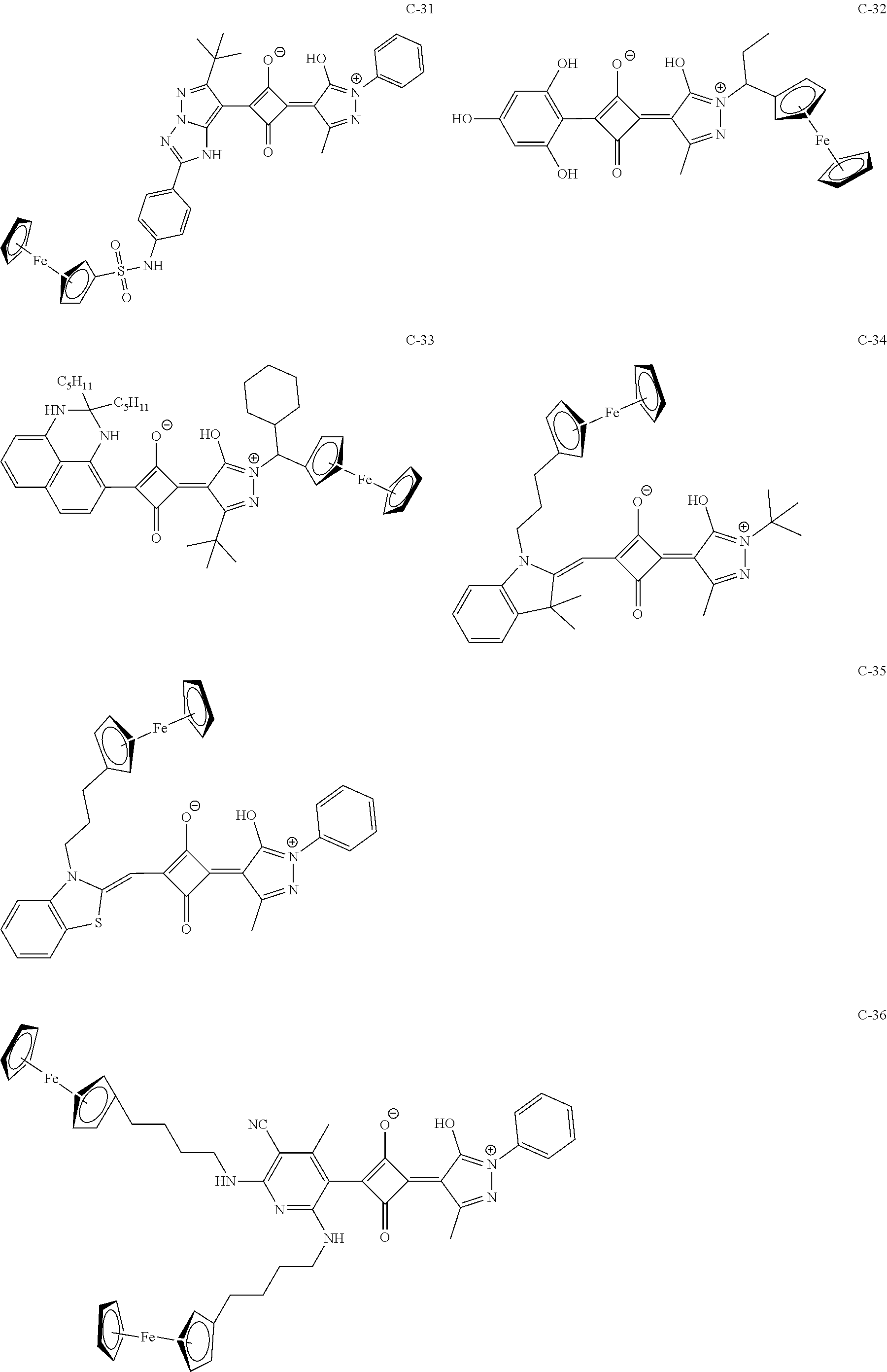

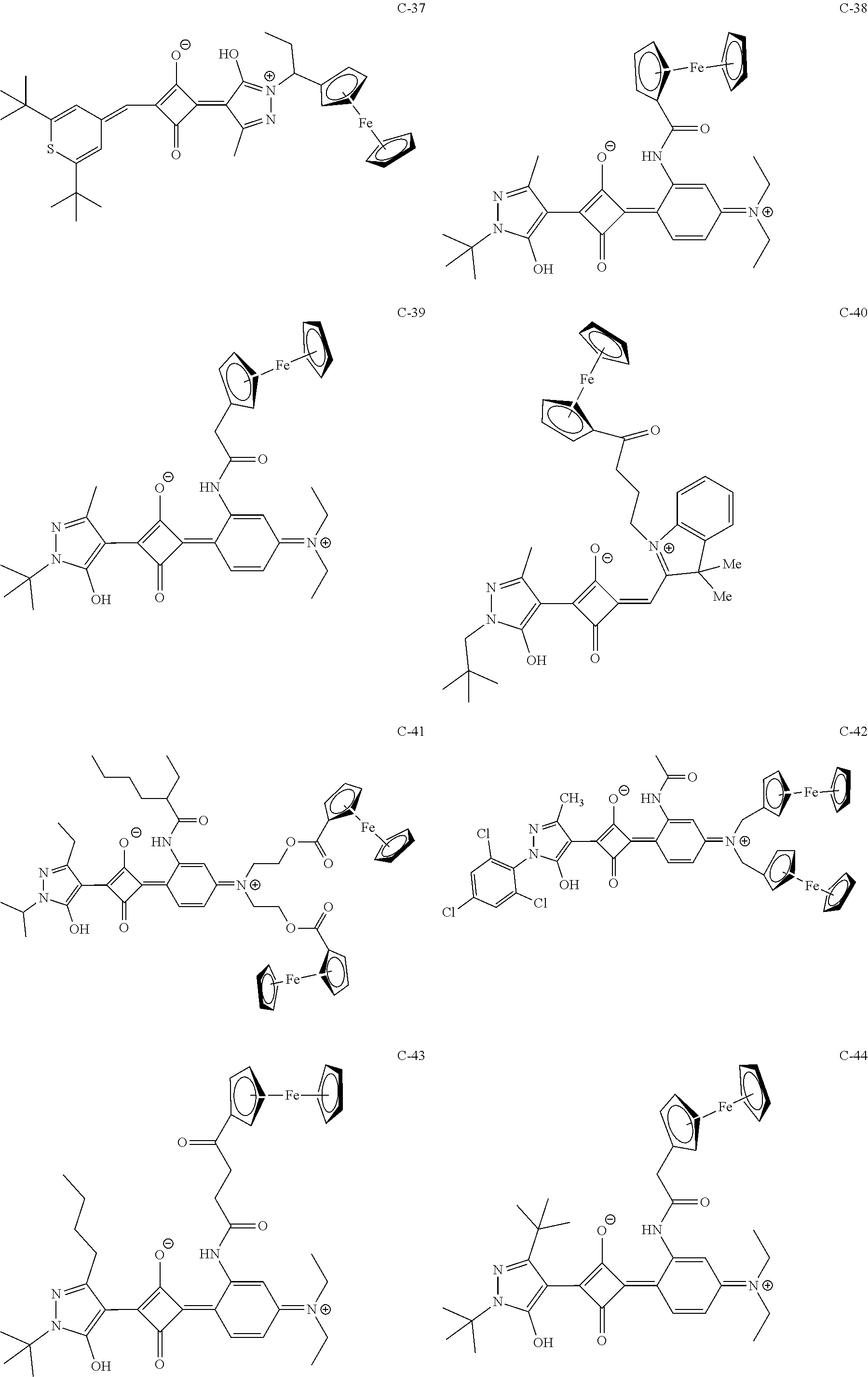

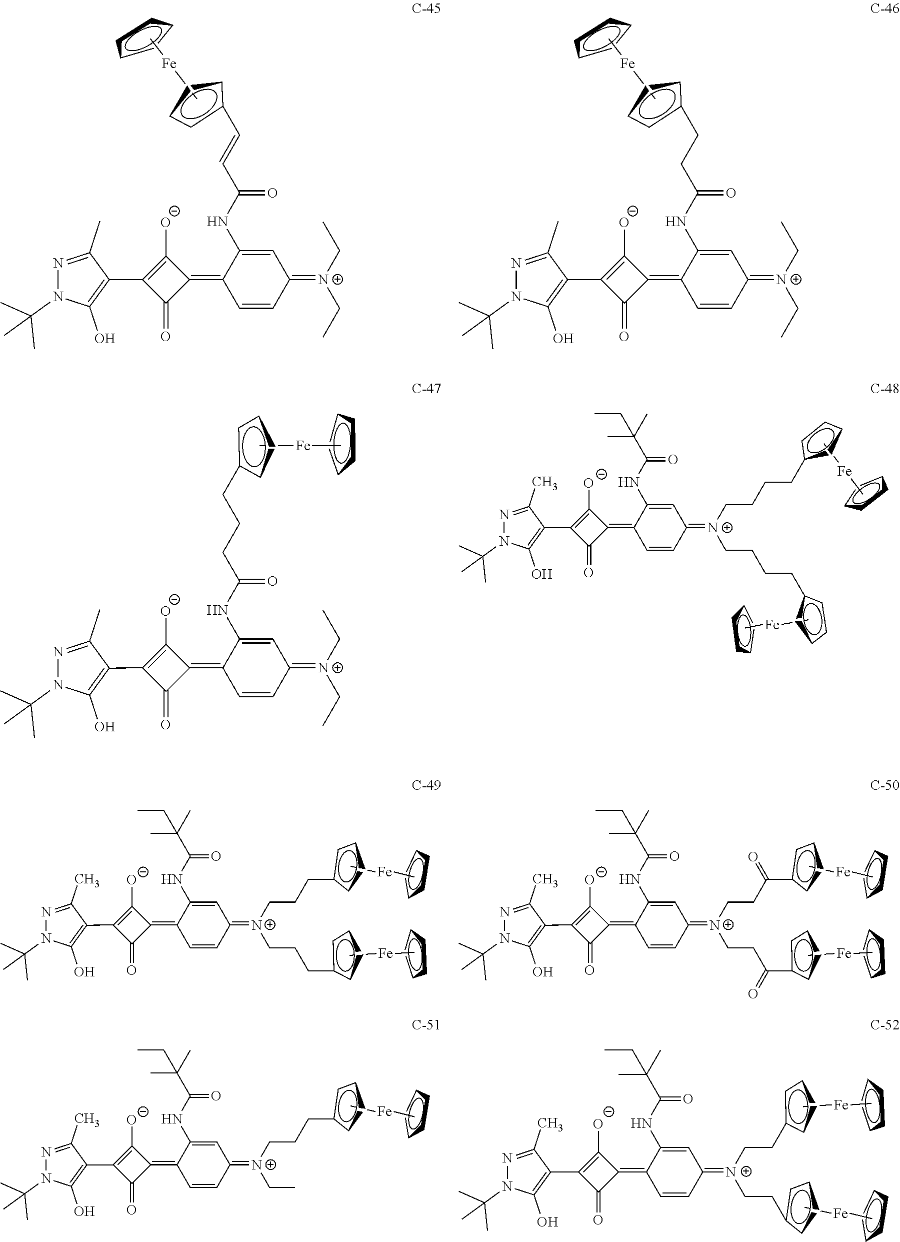

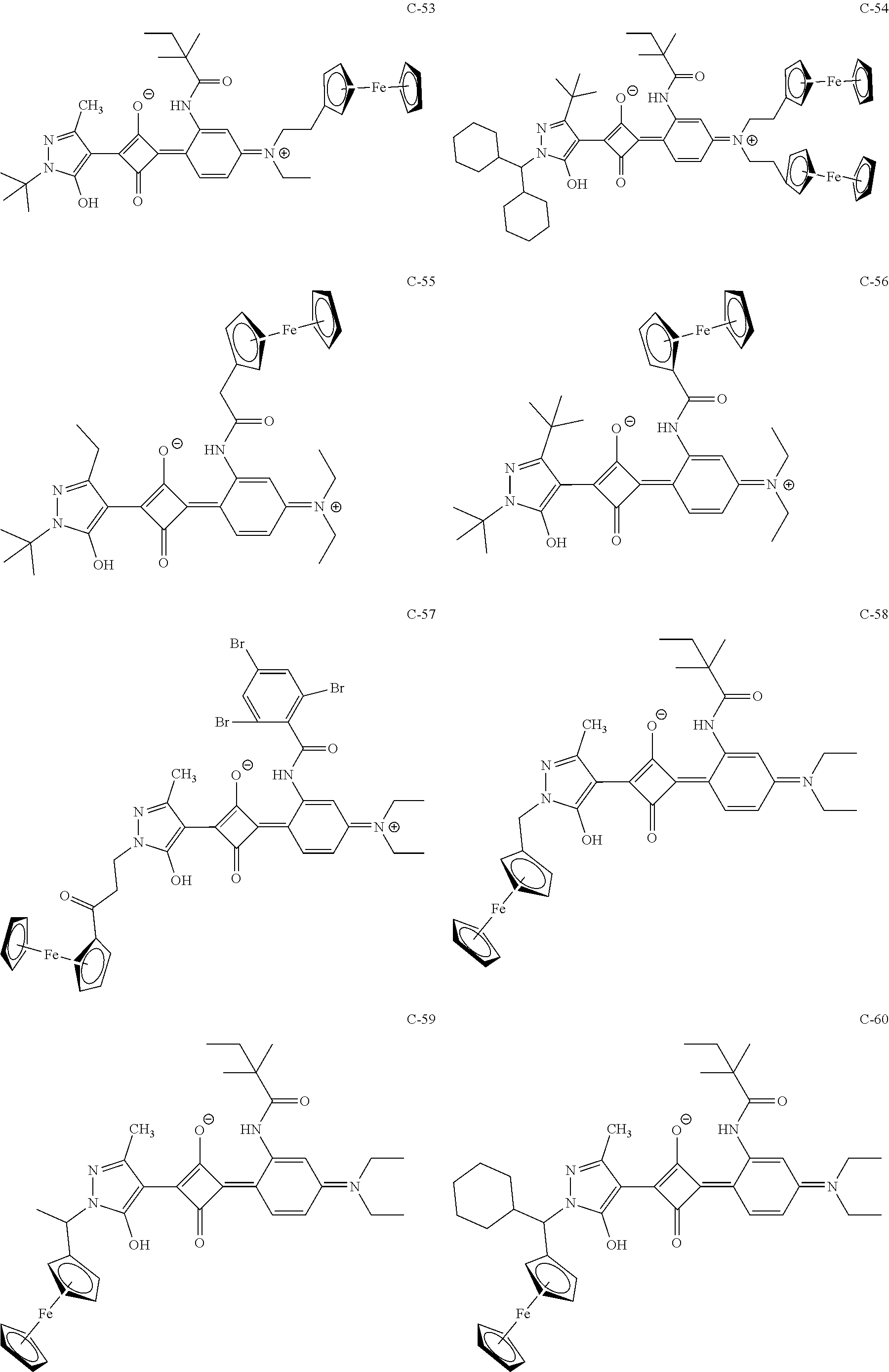

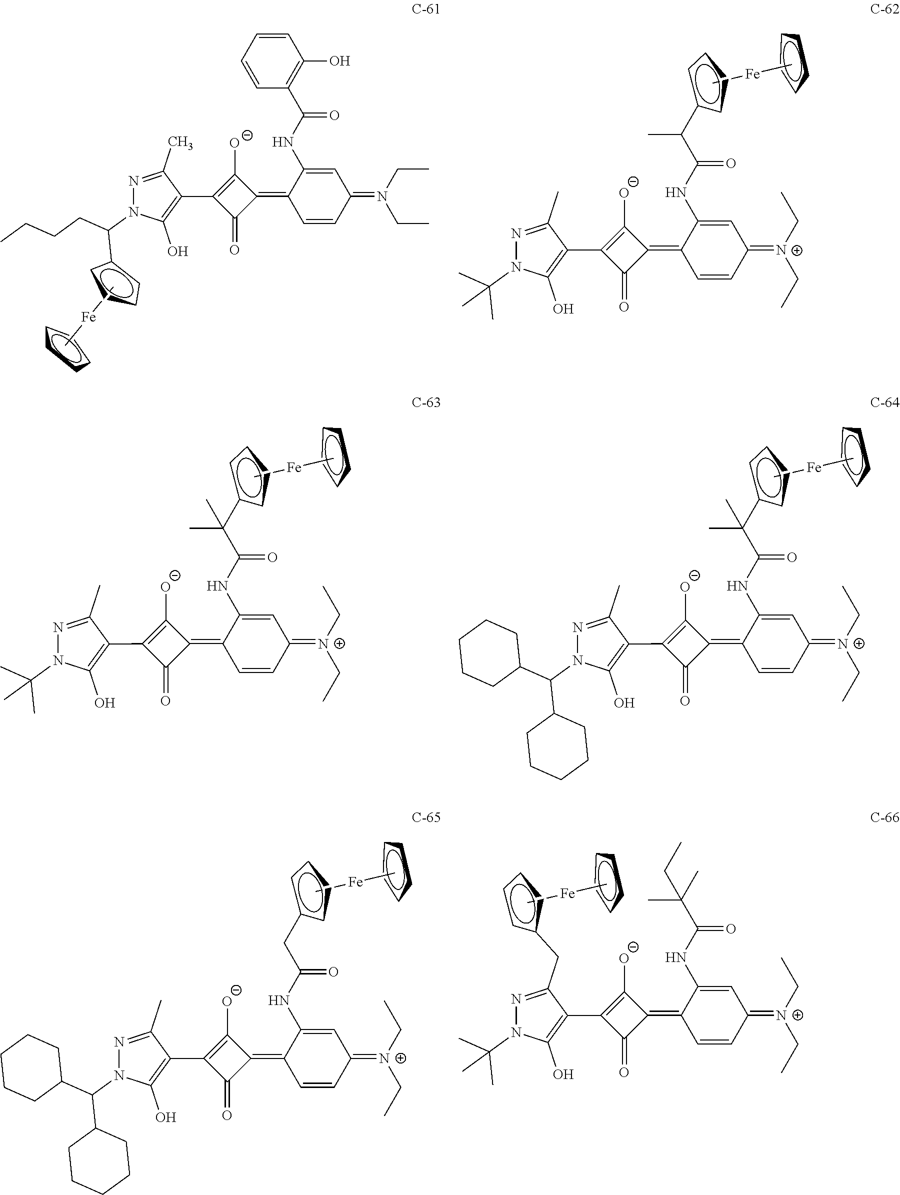

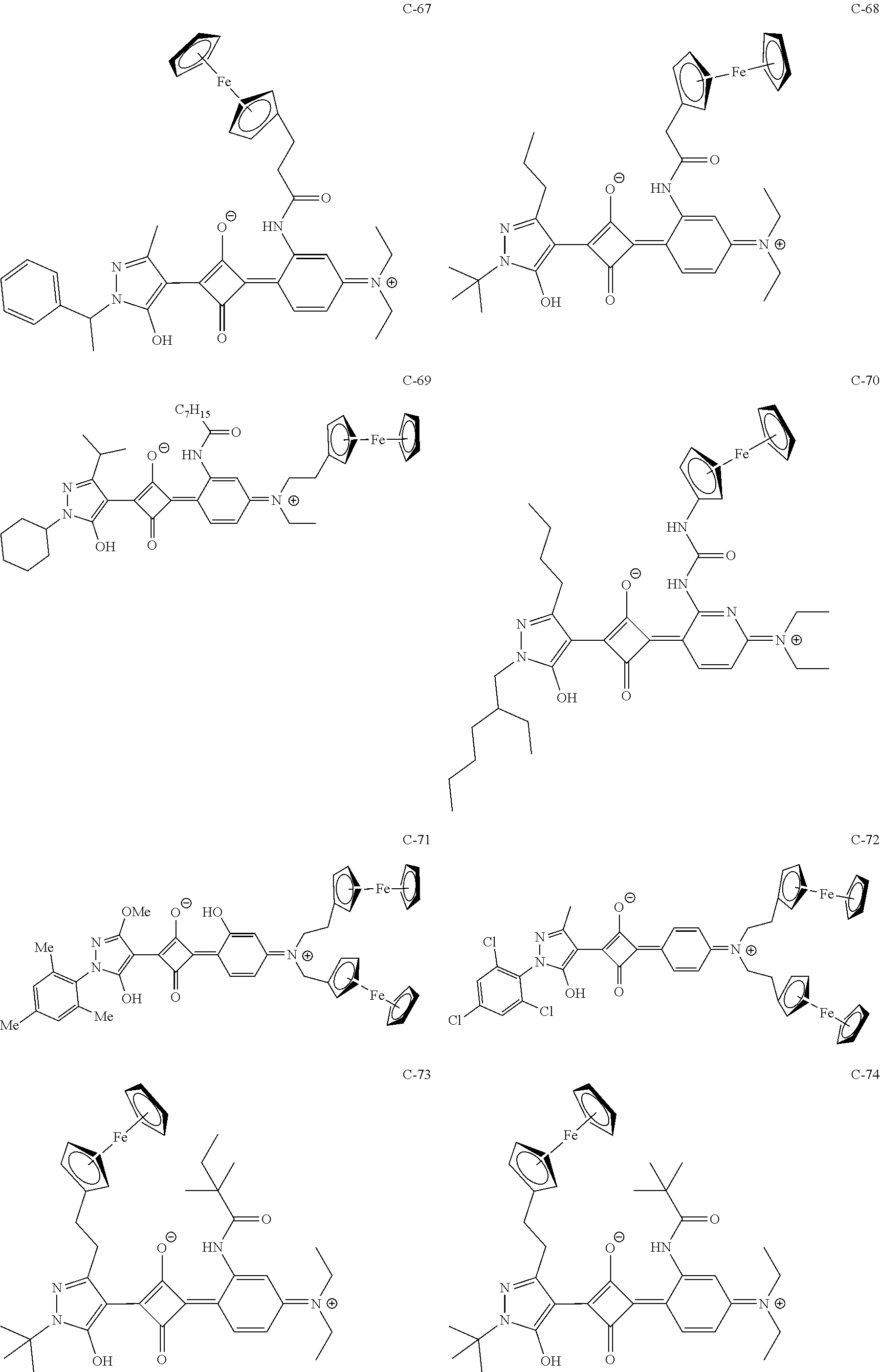

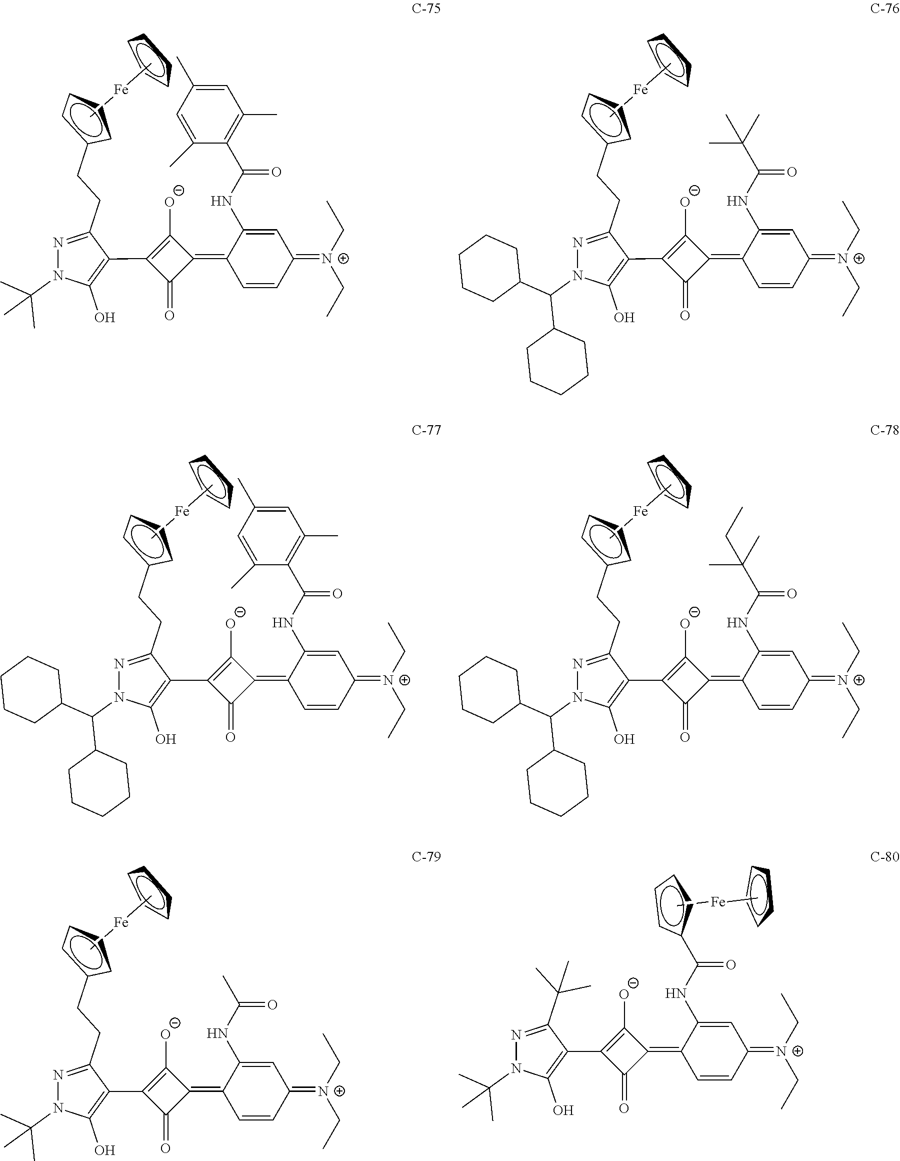

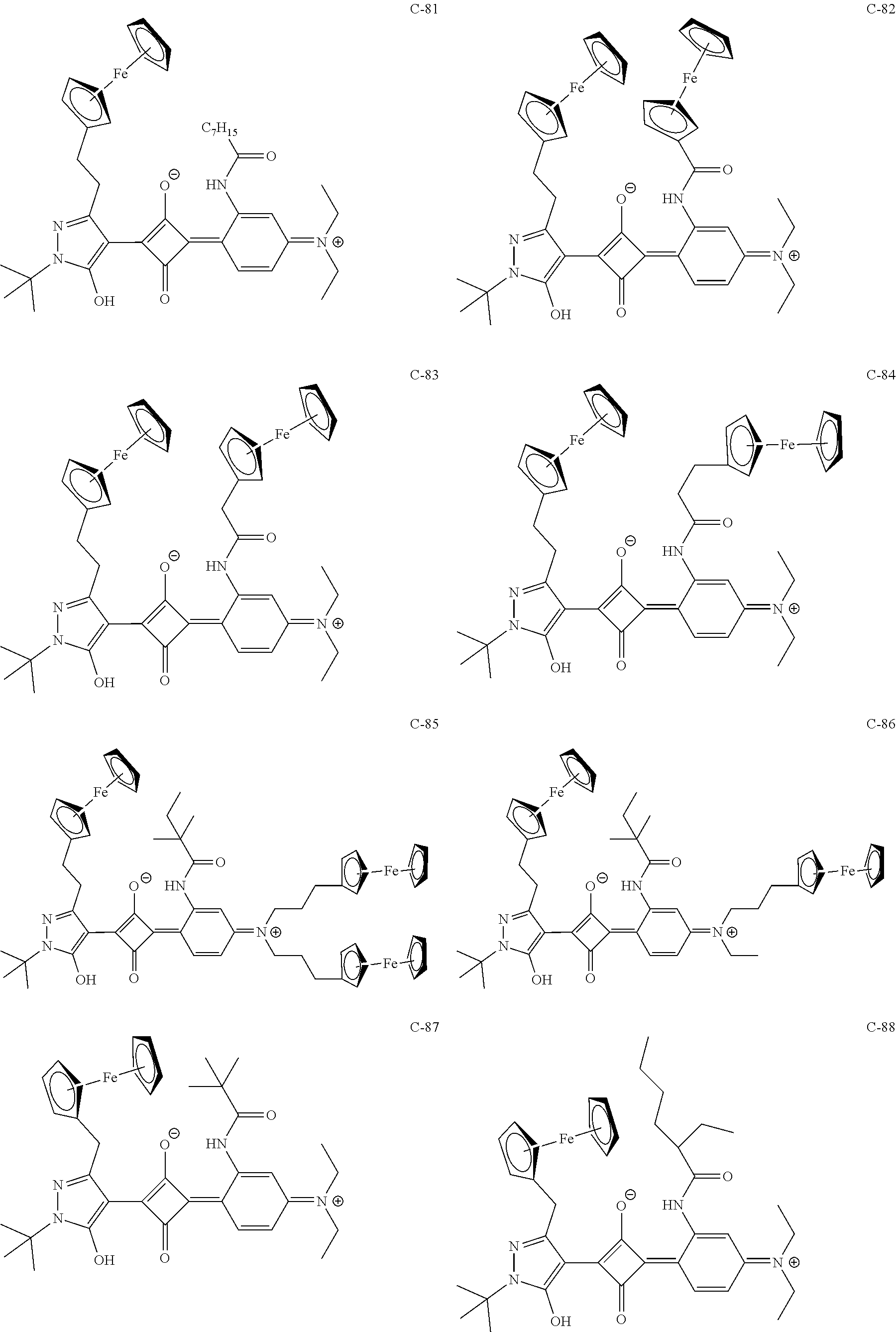

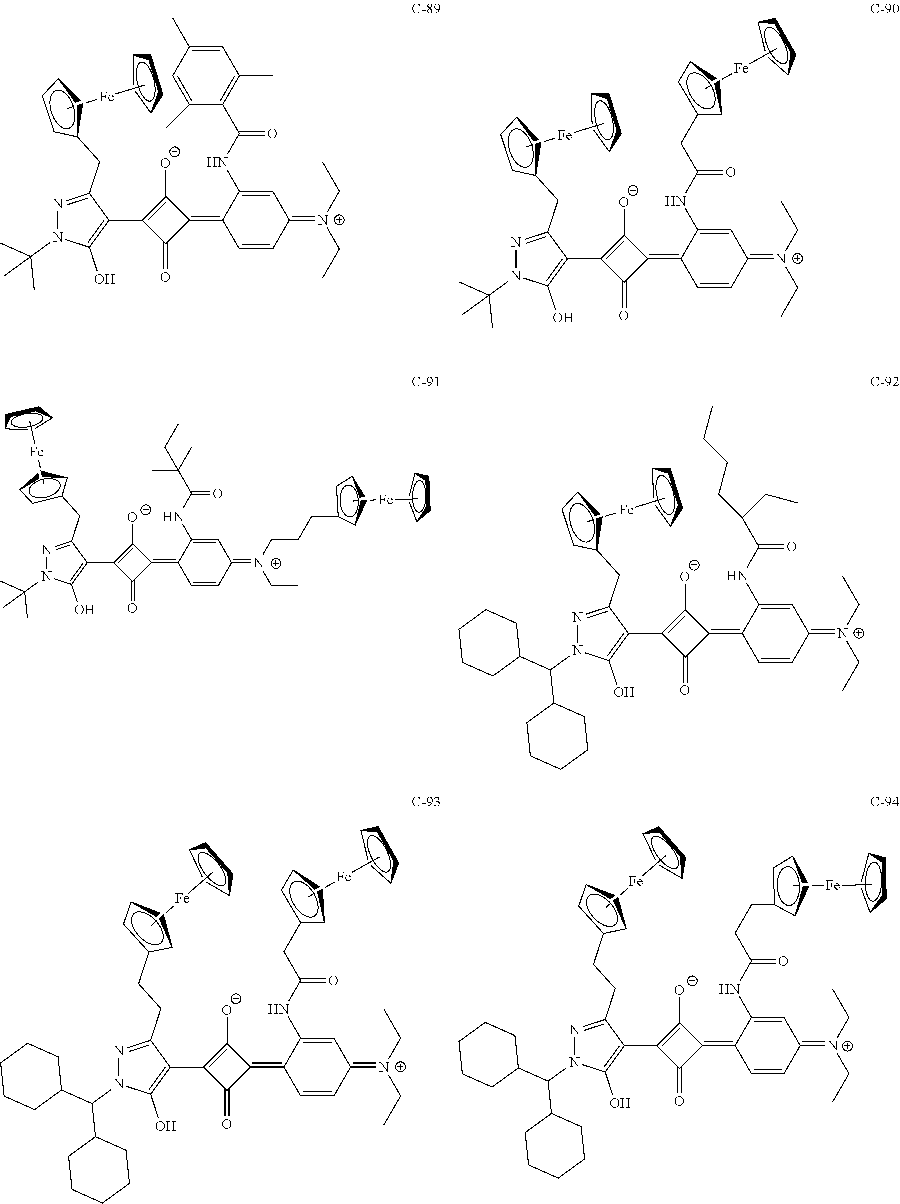

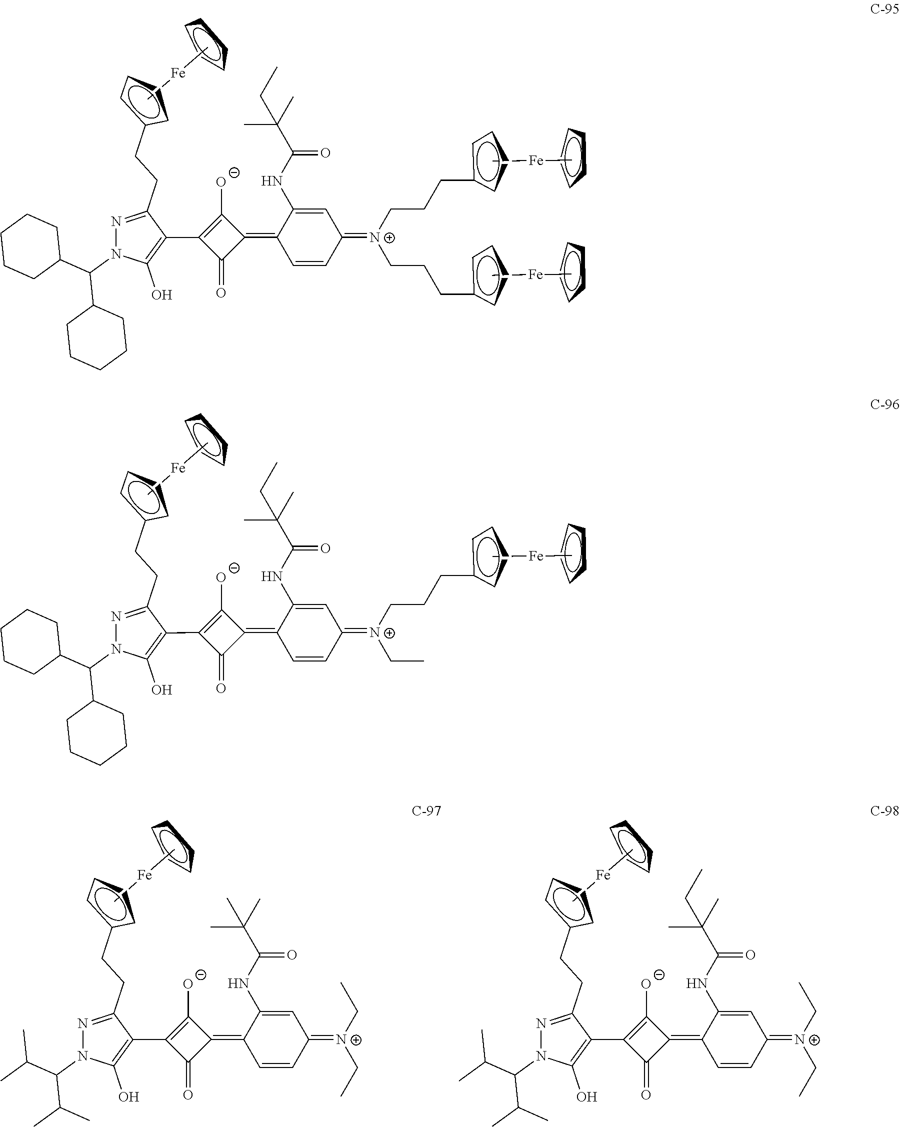

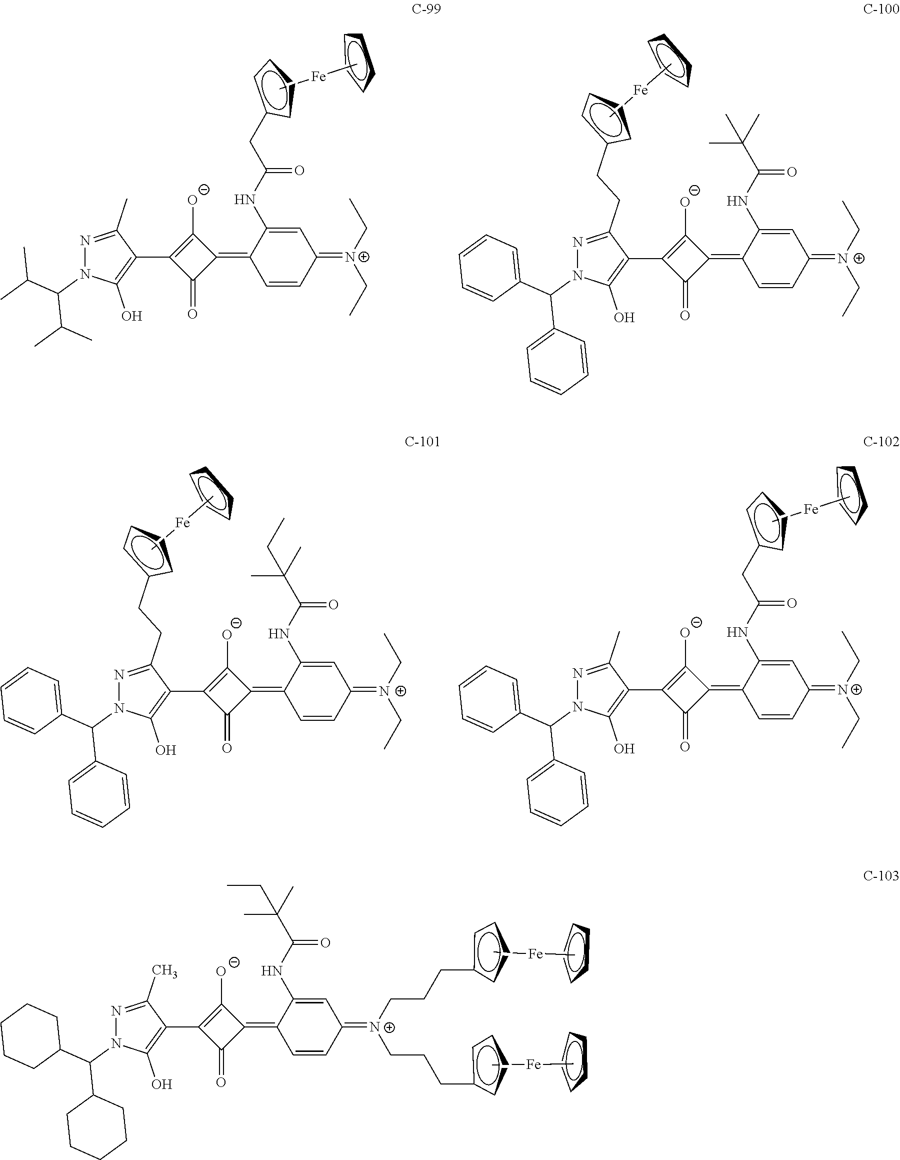

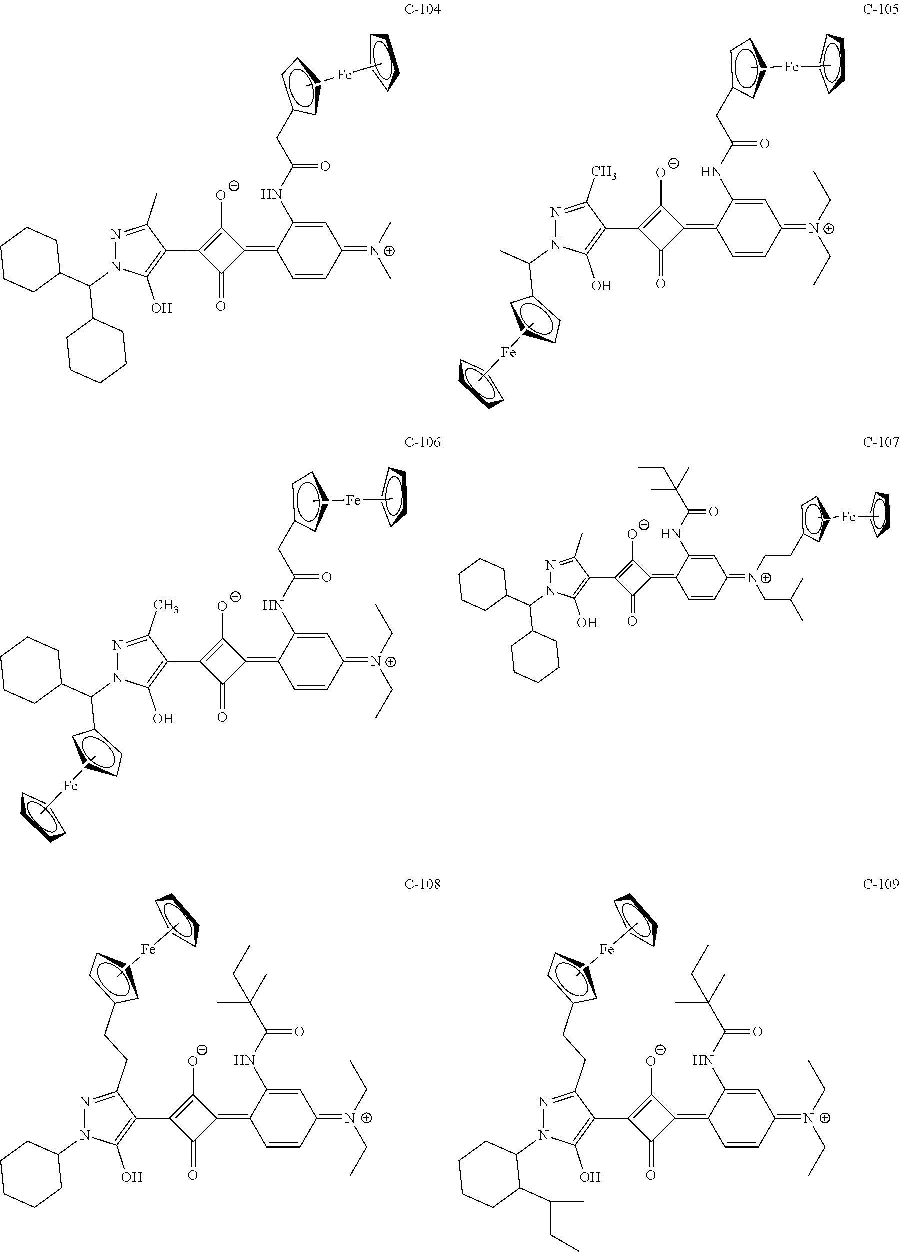

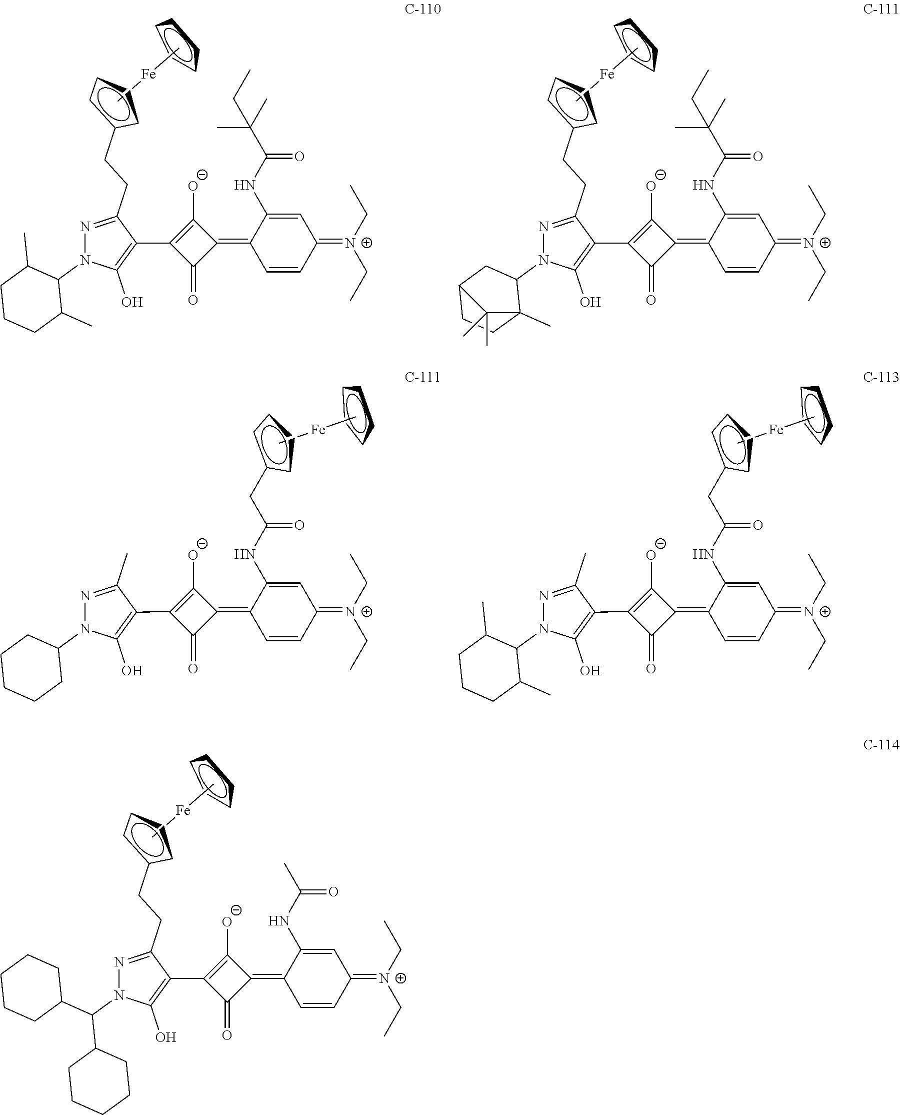

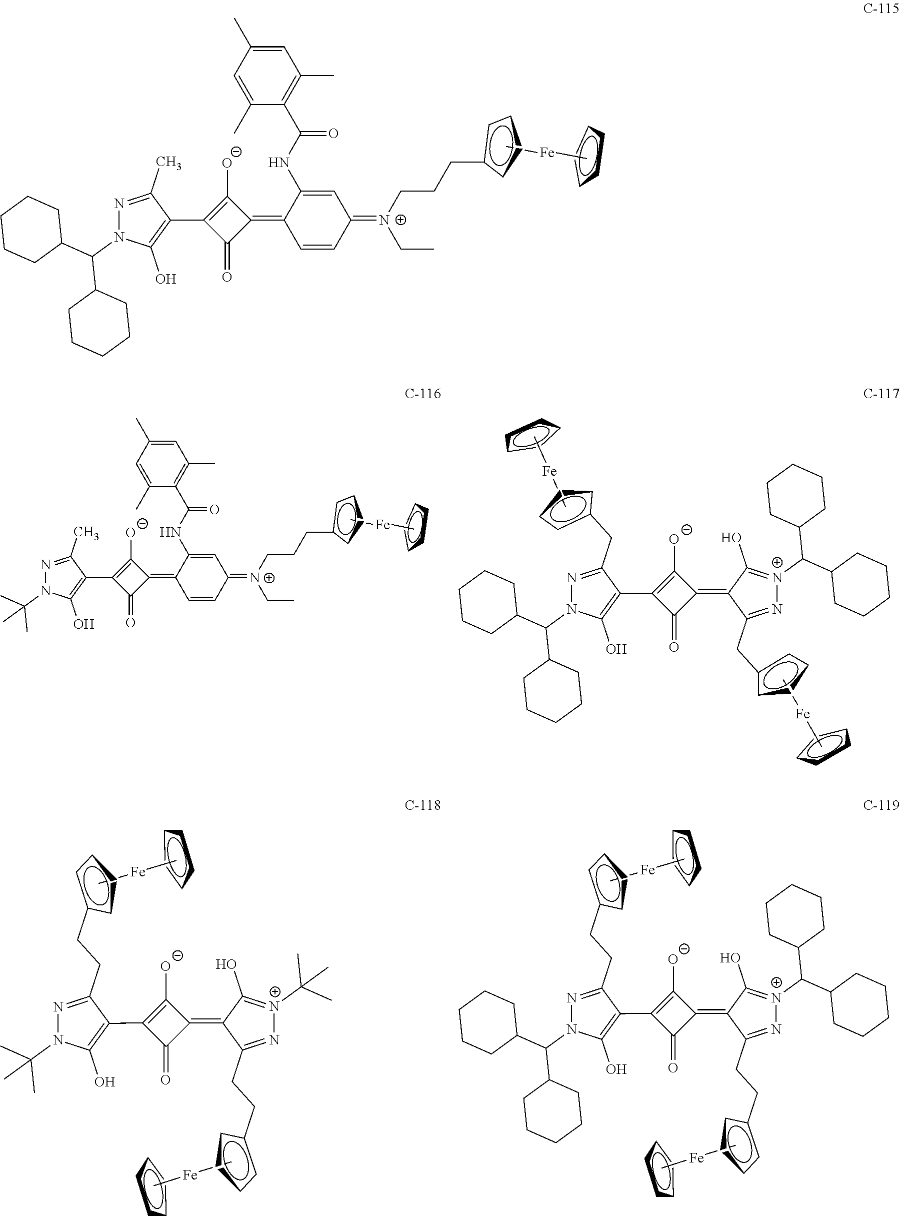

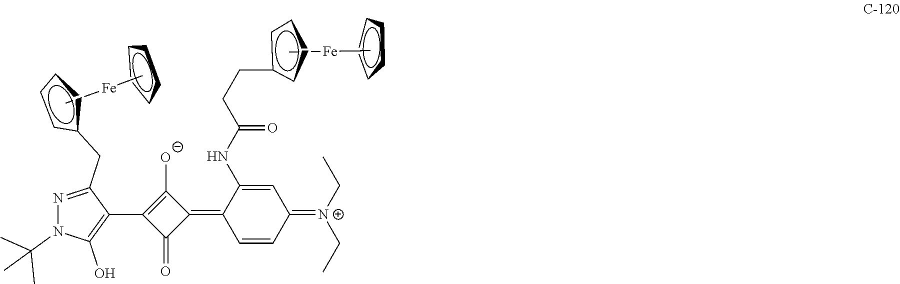

(2) Benzylidene-based or cinnamylidene-based coloring agent represented by General Formula (V)

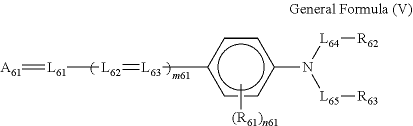

In the formula, A₆₁ represents an acidic nucleus, L₆₁, L₆₂, and L₆₃ each independently represent a methine group which may be substituted, L₆₄ and L₆₅ each independently represent an alkylene group having 1 to 4 carbon atoms. R₆₂ and R₆₃ each independently represent a cyano group, —COOR₆₄ (that is, —C(═O)R₆₄), —CONR₆₅R₆₆ (that is, —C(═O)NR₆₅R₆₆), —COR₆₄ (that is, —C(═O)OR₆₄), —SO₂R₆₄, or —SO₂NR₆₅R₆₆, where R₆₄ represents an alkyl group, an alkenyl group, a cycloalkyl group, or an aryl group, R₆₅ and R₆₆ each independently represent a hydrogen atom, an alkyl group, an alkenyl group, a cycloalkyl group, or an aryl group. R₆₁ represents a substituent, m₆₁ is an integer of 0 or 1, and n₆₁ is an integer of 0 to 4.

In the compounds (the coloring agents) represented by General Formula (V), m₆₁ is an integer of 0 or 1, where among these, a compound in a case where m₆₁ is 0 is called a benzylidene coloring agent, which is a yellow coloring agent in many cases, and a compound in a case where m₆₁ is 1 is called a cinnamylidene coloring agent, which is a magenta coloring agent in many cases.

In the present invention, m₆₁ in General Formula (V) is preferably 0, and the compound represented by General Formula (V) is preferably a yellow coloring agent.

Hereinafter, each substituent in General Formula (V) will be described in detail.

The A₆₁ represents an acidic nucleus, and it is preferably a cyclic ketomethylene compound or a compound having a methylene group sandwiched between electron withdrawing groups. In a case where A₆₁ is a cyclic ketomethylene compound, the carbon atom constituting methylene in the ketomethylene moiety is bonded to L₆₁ by a double bond. In a case where A₆₁ is a compound having a methylene group sandwiched between electron withdrawing groups, the carbon atom constituting methylene in the methylene moiety sandwiched between electron withdrawing groups is bonded to L₆₁ by a double bond.

Examples of the cyclic ketomethylene compound include 2-pyrazoline-5-one, 1,2,3,6-tetrahydropyridine-2,6-dione, rhodanine, hydantoin, thiohydantoin, 2,4-oxazolidinedione, isooxazolone, barbituric acid, thiobarbituric acid, indandione, dioxopyrazolopyridine, hydroxypyridine, pyrazolidinedione, 2,5-dihydrofuran-2-one, and pyrroline-2-one. These groups may each have a substituent.

The compound having a methylene group sandwiched between electron withdrawing groups can be represented by Z₅₁—CH₂—Z₅₂. Here, Z₅₁ and Z₅₂ each represent a cyano group, —SO₂R₅₁, —COR₅₁, —COOR₅₁, —CON(R₅₂)₂, —SO₂N(R₅₂)₂, —C[|C(CN)₂]R₅₁, or —C[═C(CN)₂]N(R₅₁)₂, where R₅₁ represents an alkyl group, an alkenyl group, a cycloalkyl group, an aryl group, or a heterocyclic group, and R₅₂ represents a hydrogen atom or a group mentioned as R₅₁. The substituents that can be respectively employed as R₅₁ and R₅₂ may have a substituent, and in a case where a plurality of R₅₁ or a plurality of R₅₂ are present in a molecule, they may be the same or different from each other. Z₅₁ and Z₅₂ may be the same.

The A₆₁ is preferably the cyclic ketomethylene compound, more preferably 2-pyrazoline-5-one, isooxazolone, hydroxypyridine, pyrazolidinedione, or barbituric acid, still more preferably isooxazolone, pyrazolidinedione, or barbituric acid, and particularly preferably pyrazolidinedione.

L₆₁, L₆₂, and L₆₃ described above represent a methine group which may have a substituent, and the substituents which may be contained in the methine group may be linked to each other to form a 5-membered or 6-membered ring (for example, cyclopentene or cyclohexene).

Examples of the substituent which may be contained in the methine group include a sulfonamide group (for example, methane sulfonamide, benzene sulfonamide, or octane sulfonamide), a sulfamoyl group (for example, sulfamoyl, methylsulfamoyl, phenylsulfamoyl, or butylsulfamoyl), a sulfonylcarbamoyl group (for example, methanesulfonylcarbamoyl or benzenesulfonylcarbamoyl), an acylsulfamoyl group (for example, acetylsulfamoyl, pivaloylsulfamoyl, or benzoylsulfamoyl), a chain-like or cyclic alkyl group (for example, methyl, isopropyl, cyclopropyl, cyclohexyl, 2-ethylhexyl, dodecyl, octadecyl, 2-phenethyl, or benzyl), an alkenyl group (for example, vinyl or allyl), an alkoxy group (for example, methoxy, octyloxy, dodecyloxy, or 2-methoxyethoxy), an aryloxy group (for example, phenoxy), a halogen atom (for example, F, Cl, or Br), an amino group (for example, amino, diethylamino, or ethyldodecylamino), an alkoxycarbonyl group (for example, ethoxycarbonyl, octyloxycarbonyl, or 2-hexyldecyloxycarbonyl), an acyloxy group (for example, acetyloxy), an acylamino group (for example, acetylamino, pivaloylamino, or benzoylamino), a carbamoyl group (for example, unsubstituted carbamoyl, ethylcarbamoyl, diethylcarbamoyl, phenylethylcarbamoyl), an aryl group (for example, phenyl or naphthyl), an alkylthio group (for example, methylthio or octylthio), an arylthio group (for example, phenylthio or naphthylthio), an acyl group (for example, acetyl, benzoyl, or pivaloyl), a sulfonyl group (for example, methanesulfonyl or benzenesulfonyl), a ureido group (for example, 3-propylureido or 3,3-dimethylureido), a urethane group (for example, methoxycarbonylamino or butoxycarbonylamino), a cyano group, a hydroxyl group, a nitro group, and a heterocyclic group (for example, a benzoxazole ring, a pyridine ring, a sulfolane ring, a furan ring, a pyrrole ring, a pyrrolidine ring, a morpholine ring, a piperazine ring, a pyrimidine ring).

L₆₁, L₆₂, and L₆₃ are preferably represented by ═CR₆₇— (R₆₇ represents an alkyl group or a hydrogen atom having 1 to 10 carbon atoms).

Further, the combination of L₆₁, L₆₂, and L₆₃ is a methine group in which all L₆₁, L₆₂, and L₆₃ are a methine group in which R₆₇ is a hydrogen atom, or a methine group in which L₆₁ and L₆₃ are both a methine group in which R₆₇ is a hydrogen atom, where it is preferable that L₆₂ is a methine group in which R₆₇ is a methyl group, and it is more preferable that all L₆₁, L₆₂, and L₆₃ are a methine group in which R₆₇ is a hydrogen atom.

L₆₄ and L₆₅ described above each independently represent an alkylene group having 1 to 4 carbon atoms, and they are preferably a methylene group or an ethylene group. It is preferable that L₆₄ and L₆₅ are the same substituent.

R₆₂ and R₆₃ each independently represent a cyano group, —COOR₆₄, —CONR₆₅R₆₆, —COR₆₄, —SO₂R₆₄, or —SO₂NR₆₅R₆₆.

R₆₄ represents an alkyl group (however, the cycloalkyl group is excluded, and examples thereof include methyl, ethyl, i-propyl, t-butyl, benzyl, trifluoromethyl, 2-chloroethyl, or 2-ethoxyethyl), an alkenyl group (for example, vinyl, allyl, or oleyl), a cycloalkyl group (for example, cyclopentyl or cyclohexyl), or an aryl group (for example, phenyl, 2-naphthyl, 4-chlorophenyl, 2-methoxyphenyl, or 3-dimethylaminophenyl), where it is preferably an alkyl group, a cycloalkyl group, or an aryl group, and more preferably a linear unsubstituted alkyl group, a cycloalkyl group, or an aryl group.

R₆₅ and R₆₆ each independently represent a group mentioned as R₆₄ (that is, an alkyl group, an alkenyl group, a cycloalkyl group, or an aryl group) or a hydrogen atom, and they are preferably an alkyl group, an aryl group, or a hydrogen atom, and more preferably a linear unsubstituted alkyl group or a hydrogen atom.

The number of carbon atoms of the alkyl group, alkenyl group, and cycloalkyl group that can be employed as R₆₅ and R₆₆ is preferably 1 to 20, more preferably 6 to 20, and particularly preferably 8 to 16. The number of carbon atoms of the aryl group that can be employed as R₆₅ and R₆₆ is preferably 6 to 20 and more preferably 6 to 18.

R₆₅ and R⁶⁶ may be linked to each other to form a nitrogen-containing heterocyclic ring.

R₆₂ and R₆₃ is preferably a cyano group, —COOR₆₄, or —CONR₆₅R₆₆, more preferably a cyano group or —COOR₆₄, and still more preferably —COOR₆₄.

In a case where R₆₂ and R₆₃ are a cyano group, L₆₄ and L₆₅ are each preferably an ethylene group, and in a case where R₆₂ and R₆₃ are a —COOR₆₄ group, L₆₄ and L₆₅ are each preferably a methylene group. R₆₂ and R₆₃ may be the same or different from each other, and they are preferably the same.

The R₆₁ represents a substituent, and preferred examples thereof include the examples of the substituent which may be contained in the methine group, which are described as L₆₁, L₆₂, and L₆₃. R⁶¹ is more preferably an alkyl group, an alkoxy group, a dialkylamino group, or an alkoxycarbonyl group, still more preferably an alkyl group or an alkoxy group, and particularly preferably a methyl group or a methoxy group.

n₆₁ is an integer of 0 to 4, preferably an integer of 0 or 1, and more preferably 0. In a case where n₆₁ is 1, it is preferable that R₆₁ is substituted at the meta position of an amino group.

Specific examples of the coloring agent represented by General Formula (V) will be shown below; however, the present invention is not limited thereto. In the following structures, * indicates a bonding site. Unless otherwise specified, the alkyl group means a linear alkyl group.

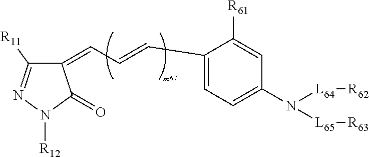

| Exemplary | | | | | | |
|---|---|---|---|---|---|---|
| compound | R₁₁ | R₁₂ | m₆₁ | R61 | —L₆₄—R₆₂ | —L₆₅—R₆₃ |
| A-87 | *—CH₃ | 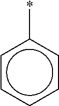 | 0 | *—H | *—CH₂COOC₁₂H₂₅ | *—CH₂COOC₁₂H₂₅ |
| A-88 | *—COOC₁₂H₂₅ | 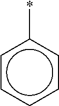 | 0 | *—H | *—CH₂CH₃CN | *—CH₃CH₂CN |
| A-89 | *—CN | 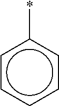 | 0 | *—H | 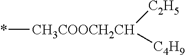 | 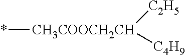 |
| A-90 | *—OC₂H₅ | 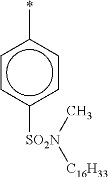 | 0 | *—CH₃ | *—CH₂COOCH₃ | *—CH₂COOCH₃ |
| A-91 | 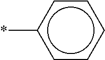 | *—CH₃ | 0 | *—OCH₂ | 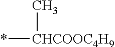 | *—CH₂COOC₁₂H₂₅ |
| A-92 | *—CH₃ | 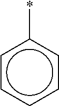 | 1 | *—CH₃ | *—CH₂COOC₁₀H₂₁ | *—CH₂COOC₁₀H₂₁ |
| A-93 | *—CN | 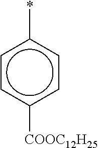 | 1 | *—H | *—CH₂CH₂CN | *—CH₃CH₂CN |
| A-94 | *—CONHC₁₂H₂₅ | 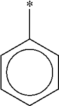 | 1 | *—OCH₃ | *—CH₂CH₂COOC₄H₃-i | *—CH₂CN |

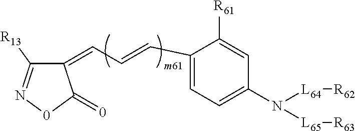

| Exemplary | | | | | |
|---|---|---|---|---|---|
| compound | R₁₃ | m₆₁ | R₆₁ | —L₆₄—R₆₂ | —L₆₅—R₆₃ |
| A-95 | 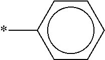 | 0 | *—H | *—CH₂COOC₁₂H₂₅ | *CH₂COOC₁₂H₂₅ |
| A-96 | 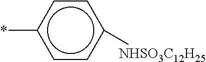 | 0 | *—H | *—CH₂CH₃CN | *—CH₂CH₂CN |
| A-97 | *—C₄H₉-t | 0 | *—CH₃ | *—CH₂CONHC₁₀H₂₁ | *—CH₂CONHC₁₀H₂₁ |
| A-98 | 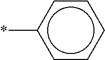 | 1 | *—CH₃ | *—CH₂COOC₁₂H₂₅ | *—CH₂COOC₁₂H₂₅ |
| A-99 | *—CH₃ | 1 | *—OCH₃ | 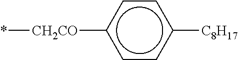 | 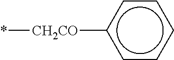 |

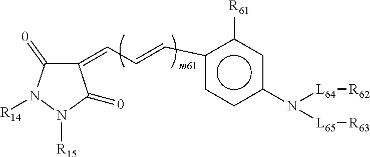

| Ex- | | | | | | |
|---|---|---|---|---|---|---|
| em- | | | | | | |
| plary | | | | | | |
| com- | | | | | | |
| pound | R₁₄ | R₁₅ | m₆₁ | R₆₁ | —L₆₄—R₆₂ | —L₆₅—R₆₃ |
| A-100 | 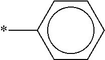 | 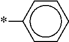 | 0 | *—H | *—CH₃COOC₁₂H₂₅ | *—CH₂COOC₁₂H₂₅ |
| A-101 | 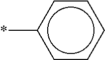 | 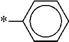 | 0 | *—OCH₃ | *—CH₂COOC₁₆H₃₃ | *—CH₂COOC₁₆H₃₃ |
| A-102 | 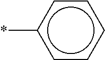 | 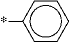 | 0 | *—H | 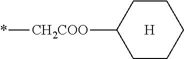 | 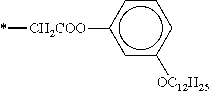 |
| A-103 | 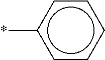 | 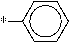 | 0 | *—OC₁₂H₂₅ | *—CH₂CH₂CN | *—CH₂CH₂CN |
| A-104 | 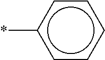 | 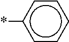 | 0 | *—H | 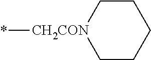 | 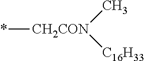 |
| A-105 | 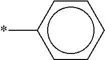 | 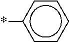 | 0 | *—H | *—CH₂CH₂SO₂C₁₂H₂₅ | 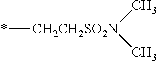 |
| A-106 | 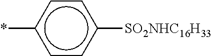 | 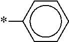 | 0 | *—H | *—CH₂CH₂CN | *—CH₂CH₂CN |
| A-107 | 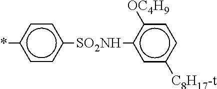 | 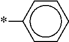 | 0 | *—H | *—CH₂COOCH₃ | *—CH₂COOCH₃ |
| A-108 | *—CH₃ | *—CH₃ | 0 | *—H | 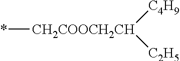 | 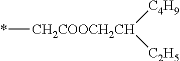 |
| A-109 | 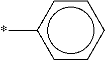 | 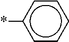 | 0 | *—CH₃ | 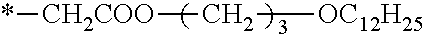 | 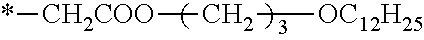 |
| A-110 | 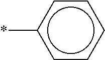 | 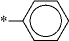 | 1 | *—H | *—CH₂COOC₁₂H₂₅ | *—CH₂COOC₁₂H₂₅ |
| A-111 | 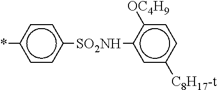 | 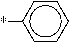 | 1 | *—H | *—CH₂CH₂CN | *—CH₂CH₂CN |
| A-112 | 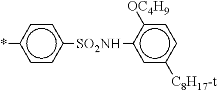 | 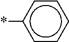 | 1 | *—H | *—CH₂COOC₁₂H₂₅ | *—CH₂COOC₁₂H₂₅ |

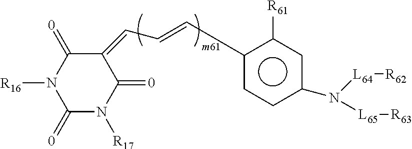

| Ex- | | | | | | |
|---|---|---|---|---|---|---|
| em- | | | | | | |
| plary | | | | | | |
| com- | | | | | | |
| pound | R₁₆ | R₁₇ | m₆₁ | R₆₁ | —L₆₄—R₆₂ | —L₆₅—R₆₃ |
| A-113 | *—CH₃ | *—CH₃ | 0 | *—H | *—CH₂COOC₁₀H₂₁ | *—CH₂COOC₁₀H₂₁ |
| A-114 | *—CH₃ | *—CH₃ | 0 | *—CH₃ | 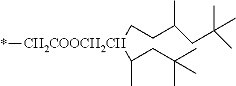 | 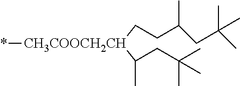 |
| A-115 | *—C₈H₁₇ | *—C₈H₁₇ | 0 | *—H | *—CH₂CH₂CN | *—CH₂CH₂CN |
| A-116 | *—CH₃ | *—CH₃ | 0 | *—OC₁₂H₂₃ | *—CH₂CH₂CN | *—CH₂CH₃CN |
| A-117 | *—CH₃ | *—CH₃ | 0 | *—H | 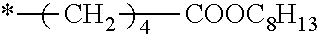 | 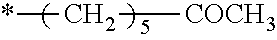 |
| A-118 | *—CH₃ | *—CH₃ | 1 | *—H | 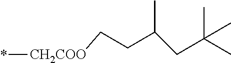 | 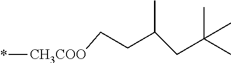 |
| A-119 | 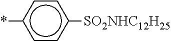 | *—CH₃ | 0 | *—H | *—CH₂COOC₂H₅ | *—CH₂COOC₂H₅ |
| A-120 | *—CH₃ | *—CH₃ | 1 | *—COOCH₃ | *—CH₂CH₂COOC₈H₁₇ | *—CH₂CH₂CN |

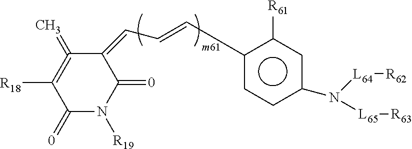

| Exemplary | | | | | | |
|---|---|---|---|---|---|---|
| compound | R₁₈ | R₁₉ | m₆₁ | R₆₁ | —L₆₄—R₆₂ | —L₆₅—R₆₃ |
| A-121 | *—CN | *—C₂H₅ | 0 | H | *—CH₃COOC₁₂H₂₅ | *—CH₂COOC₁₂H₂₅ |
| A-122 | *—CN | 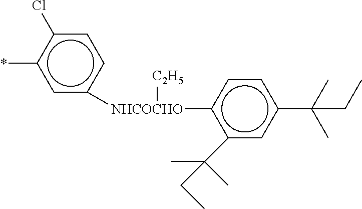 | 0 | H | *—CH₂CH₂CN | *—CH₂CH₃CN |
| A-123 | *—CONH₂ | *—C₂H₅ | 0 | H | *—CH₂COOC₁₀H₂₁ | *—CH₂COOC₁₀H₂₁ |
| A-124 | *—CN | *—C₁₂H₂₅ | 1 | H | *—CH₂CH₃CN | *—CH₂COOC₁₆H₃₃ |
| A-125 | *—CN | 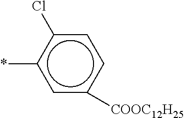 | 1 | H | *—CH₂COOCH₃ | *—CH₂COOCH₃ |
| A-126 | *—CONH₂ | 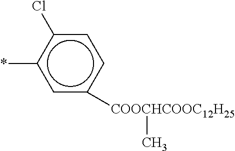 | 1 | CH₃ | *—CH₂COOC₂H₅ | *—CH₂COOC₂H₅ |

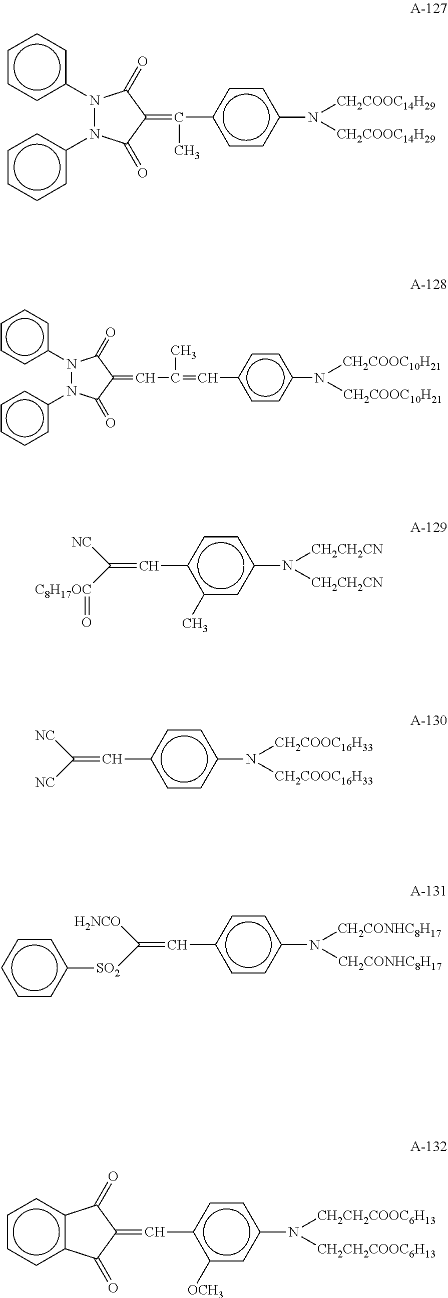

In the light absorption filter according to the embodiment of the present invention, the total content of the dye is preferably 0.10 parts by mass or more, more preferably 0.15 parts by mass or more, still more preferably 0.20 parts by mass or more, particularly preferably 0.25 parts by mass or more, and especially preferably 0.30 parts by mass or more, with respect to 100 parts by mass of the resin constituting the light absorption filter according to the embodiment of the present invention. In a case where the total content of the dye in the light absorption filter according to the embodiment of the present invention is equal to or larger than the above-described preferred lower limit value, a favorable antireflection effect can be obtained.

Further, in the light absorption filter according to the embodiment of the present invention, the total content of the dye is usually 50 parts by mass or less with respect to 100 parts by mass of the resin constituting the light absorption filter according to the embodiment of the present invention, preferably 40 parts by mass or less, and more preferably 30 parts by mass or less.

In the light absorption filter according to the embodiment of the present invention, the content of the squarine-based coloring agent represented by General Formula (1) or the benzylidene-based or cinnamylidene-based coloring agent represented by General Formula (V) is preferably 0.01 to 30 parts by mass and more preferably 0.1 to 10 parts by mass with respect to 100 parts by mass of the resin constituting the light absorption filter according to the embodiment of the present invention. It is noted that in the light absorption filter according to the embodiment of the present invention, all of the above dyes may be the squarine-based coloring agent represented by General Formula (1) or the benzylidene-based or cinnamylidene-based coloring agent represented by General Formula (V).

In a case where the dye includes the quencher-embedded coloring agent, the content of the quencher-embedded coloring agent is preferably 0.1 part by mass or more with respect to 100 parts by mass of the resin constituting the light absorption filter according to the embodiment of the present invention from the viewpoint of imparting light absorption properties such as an antireflection effect. The upper limit value thereof is preferably 45 parts by mass or less.

<Compound that Generates Radical Upon Ultraviolet Irradiation>

The compound that is used in the present invention which generates a radical upon ultraviolet irradiation (hereinafter, also referred to as a “radical generator”) is a compound that generates a radical upon ultraviolet irradiation and is not particularly limited as long as it has a function of decolorizing the dye. In the present invention, it is possible to preferably use a compound that absorbs light and generates a radical (hereinafter, also referred to as a “photoradical generator”). It is noted that the radical generated may be a biradical in addition to the typical radical.

As the photoradical generator, a compound commonly used as a photoradical polymerization initiator or a photoradical generator can be used without particular limitation, and examples thereof include an acetophenone generator, a benzoin generator, a benzophenone generator, a phosphine oxide generator, an oxime generator, a ketal generator, an anthraquinone generator, a thioxanthone generator, an azo compound generator, a peroxide generator, a disulfide generator, a lophine dimer generator, an onium salt generator, a borate salt generator, an active ester generator, an active halogen generator, an inorganic complex generator, and a coumarin generator. It is noted that a “XX generator” as the specific example of the photoradical generator may be individually referred to as a “XX compound” or “XX compounds”, and hereinafter, it is referred to as a “XX compound”.

Specific examples, preferred forms, commercially available products, and the like of the photoradical generator are respectively described as the specific examples, preferred forms, commercially available products, and the like of the photoradical initiator in paragraphs [0133] to [0151] of JP2009-098658A, and these can be similarly used suitably in the present invention.

The photoradical generator is preferably a compound that generates a radical upon intramolecular cleavage or a compound that abstracts a hydrogen atom from a compound present in the vicinity thereof to generate a radical, and it is more preferably a compound that abstracts a hydrogen atom from a compound present in the vicinity thereof to generate a radical, from the viewpoint of further improving the quenching rate.

The above-described compound that generates a radical upon intramolecular cleavage (hereinafter, also referred to as an “intramolecular cleavage type photoradical generator”) means a compound which generates a radical, where the compound absorbing light undergoes bonding cleavage in a homolytic manner.

Examples of the intramolecular cleavage type photoradical generator include an acetophenone compound, a benzoin compound, a phosphine oxide compound, an oxime compound, a ketal compound, an azo compound, a peroxide compound, a disulfide compound, an onium salt compound, a borate salt compound, an active ester compounds, an active halogen compound, an inorganic complex compound, and a coumarin compound. Among these, an acetophenone compound, a benzoin compound, or a phosphine oxide compound, which is a carbonyl compound, is preferable. The Norrish type I reaction is known as a photodecomposition reaction of an intramolecular cleavage type carbonyl compound, and this reaction can be referenced as a radical generation mechanism.

The above-described compound that abstracts a hydrogen atom from a compound present in the vicinity thereof to generate a radical (hereinafter, also referred to as a “hydrogen abstraction type photoradical generator”) means a carbonyl compound in an excited triplet state obtained upon light absorption that abstracts a hydrogen atom from a compound present in the vicinity thereof to generate a radical.

A carbonyl compound is known as the hydrogen abstraction type photoradical generator, and examples thereof include a benzophenone compound, an anthraquinone compound, and a thioxanthone compound. The Norrish type II reaction is known as a photodecomposition reaction of a hydrogen abstraction type carbonyl compound, and this reaction can be referenced as a radical generation mechanism.

Examples of the compound present in the vicinity include various components present in the light absorption filter, such as a resin, a dye, and a radical generator.

The compound present in the vicinity becomes a compound having a radical by a hydrogen atom being abstracted therefrom. Since a dye from which a hydrogen atom has been abstracted by the hydrogen abstraction type photoradical generator becomes an active compound having a radical, the dye may be faded or decolorized through a reaction such as the decomposition of the dye having the radical.

Further, in a case where the hydrogen abstraction type photoradical generator abstracts a hydrogen atom in the molecule, a biradical is generated.

The hydrogen abstraction type photoradical generator is preferably a benzophenone compound from the viewpoint of the quantum yield of the hydrogen abstraction reaction.

(Benzophenone Compound)

Examples of the benzophenone compound used as the hydrogen abstraction type photoradical generator include an alkylbenzophenone compound such as benzophenone, 2-methylbenzophenone, 3-methylbenzophenone, or 4-methylbenzophenone; a benzophenone compound having a halogen atom, such as 2-chlorobenzophenone, 4-chlorobenzophenone, or a 4-bromobenzophenone; a benzophenone compound substituted with a carboxy group or an alkoxycarbonyl group, such as 2-carboxybenzophenone, 2-ethoxycarbonylbenzophenone, benzophenone tetracarboxylic acid, or an tetramethyl ester thereof; a bis(dialkylamino)benzophenone compound (preferably a 4,4′-bis(dialkylamino)benzophenone compound), such as 4,4′-bis(dimethylamino)benzophenone, 4,4′-bis(dicyclohexylamino)benzophenone, 4,4′-bis(diethylamino)benzophenone, or 4,4′-bis(dihydroxyethylamino)benzophenone; and a benzophenone compound substituted with an alkoxy group, such as 4-methoxy-4′-dimethylaminobenzophenone, 4-methoxybenzophenone, or 4,4′-dimethoxybenzophenone.

Among the above-described benzophenone compounds, a benzophenone compound (also referred to as an alkoxybenzophenone compound) substituted with an alkoxy group is preferable from the viewpoint of realizing the achievement of both the light resistance of the unexposed portion and the decolorizing property of the exposed portion at a high level while reducing the molar formulation ratio of the radical generator to the dye.

The number of alkoxy groups contained in the benzophenone compound is preferably 1 to 3 and more preferably 1 or 2.

The moiety of the alkyl chain in the alkoxy group contained in the alkoxybenzophenone compound may be linear or branched. The alkoxy group preferably has 1 to 18 carbon atoms, more preferably 1 to 15 carbon atoms, and still more preferably 1 to 12 carbon atoms.

Regarding the substitution position of the alkoxy group in the alkoxybenzophenone compound, the alkoxy group is preferably provided at least at the 4-position, more preferably provided at least at the 4-position and the 4′-position, and still more preferably provided at the two positions of the 4-position and the 4′-position, from the viewpoint of realizing the achievement of both the light resistance of the unexposed portion and the decolorizing property of the exposed portion at a higher level while reducing the molar formulation ratio of the radical generator to the dye.

Various examples of the photoradical generator are also described in “Latest UV Curing Technology”, TECHNICAL INFORMATION INSTITUTE CO. LTD., 1991, p. 159, and “Ultraviolet Curing System”, written by Kiyomi Kato, 1989, published by SOGO GIJUTSU CENTER), p. 65 to 148, which can be also suitably used in the present invention.

In the photoradical generator, the maximal absorption wavelength of the ultraviolet ray to be absorbed is preferably in a range of 250 to 400 nm, more preferably in a range of 240 to 400 nm, and still more preferably in a range of 270 to 400 nm.

In a case where the photoradical generator is a benzophenone compound, the wavelength of the absorption maximum attributed to the n-π* transition, which is located on the longest wavelength side, is preferably in a range of 260 to 400 nm and more preferably in a range of 285 to 345 nm. The wavelength of the absorption maximum attributed to π-π*, which is located on the second longest wavelength side, is preferably in a range of 240 to 380 nm and more preferably in a range of 270 to 330 nm. In a case where the absorption maximum wavelength is set in the above range, the light of a light source used at the time of exposure, such as a metal halide lamp, is absorbed well. On the other hand, in a case of being incorporated into a display device, the light absorption filter becomes difficult to absorb an ultraviolet ray incident from the outside, and thus it becomes possible to achieve both the light resistance of the unexposed portion and the decolorizing property of the exposed portion.

Examples of the photoradical generator having absorption in a longer wavelength range include an alkoxybenzophenone compound.

In general, the maximal absorption wavelength of the ultraviolet ray absorbed by the photoradical generator is preferably separated by 30 nm or more from the main absorption wavelength band of the dye that has a main absorption wavelength band at a wavelength of 400 to 700 nm. The upper limit value thereof is not particularly limited.

Examples of the commercially available photocleavage type photoradical generator include “Irgacure 651”. “Irgacure 184”, “Irgacure 819”, “Irgacure 907”, “Irgacure 1870” (a mixed initiator of CGI-403/Irgacure 184=7/3), “Irgacure 500”. “Irgacure 369”. “Irgacure 1173”, “Irgacure 2959”, “Irgacure 4265”, “Irgacure 4263”, “Irgacure 127”, or “OXE01”, which are all product names, manufactured by BASF SE (formerly Ciba Specialty Chemicals Inc.); additionally, “Kayacure DETX-S”, “Kayacure BP-100”, “Kayacure BDMK”. “Kayacure CTX”, “Kayacure BMS”, “Kayacure 2-EAQ”, “Kayacure ABQ”, “Kayacure CPTX”, “Kayacure EPD”, “Kavacure ITX”, “Kayacure QTX”, “Kayacure BTC”, and “Kayacure MCA”, manufactured by Nippon Kayaku Co., Ltd.; and more additionally “Esacure (KIPI10F, KB1, EB3, BP, X33, KTO46, KT37, KIP150, and TZT)” manufactured by Sartomer Company Inc. Further, preferred examples thereof include a combination of two or more of these.

In the light absorption filter according to the embodiment of the present invention, the content of the radical generator (preferably the photoradical generator) is preferably 0.01 to 30 parts by mass and more preferably 0.1 to 20 parts by mass with respect to 100 parts by mass of the resin constituting the light absorption filter according to the embodiment of the present invention.

From the viewpoint of further improving the quenching rate, the formulation amount of the radical generator (preferably the photoradical generator) in the light absorption filter according to the embodiment of the present invention is preferably 0.1 to 20 mol with respect to 1 mol of the dye that has a main absorption wavelength band at a wavelength of 400 to 700 nm. The lower limit value thereof is more preferably 0.25 mol or more and still more preferably 0.50 mol or more. The upper limit value thereof is more preferably 17.5 mol or less and still more preferably 15 mol or less.

The light absorption filter according to the embodiment of the present invention may contain one kind of the radical generator (preferably the photoradical generator) or two or more kinds thereof.

<Resin>

The resin contained in the light absorption filter according to the embodiment of the present invention (hereinafter, also referred to as a “matrix resin”) can disperse (preferably dissolve) the above-described dye and the above-described radical generator (preferably the photoradical generator), can exhibit the action of decolorization of the dye due to the radical generator (preferably the photoradical generator) and is not particularly limited as long as it has a desired light transmittance (in the visible range of a wavelength of 400 to 800 nm, the light transmittance is preferably 80% or more).

In a case where the dye that has a main absorption wavelength band at a wavelength of 400 to 700 nm is a squarine-based coloring agent represented by General Formula (1), or a benzylidene-based coloring agent or cinnamylidene-based coloring agent represented by General Formula (V), the above-described matrix resin is preferably a low-polarity matrix resin by which this squarine-based coloring agent, or this benzylidene-based coloring agent or cinnamylidene-based coloring agent is capable of exhibiting the sharper absorption. In a case where the above-described squarine-based coloring agent, or the above-described benzylidene-based coloring agent or cinnamylidene-based coloring agent exhibits the sharper absorption, the light absorption filter according to the embodiment of the present invention minimizes a decrease in the transmittance of the display light and can prevent the reflection of external light. Here, the low polarity means that an fd value defined by Relational Expression I is preferably 0.50 or more.

fd=δd/(δd+δp+δh) Relational Expression I:

In Relational Expression I, δd, δp, and δh respectively indicate a term corresponding to a London dispersion force, a term corresponding to a dipole-dipole force, and a term corresponding to a hydrogen bonding force with respect to a solubility parameter δt calculated according to a Hoy method. A specific calculation method of fd will be described later. That is, fd indicates a ratio of δd to the sum of δd, δp, and δh.

In a case where the fd value is set to 0.50 or more, a sharper absorption waveform can be easily obtained.

Further, in a case where the light absorption filter according to the embodiment of the present invention contains two or more matrix resins, the fd value is calculated as follows.

fd=Σ(wᵢ·fdᵢ)

Here, wᵢ represents the mass fraction of the i-th matrix resin, and fdᵢ represents the fd value of the i-th matrix resin.

—Term δd Corresponding to London Dispersion Force—

The term δd corresponding to the London dispersion force refers to δd obtained for the Amorphous Polymers described in the column “2) Method of Hoy (1985, 1989)” on pages 214 to 220 of the document “Properties of Polymers 3′, ELSEVIER, (1990)”, and is calculated according to the description in the column of the document.

—Term δp Corresponding to Dipole-Dipole Force—

The term δp corresponding to the dipole-dipole force refers to δp obtained for Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

—Term δh Corresponding to Hydrogen Bonding Force—

The term δh corresponding to the hydrogen bonding force refers to δh obtained for the Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

In addition, in a case where the matrix resin is a resin exhibiting a certain hydrophobicity, a moisture content of the light absorption filter according to the embodiment of the present invention can be set to a low moisture content, for example, 0.5% or lower, and the light resistance of the light absorption filter according to the embodiment of the present invention is improved, which is preferable.

The resin may contain any conventional component in addition to a polymer. However, the fd of the matrix resin is a calculated value for the polymer constituting the matrix resin.

Preferred examples of the matrix resin include a polystyrene resin and a cyclic polyolefin resin, and the polystyrene resin is more preferable. In general, the fd value of the polystyrene resin is 0.45 to 0.60, and the fd value of the cyclic polyolefin resin is 0.45 to 0.70. As described above, it is preferable to use the resin having an fd value of 0.50 or more.

Further, for example, in addition to these preferable resins, it is also preferable to use a resin component, that imparts functionality to the light absorption filter according to the embodiment of the present invention, such as an extensible resin component and a peelability control resin component, which will be described later. That is, in the present invention, the matrix resin is used in the meaning of including the extensible resin component and the peelability control resin component in addition to the above-described resins.

It is preferable that the matrix resin includes a polystyrene resin from the viewpoint of sharpening the absorption waveform of the coloring agent.

(Polystyrene Resin)

The polystyrene contained in the polystyrene resin means a polymer containing a styrene component. The polystyrene preferably contains 50% by mass or more of the styrene component. The light absorption filter according to the embodiment of the present invention may contain one type of polystyrene or two or more types of polystyrene. Here, the styrene component is a structural unit derived from a monomer having a styrene skeleton in the structure thereof.

The polystyrene more preferably contains 70% by mass or more of the styrene component, and still more preferably 85% by mass or more of the styrene component, in terms of controlling the photo-elastic coefficient and the hygroscopicity to values within a preferred range as the light absorption filter. It is also preferable that the polystyrene is composed of only a styrene component.

Among polystyrenes, examples of the polystyrene composed of only the styrene component include a homopolymer of a styrene compound and a copolymer of two or more kinds of styrene compounds. Here, the styrene compound is a compound having a styrene skeleton in the structure thereof, and is meant to include, in addition to styrene, a compound in which a substituent is introduced within a range where an ethylenically unsaturated bond of styrene can act as a reactive (polymerizable) group.

Specific examples of the styrene compound include the following styrenes: alkylstyrene such as α-methylstyrene, o-methylstyrene, m-methylstyrene, p-methylstyrene, 3,5-dimethylstyrene, 2,4-dimethylstyrene, o-ethylstyrene, p-ethylstyrene, and tert-butyl styrene; and substituted styrene having a hydroxyl group, an alkoxy group, a carboxy group, or a halogen atom introduced into the benzene nucleus of styrene, such as hydroxystyrene, tert-butoxy styrene, vinyl benzoic acid, o-chlorostyrene, and p-chlorostyrene. Among these, the polystyrene is preferably a homopolymer of styrene (that is, polystyrene) from the viewpoints of availability and material cost.

The constitutional component other than the styrene component that may be contained in the polystyrene is not particularly limited. That is, the polystyrene may be a styrene-diene copolymer, a styrene-polymerizable unsaturated carboxylic acid ester copolymer, or the like. In addition, it is also possible to use a mixture of polystyrene and synthetic rubber (for example, polybutadiene and polyisoprene). Further, high impact polystyrene (HIPS) obtained by subjecting styrene to graft polymerization with synthetic rubber is also preferable. Further, a polystyrene obtained by dispersing a rubber-like elastic body in a continuous phase of a polymer including a styrene component (for example, a copolymer of a styrene component and a (meth)acrylate ester component), and subjecting the copolymer to graft polymerization with a rubber-like elastic body (referred to as graft type high impact polystyrene “graft HIPS”) is also preferable. Furthermore, a so-called styrene-based elastomer can also be suitably used.

In addition, the polystyrene may be hydrogenated (may be a hydrogenated polystyrene). The hydrogenated polystyrene is not particularly limited, and is preferably a hydrogenated styrene-diene-based copolymer such as a hydrogenated styrene-butadiene-styrene block copolymer (SEBS) obtained by hydrogenating a styrene-butadiene-styrene block copolymer (SBS) or hydrogenated styrene-isoprene-styrene block copolymer (SEPS) obtained by hydrogenating a styrene-isoprene-styrene block copolymer (SIS). Only one of these hydrogenated polystyrenes may be used, or two or more thereof may be used.

In addition, the polystyrene may be modified polystyrene. The modified polystyrene is not particularly limited, and examples thereof include polystyrene having a reactive group such as a polar group introduced therein. Specific examples thereof preferably include acid-modified polystyrene such as maleic acid-modified and epoxy-modified polystyrene.

As the polystyrene, a plurality of kinds of polystyrene resins having different compositions, molecular weights, and the like may be used in combination.

The polystyrene-based resin can be obtained using a method such as anion, bulk, suspension, emulsification, or a solution polymerization method. In addition, in the polystyrene, at least a part of the unsaturated double bond of the benzene ring of the conjugated diene and the styrene monomer may be hydrogenated. The hydrogenation rate can be measured by a nuclear magnetic resonance apparatus (NMR).

As the polystyrene resin, a commercially available product may be used, and examples thereof include “CLEAREN 530L” and “CLEAREN 730L” manufactured by Denki Kagaku Kogyo Kabushiki Kaisha, “TUFPRENE 1265” and “ASAPRENE T411” manufactured by Asahi Kasei Corporation, “KRATON D1102A”, “KRATON D1116A” manufactured by Kraton Polymers Japan Ltd., “STYROLUX S” and “STYROLUX T” by INEOS Styrolution, “ASAFLEX 840” and “ASAFLEX 860” manufactured by Asahi Kasei Chemicals Corporation (all are SBS), “679”, “HF77”, and “SGP-10” manufactured by PS Japan Corporation, “DIC STYRENE XC-515” and “DIC STYRENE XC-535” manufactured by DIC Corporation (all are GPPS), “475D”, “H0103”, and “HT478” manufactured by PS Japan Corporation, and “DIC STYRENE GH-8300-5” manufactured by DIC Corporation (all are HIPS). Examples of the hydrogenated polystyrene-based resin include “TUFTEC H series” manufactured by Asahi Kasei Corporation (formerly Asahi Kasei Chemicals Corporation), and “KRATON G series” manufactured by Shell Japan Ltd. (all are SEBS), “DYNARON” manufactured by JSR Corporation (hydrogenated styrene-butadiene random copolymer), and “SEPTON” manufactured by Kuraray Co., Ltd. (SEPS). Examples of the modified polystyrene-based resin include “TUFTEC M series” manufactured by Asahi Kasei Corporation (formerly Asahi Kasei Chemicals Corporation), “EPOFRIEND” manufactured by Daicel Corporation, “Polar Group Modified DYNARON” manufactured by JSR Corporation, and “RESEDA” manufactured by ToaGosei Co., Ltd.

The light absorption filter according to the embodiment of the present invention preferably contains a polyphenylene ether resin in addition to the polystyrene resin. By containing the polystyrene resin and the polyphenylene ether resin together, the toughness of the light absorption filter can be improved, and the occurrence of defects such as cracks can be suppressed even in a harsh environment such as high temperature and high humidity.

As the polyphenylene ether resin, ZYLON S201A, ZYLON 202A, ZYLON S203A, and the like, manufactured by Asahi Kasei Corporation, can be preferably used. In addition, a resin in which the polystyrene resin and the polyphenylene ether resin are mixed in advance may also be used. As the mixed resin of the polystyrene resin and the polyphenylene ether resin, for example, ZYLON 1002H, ZYLON 1000H, ZYLON 600H, ZYLON 500H, ZYLON 400H, ZYLON 300H, ZYLON 200H, and the like manufactured by Asahi Kasei Corporation can be preferably used.

In a case where the polystyrene resin and the polyphenylene ether resin are contained in the light absorption filter according to the embodiment of the present invention, the mass ratio of both resins is preferably 99/1 to 50/50, more preferably 98/2 to 60/40, and still more preferably 95/5 to 70/30, for the polystyrene resin/polyphenylene ether resin. In a case where the formulation ratio of the polyphenylene ether resin is set in the above-described preferred range, the light absorption filter according to the embodiment of the present invention can have sufficient toughness, and the solvent can be properly volatilized in a case where a film is formed with a solution.

(Cyclic Polyolefin Resin)

The cyclic olefin compound that forms the cyclic polyolefin contained in the cyclic polyolefin resin is not particularly limited as long as the compound has a ring structure including a carbon-carbon double bond, and examples thereof include a norbornene compound and a monocyclic olefin compound, a cyclic conjugated diene compound, and a vinyl alicyclic hydrocarbon compound, which are not the norbornene compound.

Examples of the cyclic polyolefin include (1) polymers including a structural unit derived from a norbornene compound; (2) polymers including a structural unit derived from a monocyclic olefin compound other than the norbornene compound; (3) polymers including a structural unit derived from a cyclic conjugated diene compound; (4) polymers including a structural unit derived from a vinyl alicyclic hydrocarbon compound; and hydrides of polymers including a structural unit derived from each of the compounds (1) to (4).

In the present invention, ring-opening polymers of the respective compounds are included in the polymers including a structural unit derived from a norbornene compound and the polymers including a structural unit derived from a monocyclic olefin compound.

The cyclic polyolefin is not particularly limited; however, it is preferably a polymer having a structural unit derived from a norbornene compound, which is represented by General Formula (A-II) or (A-III). The polymer having the structural unit represented by General Formula (A-II) is an addition polymer of a norbornene compound, and the polymer having the structural unit represented by General Formula (A-III) is a ring-opening polymer of a norbornene compound.

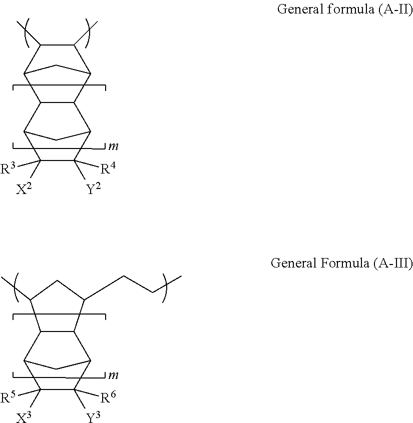

In General Formulae (A-II) and (A-III), m is an integer of 0 to 4, and preferably 0 or 1.

In General Formulae (A-II) and (A-Ill), R³ to R⁶ each independently represent a hydrogen atom or a hydrocarbon group having 1 to 10 carbon atoms.

The hydrocarbon group in General Formulae (A-I) to (A-III) is not particularly limited as long as the hydrocarbon group is a group consisting of a carbon atom and a hydrogen atom, and examples thereof include an alkyl group, an alkenyl group, an alkynyl group, and an aryl group (an aromatic hydrocarbon group). Among these, an alkyl group or an aryl group is preferable.

In General Formula (A-II) or (A-III), X² and X³, and Y² and Y³ each independently represent a hydrogen atom, a hydrocarbon group having 1 to 10 carbon atoms, a halogen atom, a hydrocarbon group having 1 to 10 carbon atoms, which is substituted with a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ or —(CH₂)ₙW, or (—CO)₂O or (—CO)₂NR¹⁵ which is formed by X² and Y² or X³ and Y³ bonded to each other.

Here, R¹¹ to R¹⁵ each independently represent a hydrogen atom or a hydrocarbon group having 1 to 20 carbon atoms. Z represents a hydrocarbon group or a hydrocarbon group substituted with halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3). n is an integer of 0 to 10, preferably 0 to 8, and more preferably 0 to 6.

In General Formulae (A-II) and (A-III), R³ to R⁶ are each preferably a hydrogen atom or —CH₃, and, from the viewpoint of moisture permeability, more preferably a hydrogen atom.

X² and X³ are each preferably a hydrogen atom, —CH₃, or —C₂H₅ and, from the viewpoint of moisture permeability, more preferably a hydrogen atom.

Y² and Y³ are each preferably a hydrogen atom, a halogen atom (particularly a chlorine atom), or —(CH₂)ₙCOOR¹¹ (particularly —COOCH₃) and, from the viewpoint of moisture permeability, more preferably a hydrogen atom.

Other groups are appropriately selected.

The polymer having the structural unit represented by General Formula (A-II) or (A-III) may further include at least one or more structural units represented by General Formula (A-I).

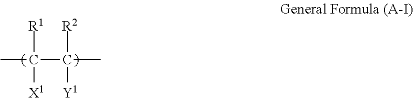

In General Formula (A-I), R¹ and R² each independently represent a hydrogen atom or a hydrocarbon group having 1 to 10 carbon atoms, and X¹ and Y¹ each independently represent a hydrogen atom, a hydrocarbon group having 1 to 10 carbon atoms, a halogen atom, a hydrocarbon group having 1 to 10 carbon atoms, which is substituted with a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ, —(CH₂)ₙW, or (—CO)₂O or (—CO)₂NR¹⁵ which is formed by X¹ and Y¹ bonded to each other.

Here, R¹¹ to R¹⁵ each independently represent a hydrogen atom or a hydrocarbon group having 1 to 20 carbon atoms, Z represents a hydrocarbon group or a hydrocarbon group substituted with halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3). n is an integer of 0 to 10.

From the viewpoint of adhesiveness to a polarizer, the content of the structural unit derived from a norbornene compound in the cyclic polyolefin having the structural unit represented by General Formula (A-II) or (A-Ill) is preferably 90% by mass or less, more preferably 30% to 85% by mass, still more preferably 50% to 79% by mass, and most preferably 600% to 75% by mass with respect to the total mass of the cyclic polyolefin. Here, the proportion of the structural unit derived from a norbornene compound represents the average value in the cyclic polyolefin.

The addition (co)polymer of a norbornene compound is described in JP1998-7732A (JP-H10-7732A), JP2002-504184A, US2004/229157A1A, and WO2004/070463A.

The polymer of a norbornene compound is obtained by the addition polymerization of norbornene compounds (for example, polycyclic unsaturated compounds of norbornene).

In addition, as the polymer of a norbornene compound, copolymers obtained by the addition copolymerization of, as necessary, a norbornene compound, olefin such as ethylene, propylene, and butene, conjugated diene such as butadiene and isoprene, unconjugated diene such as ethylidene norbornene, and an ethylenically unsaturated compound such as acrylonitrile, acrylic acid, methacrylic acid, maleic acid anhydride, acrylic acid ester, methacrylic acid ester, maleimide, vinyl acetate, and vinyl chloride are exemplified. Among these, a copolymer of a norbornene compound and ethylene is preferable.

Examples of the addition (co)polymer of a norbornene compound include APL8008T (Tg: 70° C.), APL6011T (Tg: 105° C.), APL6013T (Tg: 125° C.), APL6015T (Tg: 145° C.), APL6509T (Tg: 80° C.), and APL6011T (Tg: 105° C.) which are launched by Mitsui Chemicals, Inc. under a product name of APEL and have mutually different glass transition temperatures (Tg). In addition, pellets such as TOPAS8007, TOPAS6013, and TOPAS6015 are commercially available from Polyplastics Co., Ltd. Further, Appear 3000 is commercially available from Film Ferrania S. R. L.

As the polymer of a norbornene compound, a commercially available product can be used. For example, it is commercially available from JSR Corporation under a product name of Arton G or Arton F, and it is also commercially available from Zeon Corporation under a product name of Zeonor ZF14, ZF16, Zeonex 250, or Zeonex 280.

The hydride of a polymer of a norbornene compound can be synthesized by the addition polymerization or the metathesis ring-opening polymerization of a norbornene compound or the like and then the addition of hydrogen. The synthesis method is described in, for example, JP1989-240517A (JP-H1-240517A), JP1995-196736A (JP-H7-196736A), JP1985-26024A (JP-S60-26024A), JP1987-19801A (JP-S62-19801A), JP2003-159767A, JP2004-309979A.

The molecular weight of the cyclic polyolefin is appropriately selected depending on the intended use, and it is a mass average molecular weight measured in terms of polyisoprene or polystyrene by the gel permeation chromatography of a cyclohexane solution (a toluene solution in a case where the polymer is not dissolved). In general, it is preferable that the molecular weight is in a range of 5,000 to 500.000, preferably 8,000 to 200,000, and more preferably 10,000 to 100,000. A polymer having a molecular weight in the above-described range is capable of satisfying both the mechanical strength of a molded body and the molding workability of compacts at a high level in a well-balanced manner.

In the light absorption filter according to the embodiment of the present invention, the content of the matrix resin is preferably 5% by mass or more, more preferably 20% by mass or more, still more preferably 50% by mass or more, particularly preferably 70% by mass or more, especially preferably 80% by mass, and most preferably 90% by mass or more. The content of the matrix resin in the light absorption filter according to the embodiment of the present invention is usually 99.90% by mass or less, and preferably 99.85% by mass or less.

The cyclic polyolefin contained in the light absorption filter according to the embodiment of the present invention may be two or more types, and polymers having different at least one of a compositional ratio or a molecular weight may be used in combination. In this case, the total content of the respective polymers is in the above range.

(Extensible Resin Component)

The light absorption filter according to the embodiment of the present invention can appropriately select and contain a component exhibiting extensibility (also referred to as an extensible resin component) as a resin component. Specific examples thereof include an acrylonitrile-butadiene-styrene resin (an ABS resin), a styrene-butadiene resin (an SB resin), an isoprene resin, a butadiene resin, a polyether-urethane resin, and a silicone resin. Further, these resins may be further hydrogenated as appropriate.

As the extensible resin component, it is preferable to use an ABS resin or an SB resin, and it is more preferable to use an SB resin.

As the SB resin, for example, a commercially available one can be used. Examples of such commercially available products include TR2000, TR2003, and TR2250 (all, product name, manufactured by JSR Corporation); CLEAREN 210M, 220M, and 730V (all, product name, manufactured by Denka Corporation); Asaflex 800S, 805, 810, 825, 830, and 840 (all, product name, manufactured by Asahi Kasei Corporation); and EPOREX SB2400, SB2610, and SB2710 (all, product name, Sumitomo Chemical Co., Ltd.).

The light absorption filter according to the embodiment of the present invention preferably contains an extensible resin component in the matrix resin in an amount of 15% to 95% by mass, more preferably 20% to 50% by mass, and still more preferably 25% to 45% by mass.

The extensible resin component is preferably an extensible resin component having a breaking elongation of 10% or more and more preferably an extensible resin component having a breaking elongation of 20% or more, in a case where a sample having a form with a thickness of 30 μm and a width of 10 mm is produced by using the extensible resin component alone and the breaking elongation at 25° C. is measured in accordance with JIS 7127.

(Peelability Control Resin Component)

The light absorption filter according to the embodiment of the present invention can contain, as a resin component, a component that controls the peelability (a peelability control resin component) in a case of being produced by a method including a step of peeling the light absorption filter according to the embodiment of the present invention from a release film, among the methods of manufacturing the light absorption filter according to the embodiment of the present invention described later, which is preferable. By controlling the peelability of the light absorption filter according to the embodiment of the present invention from the release film, it is possible to prevent a peeling mark from being left on the light absorption filter according to the embodiment of the present invention after peeling, and it is possible to cope with various processing speeds in the peeling step. As a result, a preferable effect can be obtained for improving the quality and productivity of the light absorption filter according to the embodiment of the present invention.

The peelability control resin component is not particularly limited and can be appropriately selected depending on the kind of the release film. In a case where a polyester-based polymer film is used as the release film as described later, for example, a polyester resin (also referred to as a polyester-based additive) is suitable as the peelability control resin component. In a case where a cellulose acylate-based film is used as the release film, for example, a hydrogenated polystyrene-based resin (also referred to as a hydrogenated polystyrene-based additive) is suitable as the peelability control resin component.

The polyester-based additive can be obtained by a conventional method such as a dehydration condensation reaction of a polyhydric basic acid and a polyhydric alcohol and an addition of a dibasic anhydride to a polyhydric alcohol and a dehydration condensation reaction, and a polycondensation ester formed from a dibasic acid and a diol is preferable.

The mass average molecular weight (Mw) of the polyester-based additive is preferably 500 to 50,000, more preferably 750 to 40,000, and still more preferably 2,000 to 30,000. In a case where the mass average molecular weight of the polyester-based additive is equal to or larger than the above-described preferred lower limit value, it is preferable from the viewpoint of brittleness and moisture-heat resistance, and in a case where the mass average molecular weight thereof is equal to or smaller than the above-described preferred upper limit value, it is preferable from the viewpoint of compatibility with the resin.

The mass average molecular weight of the polyester-based additive is a value of the mass average molecular weight (Mw) in terms of standard polystyrene measured under the following conditions. The molecular weight distribution (Mw/Mn) can also be measured under the same conditions. Mn is a number average molecular weight in terms of standard polystyrene.

GPC: Gel permeation chromatograph device (HLC-8220GPC manufactured by Tosoh Corporation,

column: Guard column HXL-H manufactured by Tosoh Corporation, TSK gel G7000HXL, TSK gel GMHXL 2 pieces, TSK gel G2000HXL are connected in sequence,

eluent: tetrahydrofuran,

flow velocity: 1 mL/min,

sample concentration: 0.7% to 0.8% by mass,

sample injection volume: 70 μL,

measurement temperature: 40° C.,

detector: differential refractometer (RI) meter (40° C.), and

standard substance: TSK standard polystyrene manufactured by Tosoh Corporation)

Preferred examples of the dibasic acid component constituting the polyester-based additive include dicarboxylic acid.

Examples of the dicarboxylic acid include an aliphatic dicarboxylic acid and an aromatic dicarboxylic acid. An aromatic dicarboxylic acid or a mixture of an aromatic dicarboxylic acid and an aliphatic dicarboxylic acid can be preferably used.

Among the aromatic dicarboxylic acids, an aromatic dicarboxylic acid having 8 to 20 carbon atoms is preferable, and an aromatic dicarboxylic acid having 8 to 14 carbon atoms is more preferable. Specifically, preferred examples thereof include at least one of phthalic acid, isophthalic acid, or terephthalic acid.

Among the aliphatic dicarboxylic acids, an aliphatic dicarboxylic acid having 3 to 8 carbon atoms is preferable, and an aliphatic dicarboxylic acid having 4 to 6 carbon atoms is more preferable. Specifically, preferred examples thereof include at least one of succinic acid, maleic acid, adipic acid, or glutaric acid, and at least one of succinic acid or adipic acid is more preferable.

Examples of the diol component constituting the polyester-based additive include an aliphatic diol and an aromatic diol, and aliphatic diol is preferable.

Among the aliphatic diols, an aliphatic diol having 2 to 4 carbon atoms is preferable, and an aliphatic diol having 2 to 3 carbon atoms is more preferable.

Examples of the aliphatic diol include ethylene glycol, diethylene glycol, 1,2-propylene glycol, 1,3-propylene glycol, 1,3-butylene glycol, and 1,4-butylene glycol. These aliphatic diols can be used alone or two or more kinds can be used in combination.

The polyester-based additive is particularly preferably a compound obtained by fusing at least one of phthalic acid, isophthalic acid, or terephthalic acid with an aliphatic diol.

The terminal of the polyester-based additive may be sealed by reacting with a monocarboxylic acid. The monocarboxylic acid that is used for sealing is preferably an aliphatic monocarboxylic acid. Preferred examples thereof include acetic acid, propionic acid, butanoic acid, benzoic acid, and a derivative thereof, where acetic acid or propionic acid is more preferable and acetic acid is still more preferable.

Examples of the commercially available polyester-based additive include ester-based resin polyesters manufactured by Nippon Synthetic Chemical Industry Co., Ltd. (for example, LP050, TP290, LP035, LP033, TP217, and TP220) and ester-based resins Byron manufactured by Toyobo Co., Ltd. (for example, Byron 245, Byron GK890, Byron 103, Byron 200, and Byron 550, GK880).

The mass average molecular weight (Mw) of the hydrogenated polystyrene-based additive is preferably 500 to 50,000, more preferably 750 to 40,000, and still more preferably 2,000 to 30,000.

In a case where the mass average molecular weight of the hydrogenated polystyrene-based additive is equal to or larger than the above-described preferred lower limit value, it is preferable from the viewpoint of brittleness and moisture-heat resistance, and in a case where the mass average molecular weight thereof is equal to or smaller than the above-described preferred upper limit value, it is preferable from the viewpoint of compatibility with the resin.

The mass average molecular weight of the hydrogenated polystyrene-based additive is a value of the mass average molecular weight (Mw) in terms of standard polystyrene measured under the following conditions. The molecular weight distribution (Mw/Mn) can also be measured under the same conditions. Mn is a number average molecular weight in terms of standard polystyrene.

Examples of the commercially available hydrogenated polystyrene-based additive include “TUFTEC H series” manufactured by Asahi Kasei Corporation (formerly Asahi Kasei Chemicals Corporation), and “KRATON G series” manufactured by Shell Japan Ltd. (all are SEBS), “DYNARON” manufactured by JSR Corporation (hydrogenated styrene-butadiene random copolymer), and “SEPTON” manufactured by Kuraray Co., Ltd. (SEPS).

The content of the peelability control resin component in the light absorption filter according to the embodiment of the present invention is preferably 0.05% by mass or more, and more preferably 0.1% by mass or more in the matrix resin. In addition, the upper limit value thereof is preferably 25% by mass or less, more preferably 20% by mass or less, and still more preferably 15% by mass or less. From the viewpoint of obtaining proper adhesiveness, the above-described preferred range is preferable.

<Other Components>

In addition to the above-described dye, the above-described compound that generates a radical upon ultraviolet irradiation, and the above-described matrix resin, the absorption filter according to the embodiment of the present invention may contain a matting agent, a leveling agent (a surfactant), and the like.

(Matting Agent)

In order to impart sliding properties and prevent blocking, fine particles may be added on the surface of the light absorption filter according to the embodiment of the present invention, as long as the effects of the present invention are not impaired. As the fine particles, silica (silicon dioxide, SiO₂) of which the surface is coated with a hydrophobic group and which has an aspect of secondary particles is preferably used. As the fine particles, in addition to or instead of silica, fine particles of titanium dioxide, aluminum oxide, zirconium oxide, calcium carbonate, talc, clay, calcined kaolin, calcined calcium silicate, hydrated calcium silicate, aluminum silicate, magnesium silicate, and calcium phosphate may be used. Examples of the commercially available product of the fine particles include the R972 or NX90S (product name, both manufactured by Nippon Aerosil Co., Ltd.).

The fine particles function as a so-called matting agent, and the addition of the fine particles forms minute unevenness on the surface of the light absorption filter according to the embodiment of the present invention. Due to the unevenness, even in a case where the light absorption filter according to the embodiment of the present invention overlap each other or the light absorption filter according to the embodiment of the present invention and other films overlap each other, the films do not stick to each other and sliding properties are secured.

In a case where the light absorption filter according to the embodiment of the present invention contains a matting agent as fine particles, and in the fine irregularities due to the protrusions in which fine particles protrude from the filter surface, there are 10⁴/mm² or more of protrusions having a height of 30 nm or more, the effect of improving sliding properties and blocking properties is particularly large.

It is preferable to apply the matting agent fine particles particularly onto the surface layer in order to improve the blocking properties and the sliding properties. Examples of the method of applying fine particles onto the surface layer include methods such as multilayer casting and coating.

The content of the matting agent in the light absorption filter according to the embodiment of the present invention is appropriately adjusted depending on the intended purpose.

However, in a case where a gas barrier layer described later is provided in the light absorption filter according to the embodiment of the present invention, the above-described matting agent fine particles are preferably applied onto the surface of the light absorption filter in contact with the gas barrier layer, as long as the effect of the present invention is not impaired.

(Leveling Agent)

A leveling agent (surfactant) can be appropriately mixed with the light absorption filter according to the embodiment of the present invention. As the leveling agent, a commonly used compound can be used, and a fluorine-containing surfactant is particularly preferable. Specific examples thereof include the compounds described in paragraphs [0028] to [0056] of JP2001-330725A. Further, as the commercially available product. MEGAFACE F (product name) series manufactured by DIC Corporation can also be used.

The content of the leveling agent in the light absorption filter according to the embodiment of the present invention is appropriately adjusted depending on the intended purpose.

The light absorption filter according to the embodiment of the present invention may contain, in addition to the above components, a low-molecular plasticizer, an oligomer-based plasticizer, a retardation modifier, a deterioration preventing agent, a peeling accelerating agent, an infrared absorbing agent, an antioxidant, a filler, a compatibilizer.

Further, the light absorption filter according to the embodiment of the present invention may contain the reaction accelerating agent or the reaction retarder described in paragraphs [0020] and [0021] of JP1997-286979A (JP-H9-286979A).

<Method of Manufacturing Light Absorption Filter>

The light absorption filter can be produced by a solution film forming method, a melt extrusion method, or a method of forming a coating layer on a base material film (release film) (coating method) according to any method, according to a conventional method, and stretching can also be appropriately combined. The light absorption filter according to the embodiment of the present invention is preferably produced by a coating method.

(Solution Film Forming Method)

In the solution film forming method, a solution in which a material constituting the light absorption filter according to the embodiment of the present invention is dissolved in an organic solvent or water is prepared, a concentration step, a filtration step, and the like are appropriately carried out, and then the solution is uniformly cast on a support. Next, the raw dry film is peeled off from the support, both ends of a web are appropriately held by clips or the like, and the solvent is dried in the drying zone. In addition, stretching can be carried out separately while or after the film is dried.

(Melt Extrusion Method)

In the melt extrusion method, a material constituting the light absorption filter according to the embodiment of the present invention (hereinafter, also simply referred to as a “material of the light absorption filter”) is melted by heat, a filtration step or the like is appropriately carried out, and then the material is uniformly casted on a support. Next, a film solidified by cooling or the like can be peeled off and appropriately stretched. In a case where the main material of the light absorption filter according to the embodiment of the present invention is a thermoplastic polymer resin, a thermoplastic polymer resin can be selected as the main material of the release film, and the polymer resin in a molten state can be formed into a film by a known co-extrusion method. In this case, by adjusting the kind of polymer of the light absorption filter according to the embodiment of the present invention and the release film and the additives mixed in each layer, or by adjusting the stretching temperature, the stretching speed, the stretching ratio, and the like of the co-extruded film, the adhesive force between the light absorption filter according to the embodiment of the present invention and the release film can be controlled.

Examples of the co-extrusion method include a co-extrusion T-die method, a co-extrusion inflation method, and a co-extrusion lamination method. Among these, the co-extrusion T-die method is preferable. The co-extrusion T-die method includes a feed block method and a multi-manifold method. Among these, the multi-manifold method is particularly preferable from the viewpoint that a variation in thickness can be reduced.

In a case where the co-extrusion T-die method is adopted, the melting temperature of the resin in an extruder having a T-die is preferably a temperature 80° C. or more higher, and more preferably a temperature 100° C. or more higher than the glass transition temperature (Tg) of each resin, and is preferably a temperature equal to or lower than a temperature 180° C. higher than the glass transition temperature, and more preferably a temperature equal to or lower than a temperature 150° C. higher than the glass transition temperature. In a case where the melting temperature of the resin in the extruder is set to the lower limit value or greater in the above-described preferred range, the fluidity of the resin can be sufficiently enhanced, and in a case where the melting temperature is set to the upper limit value or less of the above-described preferred range, the resin can be prevented from being deteriorated.

In general, the sheet-shaped molten resin extruded from the opening portion of the die is brought into close contact with the cooling drum. The method of bringing the molten resin into close contact with the cooling drum is not particularly limited, and examples thereof include an air knife method, a vacuum box method, and an electrostatic contact method.

The number of cooling drums is not particularly limited; however, it is usually 2 or more. In addition, the method of disposing the cooling drum is not particularly limited, and examples of the disposition form include a linear form, a Z form, and an L form. Further, the method of passing the molten resin extruded from the opening portion of the die through the cooling drum is not particularly limited.

The degree of close contact of the extruded sheet-shaped resin with the cooling drum changes depending on the temperature of the cooling drum. In a case where the temperature of the cooling drum is raised, the intimate attachment is improved, but in a case where the temperature is raised too much, the sheet-shaped resin may not be peeled off from the cooling drum and may be wound around the drum. Therefore, the temperature of the cooling drum is preferably (Tg+30°) C or lower, and still more preferably in a range of (Tg−5°) C to (Tg−45°) C in a case where Tg is the glass transition temperature of the resin of the layer that is brought into contact with the drum in the resin extruded from the die. In a case where the cooling drum temperature is set within the above-described preferred range, problems such as sliding and scratches can be prevented.

Here, it is preferable to reduce the content of the residual solvent in the film before stretching. Examples of the method of reducing the content include methods of (1) reducing the amount of the residual solvent of the resin as the raw material; and (2) predrying the resin before forming the film before stretching. Predrying is carried out, for example, by making the resin into a form of a pellet or the like and using a hot air dryer or the like. The drying temperature is preferably 100° C. or higher, and the drying time is preferably 2 hours or longer. In a case of carrying out predrying, it is possible to reduce the residual solvent in the film before stretching and to prevent the extruded sheet-shaped resin from foaming.

(Coating Method)

In the coating method, a solution of a material of the light absorption filter is applied to a release film to form a coating layer. A release agent or the like may be appropriately applied to the surface of the release film in advance in order to control the adhesiveness to the coating layer. The coating layer can be used by peeling off the release film after being laminated with another member while interposing an adhesive layer in a later step. Any adhesive can be appropriately used as the adhesive constituting the adhesive layer. The release film can be appropriately stretched together with the release film coated with the solution of the material of the light absorption filter or with the coating layer laminated.

The solvent that is used for the solution of the material of the light absorption filter can be appropriately selected from the viewpoints that the material of the light absorption filter can be dissolved or dispersed, a uniform surface shape can be easily achieved during the coating step and drying step, liquid storability can be secured, and a proper saturated vapor pressure is provided.

—Addition of Dye (Coloring Agent) and Radical Generator (Preferably Photoradical Generator)—

The timing of adding the dye and the radical generator (preferably the photoradical generator) to the material of the light absorption filter is not particularly limited as long as they are added at the time of film formation. For example, the dye may be added at the time of synthesizing the matrix resin or may be mixed with the material of the light absorption filter at the time of preparing the coating liquid for the material of the light absorption filter.

—Release Film—

The release film that is used for forming the light absorption filter according to the embodiment of the present invention by a coating method or the like preferably has a film thickness of 5 to 100 μm, more preferably 10 to 75 μm, and still more preferably 15 to 55 μm. In a case where the film thickness is equal to or larger than the above-described preferred lower limit value, sufficient mechanical strength can be easily secured, and failures such as curling, wrinkling, and buckling are less likely to occur. In addition, in a case where the film thickness is equal to or smaller than the above-described preferred upper limit value, in the storage of a multi-layer film of the release film and the light absorption filter according to the embodiment of the present invention, for example, in the form of a long roll, the surface pressure applied to the multi-layer film is easily adjusted to be in an appropriate range, and adhesion defect is less likely to occur.

The surface energy of the release film is not particularly limited, and by adjusting the relationship between the surface energy of the material of the light absorption filter according to the embodiment of the present invention or the coating solution and the surface energy of the surface of the release film on which the light absorption filter according to the embodiment of the present invention is to be formed, the adhesive force between the light absorption filter according to the embodiment of the present invention and the release film can be adjusted. In a case where the surface energy difference is reduced, the adhesive force tends to increase, and in a case where the surface energy difference is increased, the adhesive force tends to decrease, and thus the surface energy can be set appropriately.

The surface energy of the release film can be calculated from the contact angle value between water and methylene iodide using the Owen's method. For the measurement of the contact angle, for example, DM901 (contact angle meter, manufactured by Kyowa Interface Science Co., Ltd.) can be used.

The surface energy of the surface of the release film on which the light absorption filter according to the embodiment of the present invention is to be formed is preferably 41.0 to 48.0 mN/m and more preferably 42.0 to 48.0 mN/m. In a case where the surface energy is equal to or larger than the above-described preferred lower limit value, the evenness of the thickness of the light absorption filter according to the embodiment of the present invention is increased. In a case where the surface energy is equal to or smaller than the above-described preferred upper limit value, it is easy to control the peeling force of the light absorption filter according to the embodiment of the present invention from the release film within an appropriate range.

The surface unevenness of the release film is not particularly limited, and depending on the relationship between the surface energy of the light absorption filter according to the embodiment of the present invention surface, the hardness, and the surface unevenness, and the surface energy and hardness of the surface of the release film opposite to the side on which the light absorption filter according to the embodiment of the present invention is formed, for example, in order to prevent adhesion defect in a case where the multi-layer film of the release film and the light absorption filter according to the embodiment of the present invention is stored in the form of a long roll, the surface unevenness of the release film can be adjusted. In a case where the surface unevenness is increased, adhesion defect tends to be suppressed, and in a case where the surface unevenness is reduced, the surface unevenness of the light absorption filter according to the embodiment of the present invention tends to be decreased and the haze of the light absorption filter according to the embodiment of the present invention tends to be small. Thus, the surface unevenness can be set appropriately.

For such a release film, any material and film can be appropriately used. Specific examples of the material include a polyester-based polymer (including polyethylene terephthalate-based film), an olefin-based polymer, a cycloolefin-based polymer, a (meth)acrylic polymer, a cellulose-based polymer, and a polyamide-based polymer. In addition, a surface treatment can be appropriately carried out for the intended purpose of adjusting the surface properties of the release film. For example, a corona treatment, a room temperature plasma treatment, or a saponification treatment can be carried out to decrease the surface energy, and a silicone treatment, a fluorine treatment, an olefin treatment, or the like can be carried out to raise the surface energy.

—Peeling Force Between Light Absorption Filter According to Embodiment of Present Invention and Release Film—

In a case where the light absorption filter according to the embodiment of the present invention is formed by a coating method, the peeling force between the light absorption filter according to the embodiment of the present invention and the release film can be controlled by adjusting the material of the light absorption filter according to the embodiment of the present invention, the material of the release film, and the internal distortion of the light absorption filter. The peeling force can be measured by, for example, a test of peeling off the release film in a direction of 90°, and the peeling force in a case of being measured at a rate of 300 mm/min is preferably 0.001 to 5 N/25 mm, more preferably 0.01 to 3 N/25 mm, and still more preferably 0.05 to 1 N/25 mm. In a case where the peeling force is equal to or larger than the above-described preferred lower limit value, peeling off the release film in a step other than the peeling step can be prevented, and in a case where the peeling force is equal to or smaller than the above-described preferred upper limit value, peeling failure in the peeling step (for example, zipping and cracking of the light absorption filter according to the embodiment of the present invention) can be prevented.

<Film Thickness of Light Absorption Filter According to Embodiment of Present Invention>

The film thickness of the light absorption filter according to the embodiment of the present invention is not particularly limited, and is preferably 1 to 18 μm, more preferably 1 to 12 μm, and still more preferably 2 to 8 μm. In a case where the film thickness is equal to or smaller than the above-described preferred upper limit value, the decrease in the degree of polarization due to the fluorescence emitted by a dye (a coloring agent) can be suppressed by adding the dye to the thin film at a high concentration. In addition, the effect of the quencher is likely to be exhibited. On the other hand, in a case where the film thickness is equal to or larger than the above-described preferred lower limit value, it becomes easy to maintain the evenness of the in-plane absorbance.

In the present invention, the film thickness of 1 to 18 μm means that the thickness of the light absorption filter according to the embodiment of the present invention is within a range of 1 to 18 μm at any portion. The same applies to the film thicknesses of 1 to 12 μm and 2 to 8 μm. The film thickness can be measured with an electronic micrometer manufactured by Anritsu Corporation.

<Absorbance of Light Absorption Filter of According to Embodiment According to Embodiment of Present Invention>

In the light absorption filter according to the embodiment of the present invention, the absorbance at the maximal absorption wavelength at which the highest absorbance is exhibited at a wavelength of 400 to 700 nm (hereinafter, also simply referred to as “Ab (λₘₐₓ)”) is preferably 0.3 or more, more preferably 0.5 or more, and still more preferably 0.8 or more.

However, the absorbance of the light absorption filter according to the embodiment of the present invention can be adjusted by the kind, adding amount, or film thickness of the dye.

The light absorption filter according to the embodiment of the present invention has a quenching rate upon ultraviolet irradiation of preferably 20% or more, more preferably 25% or more, still more preferably 30% or more, and particularly preferably 35% or more. Among the above, it is preferably 40% or more. The upper limit value thereof is not particularly limited, and it is preferably 100%.

The quenching rate is calculated according to the following expression using the values of Ab (λₘₐₓ) before and after the ultraviolet irradiation test.

Quenching rate (%)=100−(Ab(λₘₐₓ) after ultraviolet irradiation/Ab(λₘₐₓ) before ultraviolet irradiation)×100

Here, in the ultraviolet irradiation test, the light absorption filter is irradiated with an ultraviolet ray at an irradiation dose of 600 mJ/cm² using an air-cooled metal halide lamp (manufactured by EYE GRAPHICS Co., Ltd.) at 160 W/cm under atmospheric pressure (101.33 kPa).

The absorbance, the ultraviolet irradiation test, and the quenching rate can be measured and calculated according to the methods described in Examples.

Further, it is preferable that the light absorption filter according to the embodiment of the present invention hardly causes absorption (secondary absorption) derived from a new coloration structure associated with the decomposition of the coloring agent.

For example, the presence or absence of the absorption derived from the new coloration structure associated with the decomposition of the coloring agent can be checked based on the ratio of the absorbance at a specific wavelength to the above Ab (As the specific wavelength, a wavelength at which the coloring agent before ultraviolet irradiation seldom exhibits absorption but new absorption due to the decomposition of the coloring agent is observed is selected.

As a specific example, as described in Examples described later, the presence or absence of the absorption derived from a new coloration structure associated with the decomposition of the coloring agent can be checked based on the ratio of the absorbance at a wavelength of 450 nm to the above Ab (λₘₐₓ) (hereinafter, also simply referred to as “Ab (450)). That is, it is meant that the smaller the value obtained by subtracting the ratio of the following (I) from the ratio of the following (II), the less frequently the absorption derived from the new coloration structure associated with the decomposition of the coloring agent occurs. This value is preferably less than 8.5%, more preferably 7.0% or less, still more preferably 5.0% or less, particularly preferably 3% or less. Among the above, it is preferably 1% or less. The lower limit value thereof is not particularly limited; however, it is practically −10% or more and preferably −6% or more from the viewpoint of making valid the evaluation regarding the presence or absence of the secondary absorption associated with the decomposition of the coloring agent.

(I) Ab (450) before ultraviolet irradiation/Ab (λₘₐₓ)×100% before ultraviolet irradiation

(II) Ab (450) after ultraviolet irradiation/Ab (λₘₐₓ) before ultraviolet irradiation×100%

Further, as described in Examples described later, the value of the absorbance at a wavelength of 650 nm (hereinafter, also simply referred to as “Ab (650)”) is used instead of the absorbance at a wavelength of 450 nm to obtain a value obtained by subtracting the ratio of the following (III) from the ratio of the following (IV), whereby the evaluation can be carried out. The preferred range of the value obtained by subtracting the ratio of the following (Ill) from the ratio of the following (IV) has the same meaning as the value obtained by subtracting the ratio of the above expression (I) from the ratio of the above expression (II).

(III) Ab (650) before ultraviolet irradiation/Ab (λₘₐₓ) before ultraviolet irradiation×100%

(IV) Ab (650) after ultraviolet irradiation/Ab (λₘₐₓ) before ultraviolet irradiation×100%

Here, the description of the ultraviolet irradiation test regarding the above quenching rate can be preferably applied to the ultraviolet irradiation test.

The checking of the presence or absence of the absorption derived from the new coloration structure associated with the decomposition of the coloring agent can be carried out by the measurement and the calculation according to the method described in Examples.

The light absorption filter according to the embodiment of the present invention can exhibit an excellent quenching property in a case where both the above-described quenching rate and the above-described value for checking the presence or absence of the absorption derived from the new coloration structure associated with the decomposition of the coloring agent satisfy a preferred range.

The light absorptive portion having a light absorption effect in the optical filter according to the embodiment of the present invention preferably satisfies the above description of Ab (λₘₐₓ) according to the light absorption filter according to the embodiment of the present invention.

The light absorption property-eliminated portion in the optical filter according to the embodiment of the present invention preferably satisfies an absorbance of 0.70 or less and more preferably satisfies 0.60 or less in a case of the absorption corresponding to the absorption by which λₘₐₓ is exhibited before ultraviolet irradiation. The lower limit value thereof is not particularly limited, and it is practically 0.001 or more.

<Moisture Content of Light Absorption Filter According to Embodiment of Present Invention>

From the viewpoint of the durability, the moisture content of the light absorption filter according to the embodiment of the present invention is preferably 0.5% by mass or less, and more preferably 0.3% by mass or less, in conditions of 25° C. and 80% relative humidity, regardless of the film thickness.

In the present specification, the moisture content of the light absorption filter according to the embodiment of the present invention can be measured by using a sample having a thick film thickness as necessary. The moisture content can be calculated according to humidity-conditioning the sample for 24 hours or longer, then measuring a moisture content (g) by the Karl Fischer method with a water measuring instrument and a sample drying apparatus “CA-03” and “VA-05” (both manufactured by Mitsubishi Chemical Corporation), and dividing the moisture content (g) by the sample mass (g, including the moisture content).

<Glass Transition Temperature (Tg) of Light Absorption Filter According to Embodiment of Present Invention>

The glass transition temperature of the light absorption filter according to the embodiment of the present invention is preferably 50° C. or higher and 140° C. or lower. It is more preferably 60° C. or higher and 130° C. or lower, still more preferably 60° C. or higher and 120° C. or lower, and particularly preferably 65° C. or higher and 120° C. or lower. Among the above, it is preferably 70° C. or higher and 120° C. or lower. In a case where the glass transition temperature is equal to or higher than the above-described preferred lower limit value, deterioration of the polarizer in a case of being used at a high temperature can be suppressed, and in a case where the glass transition temperature is equal to or lower than the above-described preferred upper limit value, it is possible to suppress that the organic solvent used in the coating liquid easily remains in the light absorption filter according to the embodiment of the present invention.

The glass transition temperature of the light absorption filter according to the embodiment of the present invention can be measured by the following method. Regarding details thereof, the description of Examples described later can be referenced.

With a differential scanning calorimetry device (X-DSC7000 (manufactured by IT Measurement Control Co., Ltd.)), 20 mg of a light absorption filter according to the embodiment of the present invention is placed in a measurement pan, and the temperature of the pan is raised from 30° C. to 120° C. in a nitrogen stream at a rate of 10° C./min, and held for 15 minutes, and then cooled to 30° C. at −20° C./min. Thereafter, the temperature is raised again from 30° C. to 250° C. at a rate of 10° C./min, and the temperature at which the baseline began to deviate from the low temperature side is defined as the glass transition temperature Tg.

The glass transition temperature of the light absorption filter according to the embodiment of the present invention can be adjusted by mixing two or more kinds of polymers having different glass transition temperatures, or by changing the adding amount of the small molecule compound.

<Treatment of Light Absorption Filter According to Embodiment of Present Invention>

The light absorption filter according to the embodiment of the present invention may be subjected to a hydrophilic treatment by any of glow discharge treatment, corona discharge treatment, or alkali saponification treatment, and a corona discharge treatment is preferably used. It is also preferable to apply the method disclosed in JP1994-94915A (JP-H6-94915A) and JP1994-118232A (JP-H6-118232A).

As necessary, the obtained film may be subjected to a heat treatment step, a superheated steam contact step, an organic solvent contact step, or the like. In addition, a surface treatment may be appropriately carried out.

Further, as the pressure sensitive adhesive layer, a layer consisting of a pressure sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description of the pressure sensitive adhesive layer in the OLED display device described later can be applied.

<<Gas Barrier Layer>>

The light absorption filter according to the embodiment of the present invention may have a gas barrier layer on at least one surface. In a case where the light absorption filter according to the embodiment of the present invention has a gas barrier layer, the light absorption filter according to the embodiment of the present invention can be made to be a light absorption filter that achieves both excellent photoquenching property and excellent light resistance and can be suitably used in the production of an optical filter described later. The material that forms the gas barrier layer is not particularly limited, and examples thereof include an organic material (preferably a crystalline resin) such as polyvinyl alcohol or polyvinylidene chloride, an organic-inorganic hybrid material such as a sol-gel material, and an inorganic material such as SiO₂, SiOₓ, or SiON, SiNₓ, or Al₂O₃. The gas barrier layer may be a single layer or a multi-layer. In the case of a multi-layer, examples thereof include configurations such as an inorganic dielectric multi-layer film and a multi-layer film obtained by alternately laminating organic materials and inorganic materials.

In a case where the light absorption filter according to the embodiment of the present invention includes the gas barrier layer at least on a surface that comes into contact with air in a case where the light absorption filter according to the embodiment of the present invention is used, it is possible to suppress a decrease in the absorption intensity of the dye in the light absorption filter according to the embodiment of the present invention. As long as the gas barrier layer is provided at an interface of the light absorption filter according to the embodiment of the present invention in contact with air, the gas barrier layer may be provided on only one surface of the light absorption filter according to the embodiment of the present invention, or may be provided on both surfaces.

Among the above, in a case of a configuration in which the gas barrier layer contains a crystalline resin, the gas barrier layer contains a crystalline resin, and it is preferable that the thickness of the layer is 0.1 μm to 10 μm and the oxygen permeability of the layer is 60 cc/m²·day·atm or less.

In the gas barrier layer, the “crystalline resin” is a resin having a melting point that undergoes a phase transition from a crystal to a liquid in a case where the temperature is raised, and can impart gas barrier properties related to oxygen gas to the gas barrier layer.

(Crystalline Resin)

The crystalline resin contained in the gas barrier layer is a crystalline resin having gas barrier properties, and can be used without particular limitation as long as a desired oxygen permeability can be imparted to the gas barrier layer.

Examples of the crystalline resin can include polyvinyl alcohol and polyvinylidene chloride, and the polyvinyl alcohol is preferable from the viewpoint that a crystalline portion can effectively suppress the permeation of gas.

The polyvinyl alcohol may be modified or may not be modified. Examples of the modified polyvinyl alcohol include modified polyvinyl alcohol into which a group such as an acetoacetyl group and a carboxyl group is introduced.

The saponification degree of the polyvinyl alcohol is preferably 80.0% by mol or more, more preferably 90.0% by mol or more, still more preferably 97.0% by mol or more, and particularly preferably 98.0% by mol or more, from the viewpoint of further enhancing the oxygen gas barrier properties. The upper limit value thereof is not particularly limited, and it is practically 99.99% by mol or less. The saponification degree of the polyvinyl alcohol is a value calculated based on the method described in JIS K 6726 1994.

The gas barrier layer may contain any component usually contained in the gas barrier layer, as long as the effect of the present invention is not impaired. For example, in addition to the above crystalline resin, organic-inorganic hybrid materials such as an amorphous resin material and a sol-gel material, and inorganic materials such as SiO₂, SiOₓ, SiON, SiNₓ, and Al₂O₃ may be contained.

Further, the gas barrier layer may contain a solvent such as water and an organic solvent derived from a manufacturing step, as long as the effect of the present invention is not impaired.

The content of the crystalline resin in the gas barrier layer is, for example, preferably 90% by mass or more, and more preferably 95% by mass or more, in 100% by mass of the total mass of the gas barrier layer. The upper limit value thereof is not particularly limited, and it can be set to 100% by mass.

The oxygen permeability of the gas barrier layer is preferably 60 cc/m²·day·atm or less, more preferably 50 cc/m²·day·atm or less, still more preferably 30 cc/m²·day·atm or less, and particularly preferably 10 cc/m²·day·atm or less. Among the above, it is preferably 5 cc/m²·day·atm or less and most preferably 1 cc/m²·day·atm or less. The practical lower limit value thereof is 0.001 cc/m²·day·atm or more, and it is preferably, for example, more than 0.05 cc/m²·day·atm. In a case where the oxygen permeability is within the above-described preferred range, the light resistance can be further improved.

The oxygen permeability of the gas barrier layer is a value measured based on the gas permeability test method based on JIS K 7126-2 2006 As the measuring device, for example, an oxygen permeability measuring device OX-TRAN2/21 (product name) manufactured by MOCON can be used. The measurement conditions are set to a temperature of 25° C. and a relative humidity of 50%.

For the oxygen permeability, (fm)/(s·Pa) can be used as the SI unit. It is possible to carry out the conversion by (1 fm)/(s·Pa)=8.752 (cc)/(m²·day·atm). fm is read as femtometer and represents 1 fm=10⁻¹⁵ m.

The thickness of the gas barrier layer is preferably 0.5 μm to 5 μm, and more preferably 1.0 μm to 4.0 μm, from the viewpoint of further improving the light resistance.

The thickness of the gas barrier layer is measured by a method of capturing a cross-sectional image using a field emission scanning electron microscope S-4800 (product name) manufactured by Hitachi High-Technologies Corporation.

The degree of crystallinity of the crystalline resin contained in the gas barrier layer is preferably 25% or more, more preferably 40% or more, and still more preferably 45% or more. The upper limit value thereof is not particularly limited, and it is practically 55% or less and preferably 50% or less.

The degree of crystallinity of the crystalline resin contained in the gas barrier layer is a value measured and calculated according to the following method based on the method described in J. Appl. Pol. Sci., 81, 762 (2001).

Using a differential scanning calorimeter (DSC), a temperature of a sample peeled from the gas barrier layer is raised at 10° C./min over the range of 20° C. to 260° C., and a heat of fusion 1 is measured. Further, as a heat of fusion 2 of the perfect crystal, the value described in J. Appl. Pol. Sci., 81, 762 (2001) is used. Using the obtained heat of fusion 1 and heat of fusion 2, the degree of crystallinity is calculated according to the following expression.

[Degree of crystallinity (%)]=([heat of fusion 1]/[heat of fusion 2])×100

The heat of fusion 1 and heat of fusion 2 may have the same unit, which is generally Jg⁻¹.

<Method of Manufacturing Gas Barrier Layer>

The method of forming the gas barrier layer is not particularly limited, and examples thereof include a forming method according to a conventional method, for example in a case of an organic material, according to a casting method such as spin coating or slit coating. In addition, examples thereof can include a method of bonding a commercially available resin gas barrier film or a resin gas barrier film produced in advance to the light absorption filter according to the embodiment of the present invention. Further, in a case of an inorganic material, examples thereof include a plasma CVD method, a sputtering method, and a vapor deposition method.

<Optical Functional Film>

The light absorption filter according to the embodiment of the present invention may appropriately have the gas barrier layer or any optical functional film, as long as the effect of the present invention is not impaired.

The optional optical functional film is not particularly limited in terms of any of optical properties and materials, and a film containing (or containing as a main component) at least any of a cellulose ester resin, an acrylic resin, a cyclic olefin resin, and a polyethylene terephthalate resin can be preferably used. It is noted that an optically isotropic film or an optically anisotropic phase difference film may be used.

For the above optional optical functional films, for example, Fujitac TD80UL (manufactured by FUJIFILM Corporation) or the like can be used as a film containing a cellulose ester resin.

Regarding the optional optical functional film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical functional film containing a (meth)acrylic resin having a glutaric anhydride unit in described in JP2009-139754A can be used.

Further, regarding the optional optical functional films, as those containing a cyclic olefin resin, cyclic olefin-based resin film described in paragraphs 0029 and subsequent paragraphs of JP2009-237376A, and cyclic olefin resin film containing an additive reducing Rth described in JP4881827B, JP2008-063536B can be used.

[Optical Filter]

The optical filter according to the embodiment of the present invention is obtained by subjecting the light absorption filter according to the embodiment of the present invention to mask exposure by ultraviolet irradiation.

The optical filter according to the embodiment of the present invention has a light absorptive portion having an light absorption effect and a portion in which light absorption properties have been eliminated (a light absorption property-eliminated portion) in response to a mask exposure pattern (hereinafter, also referred to as a“mask pattern”).

That is, in a case where the light absorption filter according to the embodiment of the present invention is subjected to mask exposure by ultraviolet irradiation, the masked portion of the light absorption filter according to the embodiment of the present invention is not exposed and present as a light absorptive portion having a light absorption effect, whereas the unmasked portion is exposed and becomes a light absorption property-eliminated portion.

The light absorptive portion can exhibit a desired absorbance.

Further, the light absorption property-eliminated portion can exhibit optical properties close to being colorless since the light absorption filter according to the embodiment of the present invention exhibits an excellent decolorization rate and secondary absorption seldom occurs in association with the decomposition of the dye.

<Method of Manufacturing Optical Filter>

The optical filter according to the embodiment of the present invention can be obtained by irradiating the light absorption filter according to the embodiment of the present invention with an ultraviolet ray to carrying out mask exposure.

The mask pattern can be appropriately adjusted so that the optical filter according to the embodiment of the present invention having a desired pattern consisting of a light absorptive portion and a light absorption property-eliminated portion can be obtained.

The conditions of ultraviolet irradiation can be appropriately adjusted so that the optical filter according to the embodiment of the present invention having a light absorption property-eliminated portion can be obtained. For example, the pressure condition can be set to atmospheric pressure (101.33 kPa), and the lamp output can be set to 80 to 320 W/cm, where an air-cooled metal halide lamp, a mercury lamp, or the like can be used as the lamp to be used. The irradiation dose can be set to 200 to 1,000 mJ/cm².

In the method of manufacturing an optical filter according to the embodiment of the present invention, it is preferable to carry out irradiation with an ultraviolet ray under heating conditions from the viewpoint of realizing the achievement of both the light resistance of the unexposed portion and the decolorizing property of the exposed portion at a higher level while reducing the molar formulation ratio of the radical generator to the dye.

The heating temperature is preferably a temperature exceeding the glass transition temperature of the light absorption filter that is irradiated with an ultraviolet ray from the viewpoint that the color derived from the dye is more easily decolorized. This is conceived to be because the radical generator is easily diffused by increasing the mobility of the molecular chain of the matrix resin component constituting the light absorption filter. In a case where the irradiation with an ultraviolet ray is carried out at a heating temperature exceeding the glass transition temperature, an excellent decolorizing property can be exhibited even in a case where the adding amount of the radical generator with respect to the dye is reduced, and as a result, it is possible to obtain an optical filter that achieves both the decolorizing property in the light absorption property-eliminated portion and the light resistance in the light absorptive portion at a high level.

Here, the heating temperature means the temperature of the light absorption filter at the time of ultraviolet irradiation.

As described above, the glass transition temperature of the light absorption filter is a value measured by the method described in Examples described later.

From the viewpoint of further improving the ease of decolorization, the heating temperature is preferably the glass transition temperature of the light absorption filter+5° C. or higher, more preferably the glass transition temperature of the light absorption filter+10° C. or higher, still more preferably the glass transition temperature of the light absorption filter+20° C. or higher, and particularly preferably the glass transition temperature of the light absorption filter+25° C. or higher. Among the above, it is preferably the glass transition temperature of the light absorption filter+30° C. or higher. The upper limit value of the heating temperature is not particularly limited, and it is practically 200° C. or lower.

Heating can be appropriately carried out by a conventional method. For example, as the heating device, a hot plate or the like can be used. In a case where the set temperature of the heating device is set to the heating temperature, it is possible to irradiate the light absorption filter with an ultraviolet ray while heating it to the heating temperature.

The masking can be carried out according to a conventional method in accordance with the light absorption filter according to the embodiment of the present invention.

The optical filter according to the embodiment of the present invention may have an optical functional film described in the light absorption filter according to the embodiment of the present invention.

Further, the optical filter according to the embodiment of the present invention may have a layer containing an ultraviolet absorbing agent. As the ultraviolet absorbing agent, a commonly used compound can be used without particular limitation, and examples thereof include an ultraviolet absorbing agent in the ultraviolet absorbing layer described later. The resin constituting the layer containing the ultraviolet absorbing agent is also not particularly limited, and examples thereof include a resin in the ultraviolet absorbing layer described later. The content of the ultraviolet absorbing agent in the layer containing the ultraviolet absorbing agent is appropriately adjusted depending on the intended purpose.

<<Method of Manufacturing Laminate>>

In a case where the above-described gas barrier layer is provided in the light absorption filter according to the embodiment of the present invention, for example, a method of directly producing the above-described gas barrier layer on the light absorption filter according to the embodiment of the present invention produced according to the above-described production method is included. In this case, it is also preferable to apply a corona treatment to the surface of the light absorption filter according to the embodiment of the present invention to which the gas barrier layer is provided.

Further, in a case where the above-described optional optical functional film is provided, it is also preferable to carry out bonding while interposing a pressure sensitive adhesive layer. For example, it is also preferable that a gas barrier layer is provided on the light absorption filter according to the embodiment of the present invention and then bonded to an optical functional film while interposing a pressure sensitive adhesive layer.

[OLED Display Device]

The organic electroluminescent display device according to the embodiment of the present invention (referred to as an organic electroluminescence (EL) display device or an organic light emitting diode (OLED) display device, and abbreviated as an OLED display device in the present invention) includes the optical filter according to the embodiment of the present invention.

As other configurations of the OLED display device according to the embodiment of the present invention, the configuration of the typically used OLED display device can be used without particular limitation, as long as the optical filter according to the embodiment of the present invention is included. The configuration example of the OLED display device according to the embodiment of the present invention is not particularly limited, and examples thereof include a display device including glass, a layer containing a thin film transistor (TFT), an OLED display element, a barrier film, a color filter, glass, a pressure sensitive adhesive layer, the optical filter according to the embodiment of the present invention, and a surface film, in order from the opposite side to external light.

The OLED display element has a configuration in which an anode electrode, a light emitting layer, and a cathode electrode are laminated in this order. In addition to the light emitting layer, a hole injection layer, a hole transport layer, an electron transport layer, an electron injection layer, and the like are included between the anode electrode and the cathode electrode. In addition, for example, the description in JP2014-132522A can also be referenced.

Further, as the color filter, in addition to a typical color filter, a color filter in which quantum dots are laminated can also be used.

A resin film can be used instead of the above glass.

<Pressure Sensitive Adhesive Layer>

In the OLED display device according to the embodiment of the present invention, it is preferable that the optical filter according to the embodiment of the present invention is bonded to the glass (the base material) while interposing a pressure sensitive adhesive layer, on a surface positioned opposite to the side of the external light.

The composition of the pressure sensitive adhesive composition that is used for forming the pressure sensitive adhesive layer is not particularly limited, and for example, a pressure sensitive adhesive composition containing a base resin having a mass average molecular weight (M_{w}) of 500,000 or more may be used. In a case where the mass average molecular weight of the base resin is less than 500,000, the durability reliability of the pressure sensitive adhesive may decrease due to a decrease in cohesive force causing bubbles or peeling phenomenon under at least one of the high temperature condition or the high humidity condition. The upper limit of the mass average molecular weight of the base resin is not particularly limited. However, in a case where the mass average molecular weight is excessively increased, the coating property may deteriorate due to the increase in viscosity, and thus the upper limit thereof is preferably 2,000,000 or less.

The specific kind of the base resin is not particularly limited, and examples thereof include an acrylic resin, a silicone-based resin, a rubber-based resin, and an ethylene-vinyl acetate (EVA)-based resin. In a case of being applied to an optical device such as a liquid crystal display device, an acrylic resin is mainly used in that the acrylic resin is excellent in transparency, oxidation resistance, and resistance to yellowing, and it is not limited thereto.

Examples of the acrylic resin include a polymer of monomer mixture containing 80 parts by mass to 99.8 parts by mass of the (meth)acrylic acid ester monomer; and 0.02 parts by mass to 20 parts by mass (preferably 0.2 parts by mass to 20 parts by mass) of another crosslinkable monomer.

The kind of the (meth)acrylic acid ester monomer is not particularly limited, and examples thereof include alkyl (meth)acrylate. In this case, in a case where the alkyl group contained in the monomer becomes an excessively long chain, the cohesive force of the pressure sensitive adhesive may decrease, and it may be difficult to adjust the glass transition temperature (T_{g}) or the adhesiveness. Therefore, it is preferable to use a (meth)acrylic acid ester monomer having an alkyl group having 1 to 14 carbon atoms. Examples of such a monomer include methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethylbutyl (meth)acrylate, n-octyl (meth)acrylate, isooctyl (meth)acrylate, isononyl (meth)acrylate, lauryl (meth)acrylate, isobonyl (meth)acrylate, and tetradecyl (meth)acrylate. In the present invention, the above-described monomers may be used alone or two or more kinds thereof may be used in combination. The (meth)acrylic acid ester monomer is preferably contained in an amount of 80 parts by mass to 99.8 parts by mass in 100 parts by mass of the monomer mixture. In a case where the content of the (meth)acrylic acid ester monomer is less than 80 parts by mass, the initial adhesive force may decrease, and in a case where the content exceeds 99.8 parts by mass, the durability may decrease due to the decrease in cohesive force.

The other crosslinkable monomer contained in the monomer mixture reacts with a polyfunctional crosslinking agent described later to impart a cohesive force to the pressure sensitive adhesive, and can impart a crosslinking functional group having a role of adjusting the pressure sensitive adhesive force and durability reliability to the polymer. Examples of such a crosslinkable monomer include a hydroxy group-containing monomer, a carboxyl group-containing monomer, and a nitrogen-containing monomer. Examples of the hydroxy group-containing monomer include 2-hydroxyethyl (meth)acrylate, 2-hydroxypropyl (meth)acrylate, 4-hydroxybutyl (meth)acrylate, 6-hydroxyhexyl (meth)acrylate, and 8-hydroxyoctyl (meth)acrylate, 2-hydroxyethylene glycol (meth)acrylate, and 2-hydroxypropylene glycol (meth)acrylate. Examples of the carboxyl group-containing monomer include acrylic acid, methacrylic acid, 2-(meth)acryloyloxyacetic acid, 3-(meth)acryloyloxypropyl acid, 4-(meth)acryloyloxybutyl acid, an acrylic acid dimer, itaconic acid, maleic acid, and a maleic acid anhydride. Examples of the nitrogen-containing monomer include (meth)acrylamide, N-vinylpyrrolidone, and N-vinylcaprolactam. In the present invention, these crosslinkable monomers may be used alone or two or more kinds thereof may be used in combination.

The other crosslinkable monomer may be contained in an amount of 0.02 parts by mass to 20 parts by mass in 100 parts by mass of the monomer mixture. In a case where the content is less than 0.02 parts by mass, the durability reliability of the pressure sensitive adhesive may decrease, and in a case where the content exceeds 20 parts by mass, at least one of the adhesiveness or the peelability may decrease.

The monomer mixture may further contain a monomer represented by General Formula (10). Such a monomer can be added for the intended purpose of adjusting the glass transition temperature of the pressure sensitive adhesive and imparting other functionality.

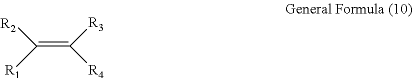

In the formula, R₁ to R₃ each independently represent a hydrogen atom or an alkyl group, and R₄ represents a cyano group; a phenyl group substituted with an alkyl group or an unsubstituted phenyl group; an acetyloxy group; or COR₅ (here, R₅ represents an alkyl group substituted with an alkyl group or alkoxyalkyl group or an unsubstituted amino group, or a glycidyloxy group).

In the definition of R₁ to R₅ in the formula, the alkyl group or the alkoxy group means alkyl or alkoxy having 1 to 12 carbon atoms, preferably 1 to 8 carbon atoms, and more preferably 1 to 12 carbon atoms, and specifically, may be methyl, ethyl, methoxy, ethoxy, propoxy, or butoxy.

Examples of the monomer represented by General Formula (10) include one or two or more of nitrogen-containing monomers such as (meth)acrylonitrile, (meth)acrylamide, N-methyl (meth)acrylamide, and N-butoxymethyl (meth)acrylamide; styrene-based monomers such as styrene or methylstyrene; epoxy group-containing monomer such as glycidyl (meth)acrylate; or a carboxylic acid vinyl ester such as vinyl acetate, and are not limited thereto. The monomer represented by General Formula (10) can be contained in an amount of 20 parts by mass or less with respect to 100 parts by mass in total of the (meth)acrylic acid ester monomer and other crosslinkable monomers. In a case where the content exceeds 20 parts by mass, at least one of the flexibility or the peelability of the pressure sensitive adhesive may decrease.

The method of producing a polymer using a monomer mixture is not particularly limited, and the polymer can be produced, for example, through a general polymerization method such as solution polymerization, photopolymerization, bulk polymerization, suspension polymerization, or emulsion polymerization. In the present invention, it is particularly preferable to use a solution polymerization method, and solution polymerization is preferably carried out at a polymerization temperature of 50° C. to 140° C. by mixing an initiator in a state where each monomer is uniformly mixed. In this case, examples of the initiator used include azo-based polymerization initiators such as azobisisobutyronitrile and azobiscyclohexanecarbonitrile; and ordinary initiators such as peroxides such as benzoyl peroxide and acetyl peroxide.

The pressure sensitive adhesive composition may further contain 0.1 parts by mass to 10 parts by mass of a crosslinking agent with respect to 100 parts by mass of the base resin. Such a crosslinking agent can impart cohesive force to the pressure sensitive adhesive through a crosslinking reaction with the base resin. In a case where the content of the crosslinking agent is less than 0.1 parts by mass, the cohesive force of the pressure sensitive adhesive may decrease. On the other hand, in a case where the content exceeds 10 parts by mass, durability reliability may decrease due to delamination and floating phenomenon.

The kind of the crosslinking agent is not particularly limited, and for example, any crosslinking agent such as an isocyanate-based compound, an epoxy-based compound, an aziridine-based compound, and a metal chelate-based compound can be used.

Examples of the isocyanate-based compound include tolylene diisocyanate, xylene diisocyanate, diphenylmethane diisocyanate, hexamethylene diisocyanate, isophorone diisocyanate, tetramethylxylene diisocyanate, and naphthalene diisocyanate, and a reactant of any one of these compounds and polyol (for example, trimethylolpropane); examples of the epoxy-based compound include ethylene glycol diglycidyl ether, triglycidyl ether, trimethylolpropane triglycidyl ether, N,N,N′,N′-tetraglycidyl ethylenediamine, and glycerin diglycidyl ether; and examples of aziridine-based compounds include N,N′-toluene-2,4-bis(1-aziridine carboxamide), N,N′-diphenylmethane-4,4′-bis(1-aziridine carboxamide), triethylene melamine, bisprothaloyl-1-(2-methylaziridine), and tri-1-aziridinylphosphine oxide. Examples of the metal chelate-based compound include compounds in which at least any one of polyvalent metals such as aluminum, iron, zinc, tin, titanium, antimony, magnesium, and vanadium is coordinated with acetylacetone or ethyl acetoacetate.

The pressure sensitive adhesive composition may further contain 0.01 parts by mass to 10 parts by mass of a silane-based coupling agent with respect to 100 parts by mass of the base resin. The silane-based coupling agent can contribute to the improvement of adhesive reliability in a case where the pressure sensitive adhesive is left for a long time under high temperature or high humidity conditions, particularly improve the adhesive stability in a case where adhering to a glass base material, and improve heat resistance and moisture resistance. Examples of the silane-based coupling agent include γ-glycidoxypropyltrimethoxysilane, γ-glycidoxypropylmethyldiethoxysilane, γ-glycidoxypropyltriethoxysilane, 3-mercaptopropyltrimethoxysilane, vinyltrimethoxysilane, vinyl triethoxysilane, γ-methacryloxypropyltrimethoxysilane, γ-methacryloxypropyltriethoxysilane, γ-aminopropyltriethoxysilane, 3-isocyanuppropyltriethoxysilane, γ-acetoacetatepropyltrimethoxysilane. These silane-based coupling agents may be used alone or two or more kinds thereof may be used in combination.

The silane-based coupling agent is preferably contained in an amount of 0.01 parts by mass to 10 parts by mass, and still more preferably contained in an amount of 0.05 parts by mass to 1 part by mass, with respect to 100 parts by mass of the base resin. In a case where the content is less than 0.01 parts by mass, the effect of increasing the pressure sensitive adhesive force may not be sufficient, and in a case where the content exceeds 10 parts by mass, durability reliability may decrease, which includes the occurrence of bubbling or peeling phenomenon.

The above-described pressure sensitive adhesive composition can further contain an antistatic agent. As the antistatic agent, any compound can be used, as long as the antistatic agent has excellent compatibility with other components contained in the pressure sensitive adhesive composition such as an acrylic resin, not adversely affect the transparency of the pressure sensitive adhesive, workability, and durability and can impart the antistatic performance to the pressure sensitive adhesive. Examples of the antistatic agent include inorganic salts and organic salts.

The inorganic salt is a salt containing an alkali metal cation or an alkaline earth metal cation as a cation component. Examples of the cation include one or two or more of a lithium ion (Li⁺), a sodium ion (Na⁺), a potassium ion (K⁺), a rubidium ion (Rb⁺), a cesium ion (Cs⁺), a beryllium ion (Be²⁺), a magnesium ion (Mg²⁺), a calcium ion (Ca²⁺), a strontium ion (Sr²⁺), and a barium ion (Ba²⁺), and preferred examples thereof include a lithium ion (Li⁺), a sodium ion (Na⁺), a potassium ion (K⁺), a cesium ion (Cs⁺), a beryllium ion (Be²⁺), a magnesium ion (Mg²⁺), a calcium ion (Ca²⁺), and a barium ion (Ba²⁺). The inorganic salt may be used alone or two or more kinds thereof may be used in combination. A lithium ion (Li⁺) is particularly preferable in terms of ion safety and mobility within the pressure sensitive adhesive.

The organic salt is a salt containing onium cations as a cation component. The term “onium cation” means ion charged to the cation (+), where at least some of the charge is unevenly distributed on one or more of the nitrogen (N), phosphorus (P), and sulfur (S). The onium cation is a cyclic or acyclic compound, and in the case of a cyclic compound, a non-aromatic or aromatic compound can be adopted. Further, in the case of a cyclic compound, one or more heteroatoms (for example, oxygen) other than nitrogen, phosphorus, or a sulfur atom can be contained. Further, the cyclic or acyclic compound is optionally substituted with a substituent such as a hydrogen atom, a halogen atom, alkyl, or aryl. Further, in the case of an acyclic compound, one or more, preferably four or more substituents can be contained, and in this case, the substituent is a cyclic type or an acyclic substituent or an aromatic or non-aromatic substituent.

The onium cation is preferably a cation containing a nitrogen atom and more preferably an ammonium ion. The ammonium ion is a quaternary ammonium ion or an aromatic ammonium ion.

Specifically, the quaternary ammonium ion is preferably a cation represented by General Formula 11.

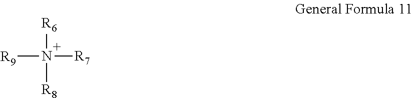

In General Formula 11, R₆ to R₉ each independently represent a hydrogen atom, substituted or unsubstituted alkyl, substituted or unsubstituted alkoxy, substituted or unsubstituted alkenyl, substituted or unsubstituted alkynyl, a substituted or unsubstituted aryl, or a substituted or unsubstituted heteroaryl.

The alkyl or alkoxy in General Formula 11 represents alkyl or alkoxy having 1 to 12 carbon atoms, and preferably 1 to 8 carbon atoms. The alkenyl or alkynyl represents alkenyl or alkynyl having 2 to 12 carbon atoms, and preferably 2 to 8 carbon atoms.

In General Formula 11, aryl represents a phenyl, biphenyl, naphthyl, or anthracenyl cyclic system, as a substituent derived from an aromatic compound, and heteroaryl represents a heterocyclic ring or aryl ring having 5 to 12 rings including one or more heteroatoms of O, N, and S, where it specifically represents prill, pyrrolyl, pyrodinyl, thienyl, pyridinyl, piperidyl, indolyl, quinolyl, thiazole, benzothiazole, or triazole.

In General Formula 11, alkyl, alkoxy, alkenyl, alkynyl, aryl, or heteroaryl may be substituted with one or more substituents. In this case, as the substituent, a hydroxy group, a halogen atom, or alkyl or alkoxy having 1 to 12 carbon atoms, preferably 1 to 8 carbon atoms, more preferably 1 to 4 carbon atoms can be exemplified.

In the present invention, it is preferable to use a quaternary ammonium cation as the cation represented by General Formula 11. In particular, a cation in which R₁ to R₄ are each independently a substituted or unsubstituted alkyl having 1 to 12 carbon atoms and preferably having 1 to 8 carbon atoms is used.

Examples of the quaternary ammonium ion represented by General Formula 11 include N-ethyl-N,N-dimethyl-N-(2-methoxyethyl) ammonium ion, N,N-diethyl-N-methyl-N-(2-methoxyethyl) ammonium ion, N-ethyl-N,N-dimethyl-N-propylammonium ion, N-methyl-N,N,N-trioctylammonium ion, N,N,N-trimethyl-N-propylammonium ion, tetrabutylammonium ion, tetramethylammonium ion, tetrahexylammonium ion, N-methyl-N,N,N-tributylammonium ion.

Examples of the aromatic ammonium ion include one or more ions of pyridinium, pyridadinium, pyrimidinium, pyrazinium, imidazolium, pyrazolium, thiazolium, oxazolium, and triazolium, and preferred examples thereof include an N-alkylpyridinium ion substituted with an alkyl group having 4 to 16 carbon atoms, a 1,3-alkylmethylimidazolium ion substituted with an alkyl group having 2 to 10 carbon atoms, and a 1,2-dimethyl-3-alkylimidazolium ion substituted with an alkyl group having 2 to 10 carbon atoms. These aromatic ammonium ions may be used alone or two or more kinds thereof may be used in combination.

The aromatic ammonium ion is a compound represented by General Formula 12.

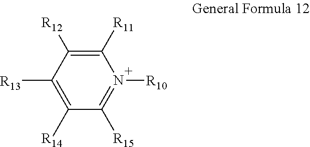

In General Formula 12, R₁₀ to R₁₅ each independently represent a hydrogen atom, substituted or unsubstituted alkyl, substituted or unsubstituted alkoxy, substituted or unsubstituted alkenyl, substituted or unsubstituted alkynyl, a substituted or unsubstituted aryl, or a substituted or unsubstituted heteroaryl.

In General Formula 12, the definitions for alkyl, alkoxy, alkenyl, alkynyl, aryl, and heteroaryl, and their substitutes are the same as in General Formula 11 above.

As the compound of General Formula 12, it is particularly preferable that R₁₁ to R₁₅ are each independently a hydrogen atom or alkyl, and R₁₀ is alkyl.

Preferred examples of the anion contained in the cation-containing inorganic salt or organic salt as described above in the antistatic agent include fluoride (F⁻), chloride (Cl⁻), and bromide (Br⁻), iodide (I⁻), perchlorate (ClO₄⁻), hydroxide (OH⁻), carbonate (CO₃²⁻), nitrate (NO₃⁻), sulfonate (SO₄⁻), methylbenzenesulfonate (CH₃(C₆H₄)SO₃⁻), p-toluenesulfonate (CH₃C₆H₄SO₃⁻), carboxybenzenesulfonate (COOH(C₆H₄)SO₃⁻), trifluoromethanesulfonate (CF₃SO₂⁻), benzoate (C₆H₅COO⁻), acetate (CH₃COO⁻), trifluoroacetate (CF₃COO⁻), tetrafluoroborate (BF₄⁻), tetrabenzylborate (B(C₆H₅)₄⁻), hexafluorophosphate (PF₆⁻), trispentafluoro ethyltrifluorophosphate (P(C₂F₅)₃F₃⁻), bistrifluoromethanesulfonimide (N(SO₂CF₃)₂⁻), bispentafluoroethanesulfonumide (N(SOC₂F₅)₂⁻), bispentafluoroethanecarbonylimide (N(COC₂F₅)₂⁻), bisperfluorobutane sulfoneimide (N(SO₂C₄F₉)₂⁻), bisperfluorobutanecarbonylimide (N(COC₄F₉)₂⁻), tristrifluoromethanesulfonylmethide (C(SO₂CF₃)₃⁻), and tristrifluoromethanecarbonylmethide (C(SO₂CF₃)⁻), which are not limited thereto. Among the anions, it is preferable to use an imide-based anion which can function as electron withdrawing and is substituted with fluorine having good hydrophobicity and has high ionic stability.

The pressure sensitive adhesive composition contains an antistatic agent in an amount of 0.01 parts by mass to 5 parts by mass, preferably 0.01 parts by mass to 2 parts by mass, more preferably 0.1 parts by mass to 2 parts by mass, with respect to 100 parts by mass of the base resin. In a case where the content is less than 0.01 parts by mass, the desired antistatic effect may not be obtained, and in a case where the content exceeds 5 parts by mass, the compatibility with other components is reduced and the durability reliability of the pressure sensitive adhesive or the transparency may be deteriorated.

The pressure sensitive adhesive composition further includes a compound capable of forming a coordinate bond with an antistatic agent, specifically, with a cation contained in the antistatic agent (hereinafter, referred to as a “coordinate-bonding compound”). In a case where a coordinate-bonding compound is properly contained, it is possible to effectively impart antistatic performance by increasing the anion concentration inside the pressure sensitive adhesive layer even in a case where a relatively small amount of antistatic agent is used.

The kind of the coordinate-bonding compound that can be used is not particularly limited as long as it has a functional group capable of coordinating with the antistatic agent in the molecule, and examples thereof include alkylene oxide-based compounds.

The alkylene oxide-based compound is not particularly limited, and it is preferable to use an alkylene oxide-based compound containing an alkylene oxide unit that has a basic unit having 2 or more carbon atoms, preferably 3 to 12 carbon atoms, and more preferably 3 to 8 carbon atoms.

The alkylene oxide-based compound preferably has a molecular weight of 5,000 or less. The term “molecular weight” that is used in the present invention means the molecular weight or mass average molecular weight of a compound. In the present invention, in a case where the molecular weight of the alkylene oxide-based compound exceeds 5,000, the viscosity may be excessively increased and the coating property may be deteriorated, or the complex forming ability with the metal may be lowered. On the other hand, the lower limit of the molecular weight of the alkylene oxide compound is not particularly limited; however, it is preferably 500 or more, and more preferably 4,000 or more.

The alkylene oxide-based compound is not particularly limited as long as the compound exhibits the above-described characteristics, and for example, a compound represented by General Formula 13 can be used.

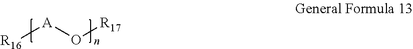

In General Formula 13, A represents an alkylene having 2 or more carbon atoms, n represents 1 to 120, R₁₆ and R₁₇ each independently represent a hydrogen atom, hydroxy, alkyl, or C(═O)R₁₈, and R₁₈ represents a hydrogen atom or an alkyl group.

In General Formula 13, the alkylene represents an alkylene having 3 to 12, preferably 3 to 8 carbon atoms, and specifically, ethylene, propylene, butylene, or pentylene.

In General Formula 13, alkyl represents alkyl having 1 to 12 carbon atoms, preferably 1 to 8 carbon atoms, and more preferably 1 to 4 carbon atoms, and n is preferably 1 to 80 and more preferably 1 to 40.

Examples of the compound represented by General Formula 13 include polyalkylene oxide (for example, polyethylene oxide, polypropylene oxide, polybutylene oxide, or polypentylene oxide), fatty acid-based alkyl esters of polyalkylene oxide (for example, polyethylene oxide, polypropylene oxide, polybutylene oxide, or polypentylene oxide), carboxylic acid esters of polyalkylene oxide (for example, polyethylene oxide, polypropylene oxide, polybutylene oxide, or polypentylene oxide), and the like, and are not limited thereto.

In the present invention, in addition to the above-described alkylene oxide-based compound, various coordinate-bonding compounds such as an ester compound having one or more ether bonds disclosed in KR2006-0018495A, an oxalate group-containing compound disclosed in KR2006-0128659A, a diamine group-containing compound, a polyvalent carboxyl group-containing compound, or a ketone group-containing compound can be appropriately selected and used as necessary.

The coordinate-bonding compound is preferably contained in the pressure sensitive adhesive composition at a ratio of 3 parts by mass or less with respect to 100 parts by mass of the base resin, more preferably 0.1 parts by mass to 3 parts by mass, and still more preferably, 0.5 parts by mass to 2 parts by mass. In a case where the content exceeds 3 parts by mass, the pressure sensitive adhesive physical properties such as peelability may deteriorate.

From the viewpoint of adjusting the adhesive performance, the pressure sensitive adhesive composition may further contain 1 part by mass to 100 parts by mass of a tackifying resin with respect to 100 parts by mass of the base resin. In a case where the content of the tackifying resin is less than 1 part by mass, the addition effect may not be sufficient, and in a case where the exceeds 100 parts by mass, at least one of the compatibility or the cohesive force improving effect may be lowered. The tackifying resin is not particularly limited, and examples thereof include a (hydrogenated) hydrocarbon resin, a (hydrogenated) rosin resin, a (hydrogenated) rosin ester resin, a (hydrogenated) terpene resin, a (hydrogenated) terpene phenol resin, a polymerized rosin resin, and a polymerized rosin ester resin. These tackifying resins may be used alone or two or more kinds thereof may be used in combination.

The pressure sensitive adhesive composition may also contain one or more additives contain a polymerization initiator, such as a thermal polymerization initiator and a photopolymerization initiator; an epoxy resin; a curing agent; an ultraviolet stabilizer; an antioxidant; a toning agent, as long as the effect of the present invention is not affected. It may contain one or more additives such as a reinforcing agent; a filler; an antifoaming agent; a surfactant; a photopolymerizable compound such as a polyfunctional acrylate; and a plasticizer.

<Base Material>

In the OLED display device according to the embodiment of the present invention, it is preferable that the optical filter according to the embodiment of the present invention is bonded to the glass (the base material) w % bile interposing a pressure sensitive adhesive layer, on a surface positioned opposite to the side of the external light.

The method of forming the pressure sensitive adhesive layer is not particularly limited, and for example, a method of applying the pressure sensitive adhesive composition to the light absorption filter according to the embodiment of the present invention by a usual means such as a bar coater, drying, and curing the pressure sensitive adhesive composition; a method of applying the pressure sensitive adhesive composition first to the surface of a peelable base material, and drying the composition, and then transferring the pressure sensitive adhesive layer using the peelable base material to the light absorption filter according to the embodiment of the present invention and then aging and curing the composition is used.

The peelable base material is not particularly limited, and any peelable base material can be used. For example, the release film in the manufacturing method of the light absorption filter according to the embodiment of the present invention described above is exampled.

In addition, the conditions of application, drying, aging, and curing can be appropriately adjusted based on a conventional method.

[Liquid Crystal Display Device]

The liquid crystal display device according to the embodiment of the present invention includes the optical filter according to the embodiment of the present invention.

The optical filter according to the embodiment of the present invention may be used as at least any one of a polarizing plate-protective film or a pressure sensitive adhesive layer as described later, or it may be included in a backlight unit that is used in the liquid crystal display device.

It is preferable that the liquid crystal display device includes an optical filter, polarizing plates including a polarizer and a polarizing plate-protective film, a pressure sensitive adhesive layer, and a liquid crystal cell, and it is preferable that the polarizing plates are bonded to the liquid crystal cell while interposing a pressure sensitive adhesive layer. In the liquid crystal display device, the optical filter may also serve as the polarizing plate-protective film or the pressure sensitive adhesive layer. That is, it is divided into a case where the liquid crystal display device includes polarizing plates including a polarizer and an optical filter (polarizing plate-protective film), a pressure sensitive adhesive layer, and a liquid crystal cell, and a case where the liquid crystal display device includes polarizing plates including a polarizer and a polarizing plate-protective film, an optical filter (pressure sensitive adhesive layer), and a liquid crystal cell.

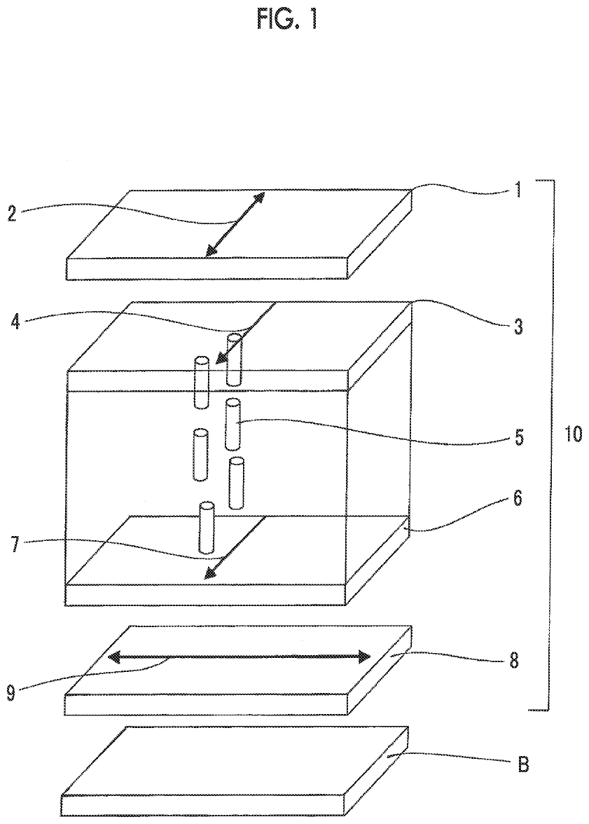

FIG. 1 is a schematic view illustrating an example of the liquid crystal display device according to the embodiment of the present invention. In FIG. 1, a liquid crystal display device 10 consists of a liquid crystal cell having a liquid crystal layer 5 and a liquid crystal cell upper electrode substrate 3 and a liquid crystal cell lower electrode substrate 6 disposed above and below the liquid crystal layer 5, and an upper polarizing plate 1 and a lower polarizing plate 8 disposed on both sides of the liquid crystal cell. A color filter layer may be laminated on the upper electrode substrate 3 or the lower electrode substrate 6. On the rear surface of the liquid crystal display device 10, a backlight is disposed. As a light source of the backlight, those described in the above backlight unit can be used.

Each of the upper polarizing plate 1 and the lower polarizing plate 8 has a configuration in which each of them is laminated such that a polarizer is sandwiched between two polarizing plate protective films, and in the liquid crystal display device 10, at least one polarizing plate is preferably a polarizing plate including the optical filter according to the embodiment of the present invention.

In addition, in the liquid crystal display device 10, the liquid crystal cell and the polarizing plate (upper polarizing plate 1 and/or lower polarizing plate 8) may be bonded together while interposing a pressure sensitive adhesive layer (not illustrated in the drawing). In this case, the optical filter according to the embodiment of the present invention may also serve as the above-described pressure sensitive adhesive layer.

The liquid crystal display device 10 includes an image direct vision-type liquid crystal display, an image projection-type liquid crystal display device, and a light modulation-type liquid crystal display device. An active matrix liquid crystal display device in which a three-terminal or two-terminal semiconductor element such as TFT or MIM is used is effective for the present invention. In addition, a passive matrix liquid crystal display device represented by an STN mode which is called as the time division driving is also effective.

In a case where the optical filter according to the embodiment of the present invention is included in the backlight unit, the polarizing plate of the liquid crystal display device may be a typical polarizing plate (a polarizing plate not including the optical filter according to the embodiment of the present invention) or may be a polarizing plate including the optical filter according to the embodiment of the present invention. In addition, the pressure sensitive adhesive layer may be a typical pressure sensitive adhesive layer (not the optical filter according to the embodiment of the present invention) or may be a pressure sensitive adhesive layer formed of the optical filter according to the embodiment of the present invention.

The IPS mode liquid crystal display device described in paragraphs 128 to 136 of JP2010-102296A is preferable as the liquid crystal display device according to the embodiment of the present invention except that the optical filter according to the embodiment of the present invention s used.

<Polarizing Plate>

The polarizing plate that is used in the present invention includes a polarizer and at least one polarizing plate protective film.

The polarizing plate that is used in the present invention is preferably a polarizing plate having a polarizer and polarizing plate protective films on both surfaces of the polarizer, and it is preferable that at least one surface of the polarizer includes the optical filter according to the embodiment of the present invention as the polarizing plate protective film. The opposite surface of the polarizer to the surface having the optical filter according to the embodiment of the present invention (polarizing plate protective film according to the embodiment of the present invention) may have a typical polarizing plate protective film.

The film thickness of the polarizing plate protective film is 5 μm to 120 μm and more preferably 10 μm to 100 μm. A thinner film is preferable since in a case of being incorporated in the liquid crystal display device, the display unevenness after elapse of time in high temperature and high humidity is less likely to occur. On the other hand, in a case where the film is too thin, it is difficult to transport the film stably at the time of manufacturing the film and producing the polarizing plate. In a case where the optical filter according to the embodiment of the present invention also serves as the polarizing plate protective film, it is preferable that the thickness of the optical filter satisfies the above-described range.

—Performance of Polarizing Plate—

The polarizing plate that is used in the present invention has a degree of polarization of preferably 99.950% or more, more preferably 99.970%, and most preferably 99.990% or more.

In the present invention, the degree of polarization of the polarizing plate is calculated according to the following expression from an orthogonal transmittance and a parallel transmittance measured at a wavelength of 380 to 700 nm using an automatic polarizing film measurement instrument: VAP-7070 (manufactured by JASCO Corporation).

Degree of polarization (%)=[(parallel transmittance−orthogonal transmittance)/(parallel transmittance+orthogonal transmittance)]^{1/2}×100

The degree of polarization can be measured as follows. Two samples (5 cm×5 cm) in which a polarizing plate has been stuck to glass while interposing a pressure sensitive adhesive are prepared. The orthogonal transmittance and the parallel transmittance are measured by setting a glass side of the sample toward a light source. The two samples are measured, and the average values thereof are defined as the orthogonal transmittance and the parallel transmittance, respectively. In a case of investigating the influence on the degree of polarization with the polarizing plate protective film, in general, the polarizing plate protective film to be evaluated is stuck to the glass while being disposed on the glass side.

Other preferred optical properties of the polarizing plate that is used in the present invention are described in [0238] to [0255] of JP2007-086748A, and it is preferable to satisfy these characteristics.

—Shape and Configuration—

The shape of the polarizing plate that is used in the present invention includes not only a polarizing plate of an aspect of a film piece cut into a size capable of being incorporated in the liquid crystal display device as it is, but also a polarizing plate of an aspect in which the polarizing plate is produced in a longitudinal shape by a continuous production and wound up in a rolled shape (for example, an aspect having a roll length of 2,500 m or more or 3,900 m or more). In order to use the polarizing plate as a large-sized screen liquid crystal display device, the width of the polarizing plate is preferably 1,470 mm or more.

The polarizing plate that is used in the present invention is composed of a polarizer and at least one polarizing plate protective film; however, it is also preferable that the polarizing plate is further composed by bonding a separate film on one surface of the polarizing plate.

The separate film is used for the intended purpose of protecting the polarizing plate during the shipping of the polarizing plate and the examination of the product. The separate film is used for the intended purpose of covering an adhesive layer which is bonded to a liquid crystal plate, and it is used on a surface where the polarizing plate is bonded to the liquid crystal plate.

(Polarizer)

The polarizer that is used in the polarizing plate that is used in the present invention will be described.

The polarizer which can be used for the polarizing plate that is used in the present invention is preferably configured of polyvinyl alcohol (PVA) and a dichroic molecule, but as described in JP1999-248937A (JP-H11-248937A), a polyvinylene-based polarizer in which a polyene structure is generated by dehydrating PVA or dechlorinating polyvinyl chloride and aligning the polyene structure can also be used.

—Film Thickness of Polarizer—

The film thickness of the polarizer before stretching is not particularly limited; however, from the viewpoint of stability of retaining film and homogeneity of stretching, it is preferably 1 μm to 1 mm and particularly preferably 5 to 200 μm. In addition, as described in JP2002-236212A, a thin PVA film of which the stress generated in a case of being stretched 4 to 6 times in water is 10 N or less may be used.

—Method of Manufacturing Polarizer—

The method of manufacturing a polarizer is not particularly limited, and it is preferable that, for example, the polarizer is configured by forming PVA into a film and introducing the dichroic molecule to the film. The PVA film can be produced with reference to the method described in [0213] to [0237] of JP2007-86748A, JP3342516B, JP1997-328593A (JP-H9-328593A), JP2001-302817A, JP2002-144401A, and the like.

(Method of Laminating Polarizer and Polarizing Plate Protective Film)

The polarizing plate that is used in the present invention is manufactured by adhering (laminating) at least one polarizing plate protective film (preferably the optical filter according to the embodiment of the present invention) on at least one surface of the above-described polarizer.

The polarizing plate that is used in the present invention is preferably produced by a method in which a polarizing plate protective film is subjected to an alkali treatment and bonded, using a completely saponified polyvinyl alcohol aqueous solution, to both surfaces of a polarizer produced by dipping and stretching a polyvinyl alcohol film in an iodine solution.

Examples of the adhesive that is used to bond the treated surface of the polarizing plate protective film to the polarizer include polyvinyl alcohol-based adhesives such as polyvinyl alcohol and polyvinyl butyral and vinyl-based latex such as butyl acrylate.

In the polarizing plate that is used in the present invention, the bonding of the polarizing plate protective film to the polarizer is preferably such bonding that the transmission axis of the polarizer and the slow axis of the polarizing plate protective film are substantially parallel, orthogonal, or 45°.

The slow axis can be measured by various known methods, for example, using a birefringence meter (KOBRADH, manufactured by Oji Scientific Instruments).

Here, “substantially parallel” refers to that the direction of the main refractive index nx of the polarizing plate protective film and the direction of the transmission axis of the polarizing plate intersect at an angle within ±5°, preferably at an angle within ±1°, and more preferably angle within 0.5°. In a case where the intersecting angle is within ±1, the performance of degree of polarization under polarizing plate crossed nicols is less likely to be deteriorated and light leakage does not easily occur, which is preferable.

The description in which the direction of the main refractive index nx and the direction of the transmission axis are orthogonal or 45° means that the angle at which the direction of the main refractive index nx and the direction of the transmission axis intersect is within a range of ±5° with respect to an exact angle of being orthogonal and 45°, and the difference with respect to the exact angle is preferably within a range of ±10 and more preferably within a range of ±0.5°.

(Functionalization of Polarizing Plate)

The polarizing plate that is used in the present invention is preferably used as a functionalized polarizing plate complexed with an antireflection film for improving the visibility of the display, a luminance improving film, or an optical film having a functional layer such as a hard coat layer, a forward scattering layer, an antiglare layer, an antifouling layer, and an antistatic layer. The antireflection film for functionalization, the luminance improving film, other functional optical films, the hard coat layer, the forward scattering layer, and the antiglare layer are described in [0257] to [0276] of JP2007-86748A, and a functionalized polarizing plate can be prepared based on the description.

<Pressure Sensitive Adhesive Layer>

In the liquid crystal display device according to the embodiment of the present invention, the polarizing plate is preferably bonded to the liquid crystal cell while interposing a pressure sensitive adhesive layer. The optical filter according to the embodiment of the present invention may also serve as the pressure sensitive adhesive layer. In a case where the optical filter according to the embodiment of the present invention does not serve as the pressure sensitive adhesive layer, a typical pressure sensitive adhesive layer can be used as the pressure sensitive adhesive layer.

The pressure sensitive adhesive layer is not particularly limited as long as the polarizing plate can be bonded to the liquid crystal cell, and for example, an acrylic type, a urethane type, polyisobutylene, or the like is preferable.

In a case where the optical filter according to the embodiment of the present invention also serves as a pressure sensitive adhesive layer, the pressure sensitive adhesive layer includes the coloring agent and the binder resin, and further contains a crosslinking agent, a coupling agent, or the like to impart adhesiveness.

In a case where the optical filter additionally serves as a pressure sensitive adhesive layer, the pressure sensitive adhesive layer includes the binder resin in an amount of preferably 90% to 100% by mass and preferably 95% to 100% by mass. The content of the coloring agent is as described above.

The thickness of the pressure sensitive adhesive layer is not particularly limited; however, it is preferably 1 to 50 μm and more preferably 3 to 30 μm.

<Liquid Crystal Cell>

The liquid crystal cell is not particularly limited, and a typical liquid crystal cell can be used.

<Ultraviolet Absorbing Layer>

The organic electroluminescent display device or liquid crystal display device including the optical filter according to the embodiment of the present invention preferably has a layer (hereinafter, also referred to as an “ultraviolet absorbing layer”) that inhibits the light absorption (the ultraviolet absorption) of the compound that generates a radical upon ultraviolet irradiation, on the viewer side with respect to the optical filter according to the embodiment of the present invention. In a case where the ultraviolet absorbing layer is provided, it is possible to prevent the fading of the optical filter according to the embodiment of the present invention due to external light.

The ultraviolet absorbing layer according to the embodiment of the present invention will be described below.

(Ultraviolet Absorbing Agent)

The ultraviolet absorbing layer according to the embodiment of the present invention contains a resin and an ultraviolet absorbing agent. From the viewpoint of excellent absorption capacity of an ultraviolet ray having a wavelength of 370 nm or less and good liquid crystal display properties, an ultraviolet absorbing agent having a small absorption of visible light having a wavelength of 400 nm or more is preferably used.

Specific examples of the ultraviolet absorbing agent preferably used in the present invention include a hindered phenol-based compound, a hydroxybenzophenone-based compound, a benzotriazole-based compound, a salicylic acid ester-based compound, a benzophenone-based compound, a cyanoacrylate-based compound, and a nickel complex salt-based compound.

Examples of the hindered phenol-based compound include 2,6-di-tert-butyl-p-cresol, pentaerythrityl-tetrakis[3-(3,5-di-tert-butyl-4-hydroxyphenyl)propionate], N,N′-hexamethylene bis(3,5-di-tert-butyl-4-hydroxy-hydrocinnamide), 1,3,5-trimethyl-2,4,6-tris(3,5-di-tert-butyl-4-hydroxybenzyl)benzene, and tris-(3,5-di-tert-butyl-4-hydroxybenzyl)-isocyanurate.

Examples of the benzotriazole-based compound include 2-(2′-hydroxy-5′-methylphenyl)benzotriazole, 2,2-methylene bis(4-(1,1,3,3-tetramethylbutyl)-6-(2H-benzotriazole-2-yl) phenol), (2,4-bis-(n-octylthio)-6-(4-hydroxy-3,5-di-tert-butylanilino)-1,3,5-triazine, triethyleneglycol-bis[3-(3-tert-butyl-5-methyl-4-hydroxyphenyl)propionate], N,N′-hexamethylene bis(3,5-di-tert-butyl-4-hydroxy-hydrocinnamide), 1,3,5-trimethyl-2,4,6-tris(3,5-di-tert-butyl-4-hydroxybenzyl)benzene, 242′-hydroxy-3′, 5′-di-tert-butylphenyl)-5-chlorbenzotriazole, (2-(2′-hydroxy-3′,5′-di-tert-amylphenyl)-5-chlorbenzotriazole, 2,6-di-tert-butyl-p-cresol, and pentaerythrityl-tetrakis[3-(3,5-di-tert-butyl-4-hydroxyphenyl)propionate].

The adding amount of this UV protection agent is preferably 0.1 part by mass to 30.0 parts by mass with respect to 100 parts by mass of the resin.

(Resin)

As the resin that is used for the ultraviolet absorbing layer according to the embodiment of the present invention, a known resin can be used, which is not particularly limited as long as it does not contradict the gist of the present invention. Examples of the resin include a cellulose acylate resin, an acrylic resin, a cycloolefin-based resin, a polyester-based resin, and an epoxy resin.

(Installation Position of Ultraviolet Absorbing Layer)

The disposition of the ultraviolet absorbing layer according to the embodiment of the present invention is not particularly limited as long as it is on the viewer side with respect to the optical filter according to the embodiment of the present invention, and the ultraviolet absorbing layer can be installed at any position. For example, it is also possible to add an ultraviolet absorbing agent to a member such as a protective film of the polarizing plate, an antireflection film, or the like to impart it a function of an ultraviolet absorbing layer.

### Examples

Hereinafter, the present invention will be described in more detail based on Examples. The materials, using amount, ratio, details of treatment, procedures of treatment, and the like described in Examples below can be appropriately changed without departing from the spirit of the present invention. Therefore, it is to be understood that the scope of the present invention is not limited to Examples described below.

It is noted that “parts” and “%” that indicate the composition in Examples below are based on mass unless otherwise specified.

All steps from a preparation step of a light absorption filter forming liquid to a production step of a base material-attached light absorption filter using the light absorption filter forming liquid and to the use thereof in the ultraviolet irradiation test were carried out under a yellow lamp to avoid ultraviolet irradiation.

[Production of Light Absorption Filter]

Materials used to prepare the light absorption filter are shown below.

<Matrix Resin (Matrix Polymer)>

(Resin 1)

A polystyrene resin (PSJ-polystyrene GPPS SGP-10 (product name), Tg: 100° C., fd: 0.56) manufactured by PS Japan Corporation was heated at 110° C., allowed to cool to room temperature (23° C.), and used as a resin 1.

(Resin 2)

A polyphenylene ether resin (manufactured by Asahi Kasei Corporation, Zylon S201A (product name), poly(2,6-dimethyl-1,4-phenylene oxide), Tg: 210° C.)

(Resin 3)

A cyclic polyolefin resin (APL6509T (product name), manufactured by Mitsui Chemicals, Inc., a copolymer of ethylene and norbornene, Tg: 80° C.)

(Resin 4)

A cyclic polyolefin resin (APL6011T (product name), manufactured by Mitsui Chemicals, Inc., a copolymer of ethylene and norbornene, Tg: 105° C.)

(Peelability Control Resin Component 1)

Byron 550 (product name, manufactured by Toyobo Co., Ltd., a polyester-based additive)

<Dye>

An alkyl group in dyes A-100 and A-102 means a linear alkyl group.

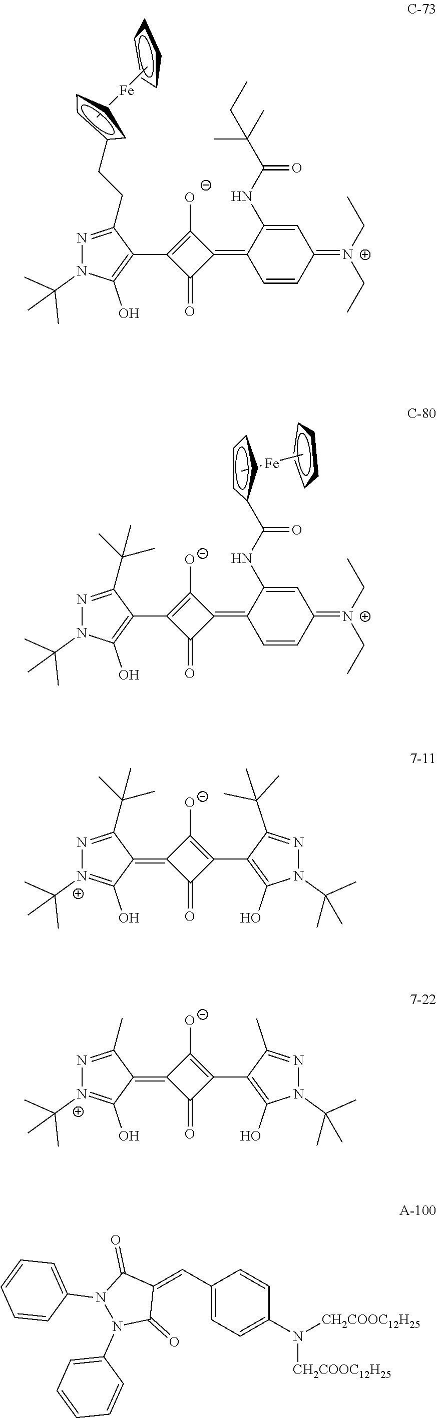

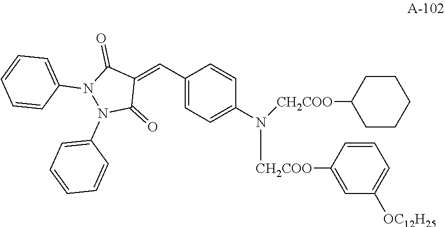

FDG007: Product name, manufactured by Yamada Chemical Co., Ltd., a tetraazaporphyrin-based coloring agent

Solvent Violet 13: Manufactured by Tokyo Chemical Industry Co., Ltd., Quinizarin Blue, an anthraquinone-based coloring agent

Solvent Blue 35: 1,4-bis(butylamino)-9,10-anthraquinone, an anthraquinone-based coloring agent

(Leveling Agent 1)

A polymer surfactant composed of the following constitutional components was used as a leveling agent 1. In the following structural formulae, the proportion of each constitutional component is in terms of a molar ratio, and t-Bu means a tert-butyl group.

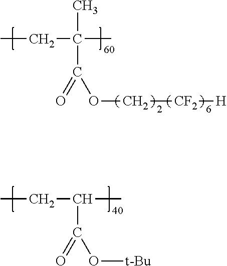

(Base Material 1)

A polyethylene terephthalate film, LUMIRROR XD-510P (product name, film thickness: 50 μm, manufactured by Toray Industries, Inc.) was used as a base material 1.

(Base Material 2)

A cellulose acylate film (manufactured by FUJIFILM Corporation, product name: ZRD40SL)

### Examples

<1. Production of Base Material-Attached Light Absorption Filter No. 101>

(1) Preparation of Resin Solution (Light Absorption Filter Forming Liquid)

Each component was mixed with the composition shown below to prepare a light absorption filter forming liquid (composition) Ba-1.

Composition of light absorption filter forming liquid Ba-1

| | | |
|---|---|---|
| Resin 1 | 74.2 | parts by mass |
| Resin 2 | 17.5 | parts by mass |
| Peelability control resin component 1 | 0.20 | parts by mass |
| Leveling Agent 1 | 0.16 | parts by mass |
| Dye C-73 | 1.57 | parts by mass |
| Photoradical generator: Irgacure 907 | 6.35 | parts by mass |
| (product name), manufactured by BASF | | |
| SE, an intramolecular cleavage type, | | |
| α-aminoalkylphenone) | | |
| Toluene (a solvent) | 1710.0 | parts by mass |
| Cyclohexanone (a solvent) | 190.0 | parts by mass |

Subsequently, the obtained light absorption filter forming liquid Ba-1 was filtered using a filter paper (#63, manufactured by Toyo Filter Paper Co., Ltd.) having an absolute filtration precision of 10 μm, and further subjected to filtration using a metal sintered filter (product name: Pall filter PMF, media code. FH025, manufactured by Pall) with an absolute filtration precision of 2.5 μm.

(2) Production of Base Material-Attached Light Absorption Filter

The above-described light absorption filter forming liquid Ba-1 after the filtration treatment was applied onto the base material 1 by using a bar coater so that the film thickness after drying was 2.5 μm, and dried at 130° C. to produce a base material-attached light absorption filter No. 101.

<2. Production of Base Material-Attached Light Absorption Filters No. 102, 121, 201, and 202>

Base material-attached light absorption filters No. 102, 121, 201, and 202 were produced in the same manner as in the production of the base material-attached light absorption filter No. 101 except that the kind of the dye or the formulation amount of the photoradical generator was changed to the contents shown in Table 1.

Here. No. 101, 102, and 121 are the light absorption filters according to the embodiment of the present invention, and No. 201 and 202 are light absorption filters for comparison.

<3. Production of Base Material-Attached Light Absorption Filter No. 103>

(1) Preparation of Resin Solution (Light Absorption Filter Forming Liquid)

Each component was mixed with the composition shown below to prepare a light absorption filter forming liquid (composition) Ba-2.

Composition of light absorption filter forming liquid Ba-2

| | | |
|---|---|---|
| Resin 3 | 90.7 | parts by mass |
| Dye C-73 | 1.57 | parts by mass |
| Photoradical generator: Benzophenone | 8.26 | parts by mass |
| (manufactured by Tokyo Chemical Industry | | |
| Co., Ltd.) | | |
| Peelabilily control resin component: TUFTEC | 3.4 | parts by mass |
| H-1043 (product name, manufactured by | | |
| Asahi Kasei Corporation) | | |
| Leveling agent: MEGAFACE F-554 | 0.16 | parts by mass |
| (product name, manufactured by DIC | | |
| Corporation, fluoropolymer) | | |
| Cyclohexane (solvent) | 770.0 | parts by mass |

Subsequently, the obtained light absorption filter forming liquid Ba-2 was filtered using a filter paper (#63, manufactured by Toyo Filter Paper Co., Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

(2) Production of Base Material-Attached Light Absorption Filter

The above-described light absorption filter forming liquid Ba-2 after the filtration treatment was applied onto the base material 2 by using a bar coater so that the film thickness after drying was 2.5 μm, and dried at 120° C. to produce a base material-attached light absorption filter No. 103.

<4. Production of Base Material-Attached Light Absorption Filters No. 104 to 109, 113 to 120, 122, 123, 203, and 204>

Base material-attached light absorption filters No. 104 to 109, 113 to 120, 122, 123, 203, and 204 were produced in the same manner as in the production of the base material-attached light absorption filter No. 103 except that the kind of the dye or at least any one of the kind or formulation amount of the photoradical generator was changed to the contents shown in Table 1.

It is noted that the base material-attached light absorption filter No. 204 further contains 6.7 parts by mass of ethyl 4-(dimethylamino)benzoate (15 mol in terms of the formulation ratio with respect to 1 mol of the dye) as a decolorization accelerating agent.

Here, Nos. 104 to 109, 113 to 120, 122, and 123 are the light absorption filters according to the embodiment of the present invention, and Nos. 203 and 204 are light absorption filters for comparison.

<5. Production of Base Material-Attached Light Absorption Filters No. 110 to 112>

Base material-attached light absorption filters No. 110 to 112 were produced in the same manner as in the production of the base material-attached light absorption filter No. 107 except that the resin 3 was changed to a resin 4.

Here, Nos. 110 to 112 are the light absorption filters according to the embodiment of the present invention.

[Production of Light Absorption Filter Having Gas Barrier Layer]

Regarding each of the base material-attached light absorption filters No. 103 to 123, 203, and 204, a light absorption filter (a light absorption filter having a gas barrier layer) formed by further laminating a gas barrier layer on the light absorption filter was produced as described below, and the evaluation described later was carried out.

(1) Production of Base Material 3

The light absorption filter side of the base material-attached light absorption filter was subjected to a corona treatment using a corona treatment device (product name: Corona-Plus, manufactured by VETAPHONE) under the conditions of a discharge amount of 1,000 W·min/m² and a processing speed of 3.2 m/min and used as a base material 3.

(2) Preparation of Resin Solution

Each component was mixed with the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98% to 99% by mole), whereby a gas barrier layer forming liquid was prepared.

Composition of gas barrier layer forming liquid

| | | |
|---|---|---|
| Kuraray Exceval AQ-4105 (product name, | 4.0 | parts by mass |
| manufactured by KURARAY Co., Ltd.) | | |
| Pure water | 88.5 | parts by mass |
| Isopropyl alcohol | 7.5 | parts by mass |

Subsequently, the obtained gas barrier layer forming liquid was filtered using a filter having an absolute filtration precision of 5 μm (product name: Hydrophobic Fluororepore Membrane, manufactured by Millex).

(3) Lamination of Gas Barrier Layer

The gas barrier layer forming liquid after the filtration treatment was applied to the corona-treated surface side of the base material 3 using a bar coater so that the film thickness after drying was 1.1 μm, and dried at 120° C. for 60 seconds, whereby a light absorption filter having a gas barrier layer was produced.

The light absorption filter having a gas barrier layer has a configuration in which the base material 1 or base material 2, the light absorption filter, and the gas barrier layer are laminated in this order.

<Absorbance of Light Absorption Filter (Before Ultraviolet Irradiation)>

(1) Measurement of Absorbance

Using a UV3150 spectrophotometer (product name) manufactured by Shimadzu Corporation, the absorbance of the base material-attached light absorption filter and the standard filter in a wavelength range of 380 nm to 800 nm was measured for every 1 nm. It is noted that the optical path length is 2.5 μm.

A standard filter for the light absorption filter containing the resin 1 and the resin 2 was produced in the same manner as in the production of the base material-attached light absorption filter No. 101 except that the above-described light absorption filter forming liquid Ba-1, which was changed so that the dye and the photoradical generator were not contained, was used.

A standard filter for the light absorption filter containing the resin 3 was produced in the same manner as in the production of the base material-attached light absorption filter No. 103 except that the above-described light absorption filter forming liquid Ba-2, which was changed so that the dye and the photoradical generator were not contained, was used.

A standard filter for the light absorption filter containing the resin 4 was produced in the same manner as in the production of the base material-attached light absorption filter No. 103 except that the above-described light absorption filter forming liquid Ba-2, which was changed so that the dye and the photoradical generator were not contained and furthermore the resin 3 was changed to the resin 4, was used.

(2) Calculation of Absorbance

Using the absorbance value Abₓ (λ) of the base material-attached light absorption filter at each wavelength λ nm measured as described above and the absorbance value Ab₀ (λ) of the standard filter containing the same resin at each wavelength λ nm, the absorbance Ab (λ) of the light absorption filter before ultraviolet irradiation was calculated according to the following expression.

Ab(λ)=Abₓ(λ)−Ab₀(λ)

Hereinafter, among the absorbances Ab (λ) of the light absorption filter in a wavelength range of 400 to 700 nm, the wavelength at which the highest absorbance Ab (λ) among the wavelengths at which the highest maximum absorption is exhibited was defined as the maximal absorption wavelength (hereinafter, also simply referred to as “λₘₐₓ”), and the absorbance at λₘₐₓ was defined as the maximal absorption value (hereinafter, also simply referred to as “Ab (λₘₐₓ)”).

<<Evaluation 1>>

Each light absorption filter was subjected to the following ultraviolet irradiation test to evaluate the quenching rate and the presence or absence of the secondary absorption associated with the decomposition of the coloring agent.

The results are summarized in Table 2 below.

(Ultraviolet Irradiation Test)

Using an air-cooled metal halide lamp (manufactured by EYE GRAPHICS Co., Ltd.) at 160 W/cm under atmospheric pressure (101.33 kPa), the base material-attached light absorption filter and the standard filter was irradiated with an ultraviolet ray at an irradiation dose of 600 mJ/cm² from the light absorption filter side (the side opposite to base material 1 or the base material 2). It is noted that the UV irradiation was carried out by placing the base material-attached light absorption filter and the standard filter on a hot plate set to the UV irradiation temperature shown in Table 1 below and heating the filters.

(Glass Transition Temperature (Tg) of Light Absorption Filter)

The glass transition temperature of the base material-attached light absorption filter produced as described above was measured as follows. It is noted that a light absorption filter portion of the base material-attached light absorption filter produced as described above was scraped off and used as a measurement sample.

A differential scanning calorimetry device X-DSC7000 (product name, manufactured by IT Measurement Control Co., Ltd.) was used, 20 mg of the measurement sample was placed in a measurement pan, and the temperature of the pan was raised from 30° C. to 120° C. in a nitrogen stream at a rate of 10° C./min, held for 15 minutes, and then cooled to 30° C. at −20° C./min. Thereafter, the temperature was raised again from 30° C. to 250° C. at a rate of 10° C./min, and the temperature at which the baseline began to deviate from the low temperature side was defined as the glass transition temperature Tg.

<Absorbance of Light Absorption Filter (after Ultraviolet Irradiation)>

Using the base material-attached light absorption filter after ultraviolet irradiation and the standard filter, the absorbance Ab (λ) of the light absorption filter after ultraviolet irradiation was calculated according to the same method as described in <Absorbance of light absorption filter (before ultraviolet irradiation)> described above.

[1. Evaluation of Decolorization Rate]

The quenching rate was calculated according to the following expression using the maximal absorption values (Ab (λₘₐₓ)) before and after the ultraviolet irradiation test. In the present invention, the quenching rate of 20% or more is a pass level.

Quenching rate (%)=100−(Ab(λₘₐₓ) after ultraviolet irradiation/Ab(λₘₐₓ) before ultraviolet irradiation)×100

[2. Evaluation of Presence or Absence of Secondary Absorption Association with Decomposition of Coloring Agent]

(Regarding Dyes C-73, C-80, 7-11, 7-22, FDG007, Solvent Violet 13, and Solvent Blue 35)

The presence or absence of the absorption (the secondary absorption) derived from a new coloration structure associated with the decomposition of the coloring agent was evaluated based on the ratio of the absorbance at a wavelength of 450 nm to the maximal absorption value (Ab (λₘₐₓ)) before ultraviolet irradiation (hereinafter, also simply referred to as “Ab (450)”). It is meant that the smaller the value obtained by subtracting the ratio of the following (I) from the ratio of the following (II), the less frequently the absorption derived from the new coloration structure associated with the decomposition of the coloring agent occurs. In the present invention, less than 8.5% is the pass level.

Ab(450) before ultraviolet irradiation/Ab(λₘₐₓ)×100% before ultraviolet irradiation (I)

Ab(450) after ultraviolet irradiation/Ab(λₘₐₓ) before ultraviolet irradiation×100% (II)

(Regarding Dyes A-100 and A-102)

The presence or absence of the absorption (the secondary absorption) derived from a new coloration structure associated with the decomposition of the coloring agent was evaluated based on the ratio of the absorbance at a wavelength of 650 nm to the maximal absorption value (Ab (λₘₐₓ)) before ultraviolet irradiation (hereinafter, also simply referred to as “Ab (650)”). It is meant that the smaller the value obtained by subtracting the ratio of the following (III) from the ratio of the following (IV), the less frequently the absorption derived from the new coloration structure associated with the decomposition of the coloring agent occurs. In the present invention, less than 8.5% is the pass level.

Ab(650) before ultraviolet irradiation/Ab(λₘₐₓ) before ultraviolet irradiation×100% (III)

Ab(650) after ultraviolet irradiation/Ab(λₘₐₓ) before ultraviolet irradiation×100% (IV)

<<Evaluation 2>>

The base material-attached light absorption filter produced as described above was subjected to the following light resistance test. It is noted that after the production, the base material-attached light absorption filter was used in this test without being irradiated with an ultraviolet ray.

The results are summarized in Table 2 below.

<Light Resistance>

(Production of Light Resistance Evaluation Film)

A triacetyl cellulose film (product name: Fujitac TD80UL, manufactured by FUJIFILM Corporation) was bonded on the side opposite to the base material of the base material-attached light absorption filter produced as described above while interposing a pressure sensitive adhesive 1 (product name: SK2057, manufactured by Soken Chemical Co., Ltd.) having a thickness of about 20 μm. Subsequently, the base material 1 or base material 2 was peeled off, and glass was bonded to the light absorption filter side to which the base material 1 or base material 2 was bonded while interposing the pressure sensitive adhesive 1 to produce a light resistance evaluation film.

It is noted that the side opposite to the base material of the base material-attached light absorption filter means a gas barrier layer in a case where the gas barrier layer is provided, and it means a light absorption filter in a case where the gas barrier layer is not provided.

(Maximal Absorption Value of Light Resistance Evaluation Film)

Using a UV3150 spectrophotometer (product name) manufactured by Shimadzu Corporation, the absorbance of the light resistance evaluation film in a wavelength range of 200 nm to 1,000 nm was measured for every 1 nm. The absorbance difference between the absorbance of the light resistance evaluation film at each wavelength and the absorbance of the light resistance evaluation film having the same configuration except that it does not contain the dye and the radical generator was calculated, and the maximum value of this absorbance difference was defined as the maximal absorption value.

(Light Resistance)

The light resistance evaluation film was irradiated with light for 200 hours in an environment of 60° C. and 50% relative humidity with Super Xenon Weather Meter SX75 (product name) manufactured by Suga Test Instruments Co., Ltd., and the maximal absorption value before and after this irradiation was measured, and the light resistance was calculated according to the following equation. In the present invention, the light resistance in a case where the gas barrier layer is provided is preferably 30% or more, and the light resistance in a case where the gas barrier layer is provided is preferably 70% or more, more preferably 80% or more, and still more preferably 85% or more.

[Light resistance (%)]=([maximal absorption value after light irradiation for 200 hours]/[maximal absorption value before light irradiation])×100

The light resistance evaluation film having the same configuration except that it does contain a dye did not exhibit any change before and after the light resistance test in the absorbance at the maximal absorption value of the coloring agent that had been subjected to the light resistance evaluation.

TABLE 1

| | | | | | Radical generator | | | | | Tg of |
|---|---|---|---|---|---|---|---|---|---|---|
| | | | | | | | Molar | | UV | Light |
| | | Dye | | | | | ratio | Oxygen | irradiation | absorption |
| | Matrix | | λmax | Formulation | | Formulation | to | barrier | temperature | filter |
| No. | polymer | Kind | (nm) | amount | Kind | amount | dye | layer | (° C.) | (° C.) |
| 101 | Resin1/ | C-73 | 592 | 1.57 | Irgacure 907 | 6.35 | 10 | Absent | 100 | 94 |
| | Resin2 | | | | | | | | | |
| 102 | Resin1/ | C-73 | 592 | 1.57 | Irgacure 907 | 1.60 | 2.5 | Absent | 100 | 102 |
| | Resin2 | | | | | | | | | |
| 103 | Resin 3 | C-73 | 590 | 1.57 | Benzophenone | 8.26 | 20 | Present | 130 | 76 |
| 104 | Resin 3 | C-73 | 590 | 1.57 | 4,4′-dimethoxybenzophenone | 4.82 | 10 | Present | 130 | 70 |
| 105 | Resin 3 | C-73 | 590 | 1.57 | 4,4′-dimethoxybenzophenone | 2.41 | 5 | Present | 130 | 72 |
| 106 | Resin 3 | C-73 | 590 | 1.57 | 4,4′-dimethoxybenzophenone | 2.75 | 5 | Present | 130 | 68 |
| 107 | Resin 3 | C-73 | 590 | 1.57 | 4,4′-dimethoxybenzophenone | 1.37 | 2.5 | Present | 130 | 71 |
| 108 | Resin 3 | C-73 | 590 | 1.57 | 4,4′-dimethoxybenzophenone | 1.37 | 2.5 | Present | 115 | 71 |
| 109 | Resin 3 | C-73 | 590 | 1.57 | 4,4′-dimethoxybenzophenone | 1.37 | 2.5 | Present | 100 | 71 |
| 110 | Resin 4 | C-73 | 590 | 1.57 | 4,4′-dimethoxybenzophenone | 1.37 | 2.5 | Present | 130 | 90 |
| 111 | Resin 4 | C-73 | 590 | 1.57 | 4,4′-dimethoxybenzophenone | 1.37 | 2.5 | Present | 115 | 90 |
| 112 | Resin 4 | C-73 | 590 | 1.57 | 4,4′-dimethoxybenzophenone | 1.37 | 2.5 | Present | 100 | 90 |
| 113 | Resin 3 | C-73 | 590 | 1.57 | 4,4′-dimethoxybenzophenone | 0.69 | 1.25 | Present | 130 | 73 |
| 114 | Resin 3 | C-73 | 590 | 1.57 | 4,4′-dimethoxybenzophenone | 0.34 | 0.62 | Present | 130 | 74 |
| 115 | Resin 3 | C-73 | 590 | 2.36 | 4,4′-dimethoxybenzophenone | 1.03 | 1.25 | Present | 130 | 72 |
| 116 | Resin 3 | C-73 | 590 | 3.14 | 4,4′-dimethoxybenzophenone | 1.37 | 1.25 | Present | 130 | 71 |
| 117 | Resin 3 | C-73 | 590 | 3.93 | 4,4′-dimethoxybenzophenone | 1.72 | 1.25 | Present | 130 | 70 |
| 118 | Resin 3 | 7-22 | 503 | 0.87 | 4,4′-dimethoxybenzophenone | 1.37 | 2.5 | Present | 130 | 71 |
| 119 | Resin 3 | 7-11 | 513 | 1.07 | 4,4′-dimethoxybenzophenone | 2.75 | 5 | Present | 130 | 66 |
| 120 | Resin 3 | C-80 | 594 | 1.47 | 4,4′-dimethoxybenzophenone | 2.75 | 5 | Present | 130 | 68 |
| 121 | Resin1/ | C-73 | 592 | 1.57 | Irgacure 907 | 6.35 | 10 | Present | 100 | 94 |
| | Resin2 | | | | | | | | | |
| 122 | Resin 3 | A-100 | 440 | 1.96 | 4,4′-dimethoxybenzophenone | 1.37 | 2.5 | Present | 130 | 67 |
| 123 | Resin 3 | A-102 | 441 | 1.85 | 4,4′-dimethoxybenzophenone | 1.37 | 2.5 | Present | 130 | 68 |
| 201 | Resin1/ | FDG007 | 594 | 2.22 | Irgacure 907 | 1.6 | 2.5 | Absent | 100 | 103 |
| | Resin2 | | | | | | | | | |
| 202 | Resin1/ | Solvent | 588 | 3.74 | Irgacure 907 | 1.6 | 2.5 | Absent | 100 | 88 |
| | Resin2 | Violet 13 | | | | | | | | |
| 203 | Resin 3 | Solvent | 651 | 3.97 | Benzophenone | 6.3 | 15 | Present | 130 | 74 |
| | | Blue 35 | | | | | | | | |
| 204 | Resin 3 | Solvent | 651 | 3.97 | Benzophenone | 6.3 | 15 | Present | 130 | 74 |
| | | Blue 35 | | | | | | | | |

TABLE 2

| | | | | | | Ratio of Ab (450) to | | |
|---|---|---|---|---|---|---|---|---|
| | | | | | | Ab (λmax) before | | Light |
| | Ab (λmax) of dye | | | Ab (450) | | ultraviolet irradiation | | resistance |
| | Before | After | | Before | After | Before | After | under |
| | ultraviolet | ultraviolet | Decolorization | ultraviolet | ultraviolet | ultraviolet | ultraviolet | xenon |
| No. | irradiation | irradiation | rate | irradiation | irradiation | irradiation | irradiation | 200 hr |
| 101 | 1.10 | 0.18 | 84% | 0.015 | 0.021 | 1.4% | 1.9% | 33% |
| 102 | 0.99 | 0.54 | 45% | 0.013 | 0.018 | 1.3% | 1.8% | 38% |
| 103 | 1.10 | 0.54 | 51% | 0.019 | 0.014 | 1.7% | 1.3% | 90% |
| 104 | 1.07 | 0.04 | 96% | 0.015 | 0.014 | 1.4% | 1.3% | 85% |
| 105 | 1.10 | 0.58 | 47% | 0.016 | 0.011 | 1.5% | 1.0% | 89% |
| 106 | 1.47 | 0.02 | 99% | 0.015 | 0.006 | 1.4% | 0.6% | 83% |
| 107 | 1.10 | 0.02 | 99% | 0.015 | 0.007 | 1.4% | 0.6% | 87% |
| 108 | 1.07 | 0.02 | 98% | 0.014 | 0.008 | 1.3% | 0.8% | 87% |
| 109 | 1.07 | 0.45 | 58% | 0.014 | 0.012 | 1.3% | 1.1% | 87% |
| 110 | 1.09 | 0.04 | 97% | 0.014 | 0.007 | 1.3% | 0.6% | 87% |
| 111 | 1.09 | 0.40 | 63% | 0.014 | 0.011 | 1.3% | 1.0% | 87% |
| 112 | 1.09 | 0.81 | 25% | 0.014 | 0.015 | 1.3% | 1.4% | 87% |
| 113 | 1.11 | 0.02 | 99% | 0.017 | 0.006 | 1.5% | 0.5% | 90% |
| 114 | 1.12 | 0.05 | 96% | 0.017 | 0.011 | 1.5% | 1.0% | 92% |
| 115 | 1.53 | 0.01 | 99% | 0.023 | 0.008 | 1.5% | 0.5% | 91% |
| 116 | 1.99 | 0.02 | 99% | 0.034 | 0.011 | 1.7% | 0.6% | 90% |
| 117 | 2.46 | 0.02 | 99% | 0.041 | 0.012 | 1.7% | 0.5% | 91% |
| 118 | 0.42 | 0.00 | 100% | 0.030 | 0.010 | 7.1% | 2.4% | 91% |
| 119 | 0.52 | 0.00 | 100% | 0.034 | 0.007 | 6.5% | 1.3% | 97% |
| 120 | 0.84 | 0.01 | 99% | 0.034 | 0.007 | 4.0% | 0.8% | 86% |
| 121 | 1.10 | 0.18 | 84% | 0.015 | 0.021 | 1.4% | 1.9% | 75% |
| 201 | 0.75 | 0.71 | 6% | 0.005 | 0.014 | 0.7% | 1.9% | 78% |
| 202 | 0.24 | 0.18 | 25% | 0.021 | 0.042 | 8.9% | 17.8% | 95% |
| 203 | 0.105 | 0.100 | 5% | 0.000 | 0.010 | 0.0% | 9.5% | 90% |
| 204 | 0.102 | 0.100 | 2% | 0.000 | 0.010 | 0.0% | 9.8% | 90% |
| 122 | 0.37 | 0.030 | 92% | 0.001 | 0.001 | 0.30% | 0.30% | 85% |
| 123 | 0.38 | 0.038 | 90% | 0.001 | 0.001 | 0.30% | 0.30% | 86% |

(Note in table)
The molar ratio to the dye means the molar amount of the formulated radical generator with respect to 1 mol of the dye.
In addition to 6.3 parts by mass of benzophenone which is a radical generator, the light absorption filter No. 204 contains 6.7 parts by mass of ethyl 4-(dimethylamino)benzoate (15 mol in terms of the formulation ratio with respect to 1 mol of the dye) as a decolorization accelerating agent.
λmax means a wavelength at which the highest absorbance Ab (λ) is exhibited among the maximal absorption wavelengths that the light absorption filter has in a wavelength range of 400 to 700 nm.
The formulation amount of the dye means an amount in terms of a part by mass with respect to 100 parts by mass of the filter, “—” indicates that the corresponding component is not contained.
Ab (λₘₐₓ) means the value of the absorbance at the maximal absorption wavelength λₘₐₓ.
Ab (450) means the value of the absorbance at a wavelength of 450 mn, and Ab (650) means the value of the absorbance at a wavelength of 650 nm.
Regarding the ratio (%) of Ab (450) to Ab (λₘₐₓ) before ultraviolet irradiation, the column of “Before ultraviolet irradiation” means a ratio calculated by using the Ab (450) before ultraviolet irradiation, and the column of “After ultraviolet irradiation” means a ratio calculated by using the Ab (450) after ultraviolet irradiation.
Further, regarding the ratio (5) of Ab (650) to Ab (λₘₐₓ) before ultraviolet irradiation, the column of “Before ultraviolet irradiation” means a ratio calculated by using the Ab (650) before ultraviolet irradiation, and the column of “After ultraviolet irradiation” means a ratio calculated by using the Ab (650) after ultraviolet irradiation.
The UV irradiation temperature means the set temperature of the hot plate in the ultraviolet irradiation test described above.

From the results in Table 1 and Table 2, the following points can be seen.

The light absorption filter No. 201 of the comparative example contains a tetraazaporphyrin-based coloring agent as a comparative dye. The light absorption filter No. 201 of this comparative example is seldom decolorized and has a decolorization rate of 6% upon ultraviolet irradiation. The light absorption filter No. 202 of the comparative example contains an anthraquinone-based coloring agent as a comparative dye. The light absorption filter No. 202 of this comparative example has a decolorization rate of 25% upon ultraviolet irradiation, and Ab (450)/Ab (λₘₐₓ) increases from 8.9% to 17.8% upon ultraviolet irradiation, whereby it has been found that the absorption derived from a new coloration structure associated with the decomposition of the coloring agent occurs.

The light absorption filter No. 203 of the comparative example contains an anthraquinone-based coloring agent as the comparative dye, and the light absorption filter No. 204 of the comparative example contains an anthraquinone-based coloring agent as the comparative dye and further contains an amine-based radical accelerating agent. The light absorption filters No. 203 and 204 of these comparative examples seldom decolorized and have a decolorization rate of 5% and 2%, respectively, upon ultraviolet irradiation, and moreover, Ab (450)/Ab (λₘₐₓ) increases from 0% to 9.5% and from 0% to 9.8%, respectively, upon ultraviolet irradiation, whereby it has been found that the absorption derived from a new coloration structure associated with the decomposition of the coloring agent occurs.

In contrast to these, all the light absorption filters No. 101 to 123 according to the embodiment of the present invention containing the squarine-based coloring agent represented by General Formula (1) or the benzylidene-based coloring agent or a cinnamylidene-based coloring agent represented by General Formula (V) and a radical generator have an excellent quenching rate upon ultraviolet irradiation as compared with the light absorption filter of the comparative example, and moreover the decolorization occurs with little absorption derived from a new coloration structure associated with the decomposition of the coloring agent, and thus they have an excellent decolorizing property. In particular, as the temperature at the time of ultraviolet irradiation is set to be a higher temperature than the glass transition temperature of the light absorption filter, the decolorization rate upon ultraviolet irradiation is more excellent (see the comparison in Nos. 107 to 109 and the comparison in Nos. 110 to 112). In addition, in a case where a benzophenone compound substituted with an alkoxy group is used, a more excellent decolorization rate was exhibited even in a case where the molar ratio of the radical generator to the dye is small as compared with the unsubstituted benzophenone compound (see Nos. 103 to 107, 110, and 113 to 117).

Further, among the light absorption filters according to the embodiment of the present invention, the light absorption filters No. 103 to 123 having a gas barrier layer have excellent light resistance as well as an excellent decolorizing property. Among them, the light absorption filters No. 103 to 120, 122, and 123 according to the embodiment of the present invention containing the benzophenone-based compound which is a hydrogen abstraction type photoradical generator exhibits excellent light resistance as compared with the light absorption filter No. 121 according to the embodiment of the present invention containing an α-aminoalkylphenone-based compound which is an intramolecular cleavage type photoradical generator. Among them, the light absorption filter according to the embodiment of the present invention containing a benzophenone compound having an alkoxy group at the 4-position and the 4′-position has the same degree of light resistance as compared with the light absorption filter according to the embodiment of the present invention containing an unsubstituted benzophenone compound while realizing more excellent quenching rate (see No. 113 to 117 in comparison with No. 103).

As described above, the light absorption filter according to the embodiment of the present invention containing the squarine-based coloring agent represented by General Formula (1) or benzylidene-based coloring agent represented by General Formula (V) and a radical generator has an excellent quenching rate in a case of being subjected to ultraviolet irradiation, and moreover, hardly causes secondary absorption associated with the decomposition of the dye upon ultraviolet irradiation, thereby capable of an exhibiting excellent decolorizing property.

Further, Similar to the light absorption filter containing the squarine-based coloring agent represented by General Formula (1) or benzylidene-based coloring agent represented by General Formula (V) and a radical generator, the light absorption filter according to the embodiment of the present invention containing the cinnamylidene-based coloring agent represented by General Formula (V) and a radical generator has an excellent quenching rate in a case of being subjected to ultraviolet irradiation, and moreover, hardly causes secondary absorption associated with the decomposition of the dye upon ultraviolet irradiation, thereby capable of an exhibiting excellent decolorizing property.

Although the present invention has been described with reference to the embodiments, it is the intention of the inventors of the present invention that the present invention should not be limited by any of the details of the description unless otherwise specified and rather be construed broadly within the spirit and scope of the invention appended in WHAT IS CLAIMED IS.
1: upper polarizing plate
2: direction of absorption axis of upper polarizing plate
3: liquid crystal cell upper electrode substrate
4: alignment control direction of upper substrate
5: liquid crystal layer
6: liquid crystal cell lower electrode substrate
7: alignment control direction of lower substrate
8: lower polarizing plate
9: direction of absorption axis of lower polarizing plate
B: backlight unit
10: liquid crystal display device

What is claimed is:

1. A light absorption filter comprising:
a resin;
a dye that has a main absorption wavelength band at a wavelength of 400 to 700 nm; and
a compound that generates a radical upon ultraviolet irradiation,
wherein the dye includes a squarine-based coloring agent represented by General Formula (1), 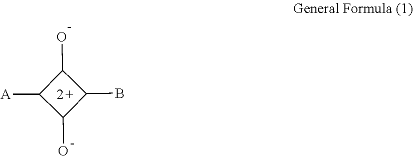
in the formula, A and B each independently represent an aryl group which may have a substituent, a heterocyclic group which may have a substituent, or —CH=G, and G represents a heterocyclic group which may have a substituent.

2. A light absorption filter comprising:
a resin;
a dye that has a main absorption wavelength band at a wavelength of 400 to 700 nm; and
a compound that generates a radical upon ultraviolet irradiation,
wherein the dye includes a benzylidene-based or cinnamylidene-based coloring agent represented by General Formula (V), 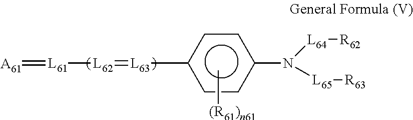
in the formula, A₆₁ represents an acidic nucleus, L₆₁, L₆₂, and L₆₃ each independently represent a methine group which may be substituted, L₆₄ and L₆₅ each independently represent an alkylene group having 1 to 4 carbon atoms, R₆₂ and R₆₃ each independently represent a cyano group, —COOR₆₄, —CONR₆₅R₆₆, —COR₆₄, —SO₂R₆₄, or —SO₂NR₆₅R₆₆, where R₆₄ represents an alkyl group, an alkenyl group, a cycloalkyl group, or an aryl group, R₆₅ and R₆₆ each independently represent a hydrogen atom, an alkyl group, an alkenyl group, a cycloalkyl group, or an aryl group, R₆₁ represents a substituent, m₆₁ is an integer of 0 or 1, and n₆₁ is an integer of 0 to 4.

3. The light absorption filter according to claim 1,
wherein the compound that generates a radical upon ultraviolet irradiation is a compound that generates a radical upon intramolecular cleavage.

4. The light absorption filter according to claim 1,
wherein the compound that generates a radical upon ultraviolet irradiation is a compound that abstracts a hydrogen atom from a compound present in a vicinity thereof to generate a radical.

5. The light absorption filter according to claim 4,
wherein the compound that abstracts a hydrogen atom from a compound present in a vicinity thereof to generate a radical is a benzophenone compound substituted with an alkoxy group.

6. The light absorption filter according to claim 1,
wherein in the light absorption filter, the dye is chemically changed to be decolorized upon irradiation with light.

7. An optical filter that is obtained by subjecting the light absorption filter according to claim 1 to mask exposure by ultraviolet irradiation.

8. An organic electroluminescent display device or a liquid crystal display device, comprising the optical filter according to claim 7.

9. The organic electroluminescent display device or the liquid crystal display device according to claim 8,
wherein the organic electroluminescent display device or the liquid crystal display device has a layer, on a viewer side of the optical filter, which inhibits light absorption of the compound that generates a radical upon ultraviolet irradiation.

10. A method of manufacturing an optical filter, comprising irradiating the light absorption filter according to claim 1 with an ultraviolet ray to carry out mask exposure.

11. The method of manufacturing an optical filter according to claim 10,
wherein the irradiation with an ultraviolet ray is carried out under a condition of heating.

12. The method of manufacturing an optical filter according to claim 11,
wherein a temperature of the heating is a temperature that exceeds a glass transition temperature of the light absorption filter.
